(19) United States
(12) Patent Application Publication
(10) Pub. No.: US 2025/0311611 A1
(43) Pub. Date: Oct. 2, 2025

(54) POLYMERIC COMPOUND, AND ELECTROLUMINESCENCE DEVICE MATERIAL AND ELECTROLUMINESCENCE DEVICE INCLUDING THE POLYMERIC COMPOUND

(71) Applicant: Samsung Electronics Co., Ltd., Suwon-si (KR)

(72) Inventors: Masashi TSUJI, Suwon-si (KR); Fumiaki KATO, Suwon-si (KR); Naotoshi SUGANUMA, Suwon-si (KR); Yusaku KONISHI, Suwon-si (KR); Ha Il KWON, Suwon-si (KR); Kiyohiko TSUTSUMI, Suwon-si (KR); Norihito ISHII, Suwon-si (KR); Takahiro FUJIYAMA, Suwon-si (KR); Won Sik YOON, Suwon-si (KR)

(21) Appl. No.: 19/090,797

(22) Filed: Mar. 26, 2025

(30) Foreign Application Priority Data
Mar. 26, 2024 (JP) 2024-049465
Feb. 25, 2025 (KR) 10-2025-0024260

(51) Int. Cl. H10K 85/10; C08G 73/02; H10K 50/115; H10K 50/15; H10K 50/17; H10K 71/15

(52) U.S. Cl. CPC H10K 85/151; C08G 73/0266; H10K 85/115; H10K 50/115; H10K 50/15; H10K 50/17; H10K 71/15

(57) ABSTRACT

A polymeric compound including a structural unit represented by Chemical Formula 1, and a structural unit represented by Chemical Formula 2:

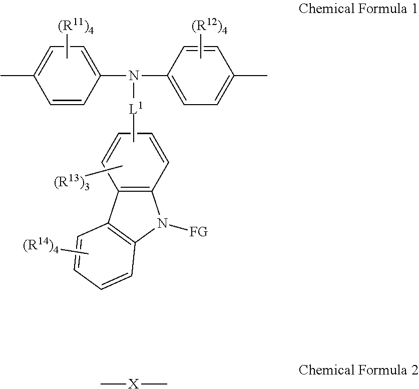

wherein Chemical Formula 1 and Chemical Formula 2 are as defined herein.

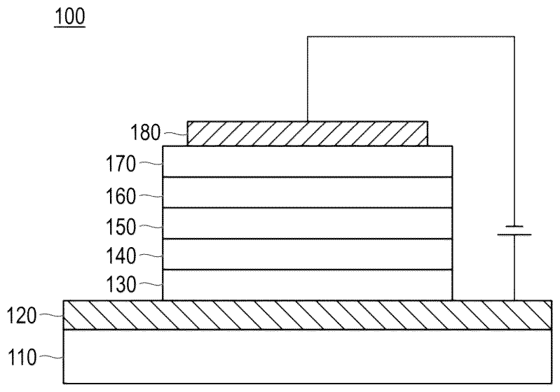

### CROSS-REFERENCE TO RELATED APPLICATION

This application claims priority to and the benefit of Japanese Patent Application No. 2024-049465, filed on Mar. 26, 2024, and Korean Patent Application No. 10-2025-0024260 filed on Feb. 25, 2025, and all the benefits accruing therefrom under 35 U.S.C. § 119, the contents of which in their entireties are herein incorporated by reference.

### BACKGROUND

### 1. Field

A polymeric compound, an electroluminescence device material, and an electroluminescence device including the polymeric compound are provided.

### 2. Description of the Related Art

Research and development of electroluminescence devices (EL devices) are actively progressing. In particular, EL devices are expected to be used as solid light-emitting, inexpensive, and large area full color display device or as a writing light source array. An EL device is alight emitting device including a thin film having a thickness of several nanometers to several hundred nanometers, and is disposed or arranged between an anode and a cathode. The EL devices usually further include a hole transport layer, a light emitting layer, an electron transport layer, or the like.

Among these, the light emitting layer includes a fluorescent light emitting material and/or a phosphorescent light emitting material. The phosphorescent light emitting material is a material expected to have a higher luminous efficiency than the fluorescent light emitting material. In addition, to cover a wide color gamut, an RGB light source requires an emission spectrum having a narrow full width at half maximum (FWHM). For example, although deep blue is particularly required for blue, there are currently no devices found to have a long life-span and a high color purity.

Light emitting devices using a “quantum dot,” which is an inorganic light emitting material as a light emitting material, have been known. Quantum dots (QD) are semiconductor materials having crystal structures of several nanometers in size and are made up of hundreds to thousands of atoms. Because quantum dots are very small in size, a surface area per unit volume is large. For this reason, most of the atoms are present on the surface of the nanocrystals, and exhibit quantum confinement effects. Due to the quantum confinement effect, a quantum dot can adjust the emission wavelength by adjusting its size, and has garnered much attention because it has characteristics such as improved color purity and high photoluminescence (PL) luminous efficiency. A quantum dot electroluminescence device (QD LED) is a three-layered device including a hole transport layer and an electron transport layer at both sides, with a quantum dot light emitting layer which is known as the basic device.

### SUMMARY

There is an ongoing demand for technology to improve luminous efficiency and durability.

Therefore, embodiments provide a technology capable of achieving a good balance between luminous efficiency and durability (e.g., luminescence life-span) of an electroluminescence device (e.g., a quantum dot electroluminescence device).

Accordingly, an aspect provides a polymeric compound including a structural unit represented by Chemical Formula 1, and a structural unit represented by Chemical Formula 2:

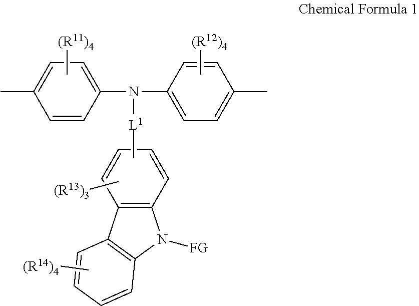

wherein, in Chemical Formula 1,
   R¹¹ to R¹⁴ are each independently a hydrogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aryl group, or a halogen atom,
   L¹ is a substituted or unsubstituted aromatic ring group having 6 to 15 ring-forming atoms, and
   FG is represented by one of Chemical Formula 3 to Chemical Formula 5:

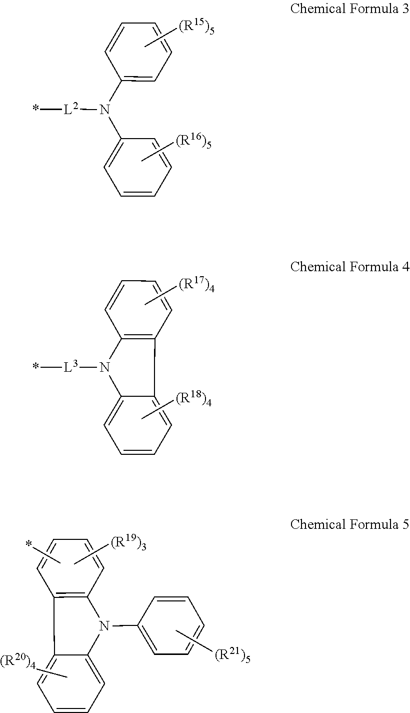

wherein, in Chemical Formula 3 to Chemical Formula 5,
   L² and L³ are each independently a substituted or unsubstituted aromatic ring group having 6 to 15 ring-forming atoms,
   R¹⁵ to R²¹ are each independently a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, or a substituted or unsubstituted heteroaromatic ring group having 5 to 20 ring-forming atoms, and
   * indicates a linking position to a nitrogen atom;

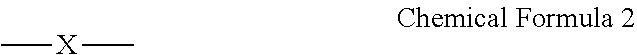

wherein, in Chemical Formula 2, X is an aromatic ring group having 6 to 30 carbon atoms unsubstituted or substituted with a hydrocarbon group having 1 to 14 carbon atoms, or an aromatic ring group having 4 to 30 carbon atoms and at least one heteroatom and unsubstituted or substituted with a hydrocarbon group having 1 to 14 carbon atoms.

Another aspect provides a composition including the polymeric compound, and at least one solvent.

Another aspect provides an electroluminescence device including a first electrode, a second electrode, and at least one layer of an organic film arranged between the first electrode and the second electrode, wherein the at least one layer of the organic film comprises the polymeric compound of claim 1.

Still another aspect provides an electroluminescence device including a first electrode, a second electrode, and at least one layer of an organic film arranged between the first electrode and the second electrode, wherein the at least one layer of the organic film includes the composition.

Yet another aspect provides a method of manufacturing an electroluminescence device comprising a first electrode, a second electrode, and at least one layer of an organic film arranged between the first electrode and the second electrode, the method including coating a composition including the polymeric compound and at least one solvent to form the at least one layer of the organic film between the first electrode and the second electrode, and removing the at least one solvent.

An electroluminescence device (e.g., a quantum dot electroluminescence device) according to some embodiments may have a good balance of luminous efficiency and durability (e.g., luminescence life-span).

### BRIEF DESCRIPTION OF THE DRAWINGS

The above and other aspects, features, and advantages of certain exemplary embodiments will be more apparent from the following detailed description taken in conjunction with the accompanying drawing, in which:

The FIGURE is a schematic view showing an electroluminescence device according to an embodiment.

### DETAILED DESCRIPTION

Reference will now be made in further detail to exemplary embodiments, examples of which are illustrated in the accompanying drawing, wherein like reference numerals refer to like elements throughout the specification. In this regard, the present exemplary embodiments may have different forms and should not be construed as being limited to the detailed descriptions set forth herein. Accordingly, the exemplary embodiments are merely described in further detail below, and by referring to the FIGURE, to explain certain aspects and features. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Provided is a polymeric compound including a structural unit represented by Chemical Formula 1 and a structural unit represented by Chemical Formula 2:

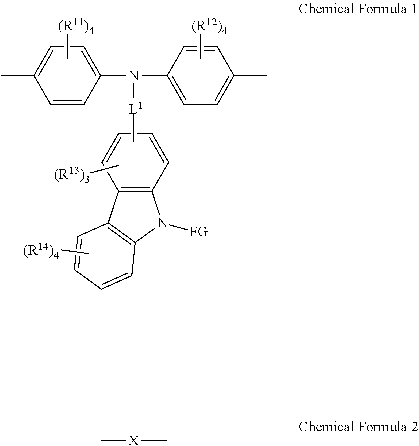

In Chemical Formula 1, R¹¹ to R¹⁴ are each independently a hydrogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aryl group, or a halogen atom,
L¹ is a substituted or unsubstituted aromatic ring group having 6 to 15 ring-forming atoms, and
FG is represented by one of Chemical Formula 3 to Chemical Formula 5:

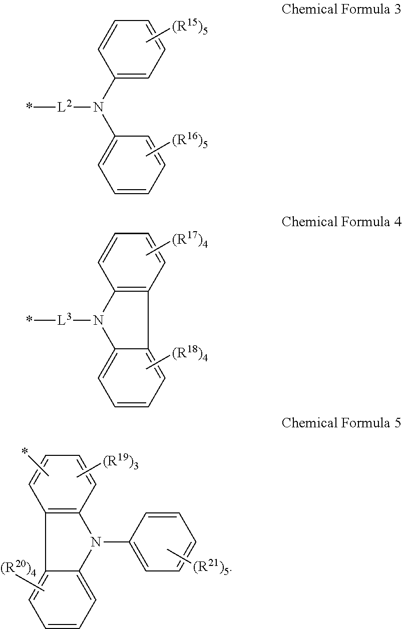

In Chemical Formula 3 to Chemical Formula 5, L² and L³ are each independently a substituted or unsubstituted aromatic ring group having 6 to 15 ring-forming atoms,
R¹⁵ to R²¹ are each independently a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, or a substituted or unsubstituted heteroaromatic ring group having 5 to 20 ring-forming atoms, and
* indicates a linking position to a nitrogen atom.

In Chemical Formula 2,
X is an aromatic ring group having 6 to 30 carbon atoms unsubstituted or substituted with a hydrocarbon group having 1 to 14 carbon atoms, or an aromatic ring group having 4 to 30 carbon atoms and at least one heteroatom and unsubstituted or substituted with a hydrocarbon group having 1 to 14 carbon atoms.

As used herein, the structural unit represented by Chemical Formula 1 is also simply referred to as “structural unit (A)” or “structural unit (A) according to an embodiment.” Similarly, the structural unit represented by Chemical Formula 2 is also simply referred to as “structural unit (B)” or “structural unit (B) according to an embodiment.” In addition, the polymeric compound including structural unit (A) represented by Chemical Formula 1 and the structural unit (B) represented by Chemical Formula 2 is also simply referred to as “polymeric compound” or “polymeric compound according to an embodiment”.

According to another aspect, provided is an electroluminescence device including a first electrode, a second electrode, and one or more layers of organic film arranged between the first electrode and the second electrode, wherein at least one layer of the organic film includes the polymeric compound.

As used herein, the electroluminescence device may be referred to as an “LED.” The quantum dot electroluminescence device may also be referred to simply as “QLEDs.” The organic electroluminescence device may be also simply referred to as an “OLED.”

By such a configuration, it is possible to provide an electroluminescence device, for example, a quantum dot electroluminescence device, which may achieve a good balance between luminous efficiency, for example, EQEₘₐₓ, and durability, for example, luminescence life-span (for example, LT50).

As materials constituting the light emitting layer or carrier transport layer of an electroluminescence device, various low-molecular materials and polymeric materials may be used. Among these, low-molecular materials are superior in terms of device efficiency and life-span. However, when using low-molecular materials, there is a problem of high manufacturing costs because the device needs to be manufactured using a vacuum process. Accordingly, there is demand for a polymeric materials achieving a good balance between luminous performance, such as, for example, luminous efficiency, and durability, for example, luminescence life-span.

By applying a polymeric compound having a structural unit (A) represented by Chemical Formula 1 and a structural unit (B) represented by Chemical Formula 2 to an electroluminescence device, both luminous efficiency and durability (luminescence life-span) may be improved compared to the case where another material is used. In addition, by applying the polymeric compound to an electroluminescence device, it was discovered that sufficient luminous efficiency and luminescence life-span may be achieved while maintaining a certain level of low driving voltage.

The mechanism of exertion of the above-mentioned effect by an embodiment is presumed to be as follows, but there is no intention to be limited by theory.

According to various embodiments, when a polymeric compound according to an embodiment is included in a hole injection layer or a hole transport layer (i.e., as a hole transport material) of an electroluminescence device, the difference between HOMO level and HOMO-1 level, and the difference between HOMO-1 level and the energy level of a metal, a semiconductor nanoparticle, or perovskite compound, are small. In addition, in an electroluminescence device including the polymeric compound according to an embodiment, a good balance between the amount of holes injected from hole transport layer and the amount of electrons injected from electron transport layer may be achieved. Accordingly, the light-emitting region in the light-emitting layer (i.e., a light-emitting layer including quantum dots) may have a peak in the center of the layer, as well as the light-emitting region may respectively broadly be distributed in the layer. As a result, luminous efficiency may be improved. Further, the distribution of the light-emitting region may suppress deterioration of the interfaces between hole transport layer and light-emitting layer, as well as between light-emitting layer and electron transport layer, and thus, durability (i.e., luminescence life-span) may be improved. Therefore, it is expected that an electroluminescence device, for example, a quantum dot electroluminescence device, using the polymeric compound according to one or more embodiments as a hole injection material or a hole transport material, for example, a hole transport material, may achieve excellent luminous efficiency exhibit and also high durability (luminescence life-span).

In addition, since the polymeric compound according to one or more embodiments has excellent film forming properties and solvent solubility, it is possible to form a film using a wet (coating) method. Therefore, by using the polymeric compound according to one or more embodiments, it becomes possible to enlarge the area of the electroluminescence device and to achieve higher productivity. The above effect may be effectively exhibited when the polymeric compound is applied to an EL device, particularly a hole transport layer or a hole injection layer of a QLED.

In addition, the aforementioned mechanism is theory, and the present disclosure is not limited by the theoretical mechanism.

The FIGURE is exaggerated for better understanding and ease of description, and the dimensional ratio of each constituent element in each drawing may differ from reality. In addition, when the embodiment of the present disclosure has been described with reference to the drawing, the same reference numerals are given to the same elements in the description of the drawing, and redundant descriptions may be omitted.

In this specification, unless otherwise specified, operation and physical properties were measured under the conditions of room temperature, such as, for example, 20° C. or more and 25° C. or less, and relative humidity (RH) of 40% or more and 50% or less.

As used herein, “x and y are each independently” means that x and y may be the same or different.

As used herein, “a group derived from compound z” or “a compound z-derived group” refers to a group where hydrogen atom that is directly bonded to the ring atom from the cyclic structure, when “compound z” is a cyclic compound, is removed as much as the valence to represent a free valence.

As used herein, the number of ring-forming atoms refers to the number of atoms constituting the corresponding ring itself of the compound (e.g., monocyclic compound, condensed ring compound, crosslinked compound, carbocyclic compound, and heterocyclic compound) having a structure in which atoms are bonded in a ring (e.g., monocycle, condensed ring, ring assembly, etc.). Atoms that do not form a ring (e.g., a hydrogen atom that terminates the bond of the atoms forming a ring) or atoms included in a substituent when the ring is substituted by a substituent group are not included in the number of ring-forming atoms. The number of ring-forming atoms described below is assumed to be the same unless otherwise specified.

For example, a benzene ring has 6 ring-forming atoms, a naphthalene ring has 10 ring-forming atoms, a pyridine ring has 6 ring-forming atoms, and a furan ring has 5 ring-forming atoms.

When the benzene ring is substituted with a substituent, for example, an alkyl group, the number of carbon atoms of the alkyl group is not included in the number of ring-forming atoms of the benzene ring. Accordingly, the number of ring-forming atoms of the benzene ring substituted by the alkyl group is 6. In addition, when the naphthalene ring is substituted with an alkyl group as a substituent, for example, the number of atoms of the alkyl group is not included in the number of ring-forming atoms of the naphthalene ring. Accordingly, the number of ring-forming atoms of the naphthalene ring substituted by the alkyl group is 10.

For example, the number of hydrogen atoms bonded to the pyridine ring or the atoms constituting the substituent is not included in the number of ring-forming atoms of the pyridine ring. Accordingly, the number of ring-forming atoms of the pyridine ring to which the hydrogen atom or substituent is bonded is 6.

In the present specification, “the substituent represents a hydrogen atom” indicates that the structure in which the substituent exists is unsubstituted. For example, in Chemical Formula 1, when R¹¹ is all hydrogen atoms, it means that the benzene ring having R¹¹ is a p-phenylene group. Further, when three (3) are hydrogen atoms and one (1) is a methyl group among the R¹¹, it means that the benzene ring having R¹¹ is a p-phenylene group having a methyl group substituted at one carbon of the benzene ring.

As used herein, unless specifically defined, “substituted” refers to being substituted with an alkyl group, a cycloalkyl group, a hydroxyalkyl group, an alkoxy group, an alkoxyalkyl group, a cycloalkoxy group, an alkenyl group, an alkynyl group, a primary amino group (—NH₂), a secondary amino group —NH(R¹) wherein R¹ is an alkyl group or an aryl group, a tertiary amino group —N(R¹)(R²) wherein R¹ and R² are each independently an alkyl group or an aryl group, and in this case, R¹ and R² may form a ring, an aryl group, an aryloxy group, an alkylthio group, a cycloalkylthio group, an arylthio group, an alkoxycarbonyl group, an aryloxycarbonyl group, a hydroxy group (—OH), a carboxyl group (—COOH), a thiol group (—SH), a cyano group (—CN), a halogen atom (a fluorine atom, a chlorine atom, a bromine atom, or an iodine atom), or a combination thereof. On the other hand, when a group is substituted, the form of the group which is included in the definition of a substituent does not include a form which has been further substituted with the group as a substituent. For example, when the substituent is an alkyl group, this alkyl group as a substituent is not further substituted with an alkyl group.

Herein, the alkyl group as the substituent may be either a linear or branched alkyl group, for example a linear alkyl group having 1 to 20, for example, 1 to 10, or 1 to 5 carbon atoms or a branched alkyl group having 3 to 20, for example, 3 to 10, or 3 to 5 carbon atoms. Non-limiting examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, a 1,2-dimethylpropyl group, an n-hexyl group, an isohexyl group, a 1,3-dimethylbutyl group, a 1-isopropylpropyl group, a 1,2-dimethylbutyl group, an n-heptyl group, a 1,4-dimethylpentyl group, a 3-ethylpentyl group, a 2-methyl-1-isopropylpropyl group, a 1-ethyl-3-methylbutyl group, an n-octyl group, a 2-ethylhexyl group, a 3-methyl-1-isopropylbutyl group, a 2-methyl-1-isopropylbutyl group, a 1-tert-butyl-2-methylpropyl group, an n-nonyl group, a 3,5,5-trimethylhexyl group, an n-decyl group, an isodecyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, an nonadecyl group, an icosyl group, or the like..

As the substituent, the cycloalkyl group may have 3 to 20, 4 to 10, or 5 to 8 carbon atoms, and include for example, a cyclopropyl group, a cyclobutyl group, a cyclopentyl group, a cyclohexyl group, or the like.

The hydroxyalkyl group may be, for example, an alkyl group that is substituted with 1 to 3 (e.g., 1 or 2, and for example 1) hydroxy groups (for example, hydroxymethyl group, hydroxyethyl group, or the like).

The alkoxy group as the substituent may be either a linear or branched alkoxy group, but desirably a linear alkoxy group having 1 to 20 carbon atoms or a branched alkoxy group having 3 to 20 carbon atoms. Non-limiting examples of the alkoxy group include a methoxy group, an ethoxy group, a propoxy group, an isopropoxy group, a butoxy group, a pentyloxy group, a hexyloxy group, a heptyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, a 3-ethylpentyloxy group, or the like.

The alkoxyalkyl group as a substituent may include, for example, the alkyl groups listed above, in which from one to three (e.g., one or two, or one) hydrogen atoms from alkyl group are substituted with the alkoxy group.

The cycloalkoxy group as a substituent may be, for example, a cyclopropoxy group, a cyclobutoxy group, a cyclopentoxy group, a cyclohexoxy group, or the like.

The alkenyl group as a substituent may have 2 to 20, 2 to 10, or 2 to 5 carbon atoms, and include, for example, a vinyl group, an allyl group, a 1-propenyl group, an isopropenyl group, a 1-butenyl group, a 2-butenyl group, a 3-butenyl group, a 1-pentenyl group, a 2-pentenyl group, a 3-pentenyl group, a 1-hexenyl group, a 2-hexenyl group, a 3-hexenyl group, a 1-heptenyl group, a 2-heptenyl group, a 5-heptenyl group, a 1-octenyl group, a 3-octenyl group, a 5-octenyl group, or the like.

The alkynyl group as a substituent may have 2 to 20, 2 to 10, or 2 to 5 carbon atoms, and include, for example, an acetylenyl group, a 1-propynyl group, a 2-propynyl group, a 1-butynyl group, a 2-butynyl group, a 3-butynyl group, a 1-pentynyl group, a 2-pentynyl group, a 3-pentynyl group, 1-hexynyl group, a 2-hexynyl group, a 3-hexynyl group, a 1-heptynyl group, a 2-heptynyl group, a 5-heptynyl group, a 1-octynyl group, a 3-octynyl group, a 5-octynyl group, or the like.

The secondary amino groups as a substituent may include, for example, an alkylamino group having 1 to 10 carbon atoms such as a methylamino group, an ethylamino group, an n-propylamino group, an n-butylamino group, an isobutylamino group, and the like, and a monoarylamino group having 6 to 20 or 6 to 10 carbon atoms, such as, a monophenylamino group, a mononaphthylamino group, and the like.

The tertiary amino group as a substituent may include, for example, a dialkylamino group having 2 to 20 carbon atoms, for example a dimethylamino group, such as a diethylamino group, a di-n-propylamino group, a di-n-butylamino group, or a methylethylamino group, or a diarylamino group having 12 to 40 or 12 to 20 carbon atoms, such as a diphenylamino group or a dinaphthylamino group, or the like.

The aryl group as a substituent may be an aryl group having 6 to 30, 6 to 20, or 6 to 10 ring-forming atoms (carbon atoms). Non-limiting examples include a phenyl group, a naphthyl group, a biphenyl group, a fluorenyl group, anthryl group, a pyrenyl group, an azulenyl group, an acenaphthylenyl group, a diphenyl group, a phenanthryl group, or the like.

Non-limiting examples of the aryloxy group as a substituent include a phenoxy groups, a naphthyloxy group, or the like.

Non-limiting examples of the alkylthio group as a substituent include a methylthio group, an ethylthio group, a propylthio group, a pentylthio group, a hexylthio group, an octylthio group, a dodecylthio group, or the like.

Non-limiting examples of the cycloalkylthio group as a substituent include a cyclopentylthio group, a cyclohexylthio group, or the like.

Non-limiting examples of the arylthio group as a substituent include a phenylthio group, a naphthylthio group, or the like.

Non-limiting examples of the alkoxycarbonyl group as a substituent include a methoxycarbonyl group, an ethoxycarbonyl group, a butoxycarbonyl group, an octoxycarbonyl group, a dodecoxycarbonyl group, or the like.

Non-limiting examples of aryloxycarbonyl groups as a substituent include a phenoxycarbonyl group, a naphthoxycarbonyl group, or the like.

The term “aromatic group” refers to a hydrocarbon having an aromatic ring and includes monocyclic and polycyclic hydrocarbons wherein the additional ring(s) of the polycyclic hydrocarbon may be aromatic or nonaromatic.

The term “heteroaromatic group” refers to an heteroaromatic ring and includes monocyclic and polycyclic ring systems wherein one to three aromatic ring atoms is selected from N, O, S, Si, and P, and additional ring(s) of the polycyclic ring system may be aromatic or nonaromatic.

### Polymeric Compound

A polymeric compound according to an aspect has a structural unit (A) represented by Chemical Formula 1 and a structural unit (B) represented by Chemical Formula 2. There may be two or more structural units (A) in the polymeric compound. That is, the structural unit (A) represented by Chemical Formula 1 may be a repeating unit. Therefore, the polymeric compound according to various embodiments may have a repeating unit, repeating unit (A), represented by Chemical Formula 1. Similarly, there may be two or more structural units (B) in a polymeric compound meaning the structural unit (B) represented by Chemical Formula 2 may be a repeating unit. The polymeric compound according to one or more embodiments may include two repeating units, repeating unit (A) represented by Chemical Formula 1 and repeating unit (B) represented by Chemical Formula 2.

In one or more embodiments, the repeating unit (A) may repeat in the polymeric composition from 3 to 1,500 times, 100 to 1500 time, 100 to 1000 times, 50 to 1000 times, or 100 to 900 times. The repeating unit (B) may repeat in the polymeric composition from 3 to 1,500 times, 100 to 1500 time, 100 to 1000 times, 50 to 1000 times, or 100 to 900 times.

The polymeric compound having the structural unit (A) and the structural unit (B) has excellent hole injection properties (for example, into quantum dots, etc.), as well as broad light-emitting region in a light-emitting layer. Accordingly, luminous efficiency and durability (luminescence life-span) of an electroluminescence device including the polymeric compound may improve. In addition, a high current efficiency and a low driving voltage may be achieved. The polymeric compound according to one or more embodiments may include only one type of structural unit (A), or may include two or more types of structural units (A). The polymeric compound according to one or more embodiments may include only one type of structural unit (B), or may include two or more types of structural units (B).

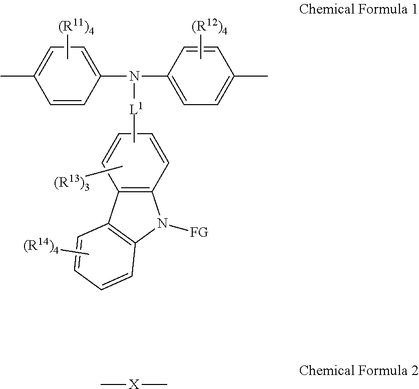

### Structural Unit A

The polymeric compound according to an aspect includes a structural unit (A) represented by Chemical Formula 1. The polymeric compound including the structural unit (A) has excellent hole injection properties (for example, into quantum dots, etc.), as well as broad light-emitting region in a light-emitting layer. Accordingly, an electroluminescence device including the polymeric compound according to some embodiments may achieve a balance between excellent luminous efficiency and durability (luminescence life-span). In addition, a high current efficiency and a low driving voltage may be achieved.

The polymeric compound according to some embodiments may include only one type of structural unit (A), or may include two or more types of structural units (A). If the polymeric compound includes more than two types of structural units (A), the plurality of structural units (A) may exist in a block form (i.e., as a block copolymer), a random form (i.e., as a random copolymer), an alternating form (i.e., as an alternating copolymer), or a periodic form (i.e., as a periodic copolymer).

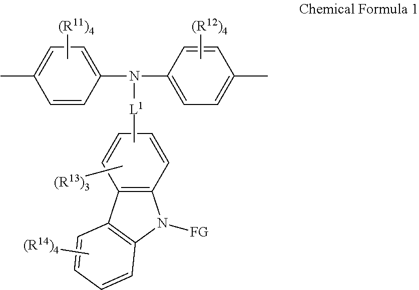

In Chemical Formula 1, R¹¹ to R¹⁴ are each independently a hydrogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aryl group, or a halogen atom. Here, each of R¹¹ to R¹⁴ present on one benzene ring may be the same as or different from each other. Further, R¹¹ to R¹⁴ present in different benzene rings may be the same as or different from each other.

Specific examples of the alkyl group, the cycloalkyl group, the alkoxy group, the cycloalkoxy group, the aryl group, or a halogen atom as R¹¹ to R¹⁴ are the same as those listed as examples of the groups as a “substituent”.

Among them, in view of higher hole injection property (and as a result, luminous efficiency) into the LED (i.e., QLED), higher durability (i.e., luminescence life-span), lower driving voltage, good film-forming properties, or a good balance of at least two properties thereof (such as, for example, a good balance of hole injection property and durability), R¹¹ to R¹³ may each independently be a hydrogen atom (i.e., unsubstituted), a straight alkyl group having 1 to 8 carbon atoms, or a branched alkyl group having 3 to 8 carbon atoms, for example, a hydrogen atom (i.e., unsubstituted), or a straight alkyl group having 1 to 3 carbon atoms, or for example, a hydrogen atom (i.e., unsubstituted). In view of the higher durability (i.e., luminescence life-span), and the like., R¹⁴ may be a hydrogen atom (i.e., unsubstituted), an alkyl group having 1 to 3 carbon atoms, or an aryl group having 6 to 10 carbon atoms, such as, for example, a methyl group or a phenyl group. For example, R¹⁴, other than a hydrogen atom, that is, for example, an alkyl group having 1 to 3 carbon atoms (i.e., a methyl group) or a phenyl group is easy to the substitution of an electron (i.e., unstable to anion), and thus may be present at the third position (i.e., para-position with respect to the nitrogen atom) of the carbazole ring.

In Chemical Formula 1, L¹ is a substituted or unsubstituted aromatic ring group having 6 to 15 ring-forming atoms. Here, as the aromatic ring group, groups derived from benzene, pentalene, indene, naphthalene, azulene, heptalene, acenaphthene, phenanthrene, biphenyl, fluorene, or the like, or a combination thereof may be exemplified. Among them, L¹ may be a group derived from a compound that is benzene, biphenyl, or fluorene (e.g., fluorene with the binding sites at positions 3 and 6), for example, L¹ may be a group derived from benzene or biphenyl, or for example, L¹ may be a group derived from benzene. If L¹ is a substituted aromatic ring group, the substituent may be an alkyl group or a phenyl group, for example, an alkyl group, such as, for example, a methyl group, an ethyl group, an n-propyl group, an isopropyl group, or the like, for example, methyl group or ethyl group, or for example, a methyl group. In some embodiments, L¹ may a benzene-derived group unsubstituted or substituted with a methyl group, an ethyl group, an n-propyl group, or an isopropyl group, a biphenyl-derived group unsubstituted or substituted with a methyl group, an ethyl group, an n-propyl group, or an isopropyl group, or a fluorene-derived group substituted with a methyl group, an ethyl group, an n-propyl group, or an isopropyl group at the 9^{th} position (i.e., a fluorene having 3^{rd} and 6^{th} positions as linking positions). For example, L¹ may a benzene-derived group or biphenyl-derived group unsubstituted or substituted with a methyl group or an ethyl group. In some embodiments, L¹ may be a benzene-derived group unsubstituted or substituted with 1 or 2 methyl groups, or a biphenyl-derived group unsubstituted or substituted with 1 or 2 methyl groups. In some embodiments, L¹ may a benzene-derived group unsubstituted or substituted with 1 or 2 methyl groups. In an example, L¹ may be an unsubstituted benzene-derived group (o-, m-, or p-phenylene group), or for example, a p-phenylene group. Such L¹ may allow the polymeric compound to achieve higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability).

In Chemical Formula 1, L¹ may be linked to any position of the carbazole ring having the substituent “FG”, as depicted in Group 1:

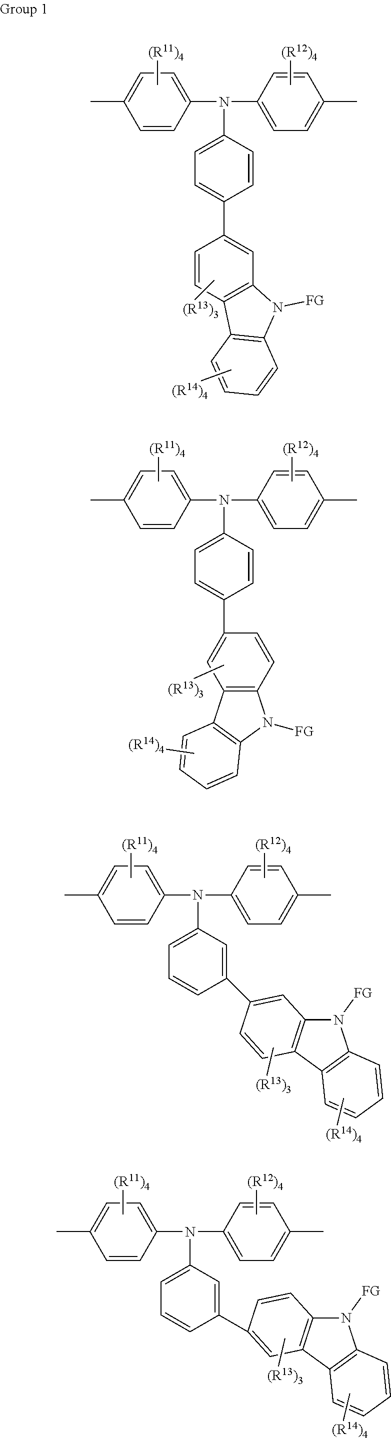

Among them, in view of higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability), L¹ may be linked to the carbazole ring having the substituent “FG”, as described below:

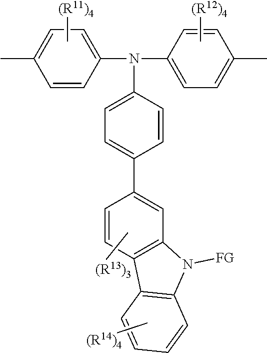

In Chemical Formula 1, FG is represented by one of Chemical Formula 3 to Chemical Formula 5. In view of higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability), FG may be represented by any of Chemical Formula 3 to Chemical Formula 5, and for example, may be represented by Chemical Formula 3:

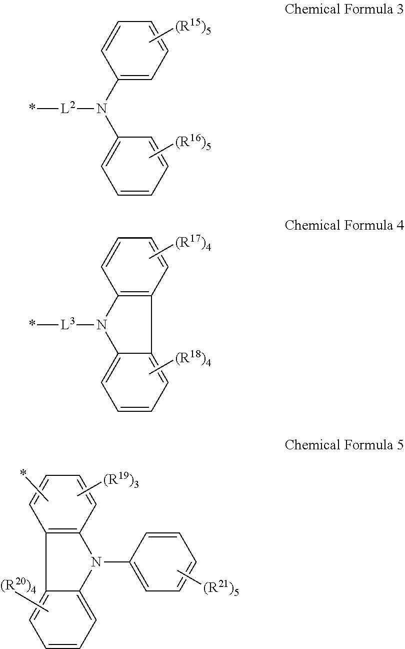

In Chemical Formula 3, L² is a substituted or unsubstituted aromatic ring group having 6 to 15 ring-forming atoms. Here, as the aromatic ring group of L² may be the same as the groups of L¹ of Chemical Formula 1. If L² is not substituted, L² may be a benzene-derived or a biphenyl-derived group, for example, a benzene-derived group. If L² is a substituted aromatic ring group, the substituent may be an alkyl group or a phenyl group, for example, an alkyl group, such as, for example, a methyl group, an ethyl group, an n-propyl group, an isopropyl group, or the like, for example, a methyl group or an ethyl group, or for example, a methyl group. L² may a benzene-derived group unsubstituted or substituted with a methyl group, an ethyl group, an n-propyl group, or an isopropyl group, or a biphenyl-derived group unsubstituted or substituted with a methyl group, an ethyl group, an n-propyl group, or an isopropyl group. For example, L² may a benzene-derived group or biphenyl-derived group unsubstituted or substituted with a methyl group or an ethyl group. L² may a benzene-derived group unsubstituted or substituted with 1 or 2 methyl groups, or a biphenyl-derived group unsubstituted or substituted with 1 or 2 methyl groups. Or, for example, L² may a benzene-derived group unsubstituted or substituted with 1 or 2 methyl groups. In an example, L² may be an unsubstituted benzene-derived group (o-, m-, or p-phenylene group), or for example, a p-phenylene group. Such L² may render the polymeric compound to achieve higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability).

In Chemical Formula 3, R¹⁵ and R¹⁶ may each independently be a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, a substituted or unsubstituted heteroaromatic ring group having 5 to 20 ring-forming atoms. Each R¹⁵ may be the same as or different from each other. Each R¹⁶ may be the same as or different from each other. Further, each of R¹⁵ and R¹⁶ may be the same as or different from each other.

Here, specific examples of the halogen atom, the alkyl group, the cycloalkyl group, the alkoxy group, and the cycloalkoxy group as R¹⁵ and R¹⁶ may be the same as those defined as a “substituent”. Further, specific examples of the aromatic ring group as R¹⁵ and R¹⁶ may be the same as those defined for L¹. Specific examples of the heteroaromatic ring group having 5 to 20 ring-forming atoms as R¹⁵ and R¹⁶ may be derived from a heteroaromatic compound, such as, for example, acridine, phenazine, benzoquinoline, benzo isoquinoline, phenanthridine, phenanthroline, anthraquinone, fluorenone, dibenzofuran, dibenzothiophene, carbazole, imidazophenanthridine, benzimidazophenanthridine, azadibenzofuran, 9-phenyl carbazole, azacarbazole, azadibenzothiophene, diazadibenzofuran, diazacarbazole, diazadibenzothiophene, xanthone, thioxanthone, pyridine, quinoline, anthraquinone, or the like.

Among them, in view of higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability), R¹⁵ and R¹⁶ may each independently be a hydrogen atom, a straight alkyl group having 1 to 8 carbon atoms, or a branched alkyl group having 3 to 8 carbon atoms, for example, a hydrogen atom, or a straight alkyl group having 1 to 3 carbon atoms, or for example, a hydrogen atom (unsubstituted).

In Chemical Formula 3, * indicates a linking position to nitrogen atom.

In Chemical Formula 4, L³ is a substituted or unsubstituted aromatic ring group having 6 to 15 ring-forming atoms. Here, non-limiting examples of the aromatic ring group of L³ may be the same as the groups of L¹ of Chemical Formula 1. If L³ is not substituted, L³ may be a benzene-derived group or a biphenyl-derived group, or for example, a benzene-derived group. If L³ is a substituted aromatic group, the substituent may be an alkyl group or a phenyl group, for example, an alkyl group, such as, for example, a methyl group, an ethyl group, an n-propyl group, an isopropyl group, or the like, for example, a methyl group or an ethyl group, or for example, a methyl group. That is, L³ may a benzene-derived group unsubstituted or substituted with a methyl group, an ethyl group, an n-propyl group, or an isopropyl group, or a biphenyl-derived group unsubstituted or substituted with a methyl group, an ethyl group, an n-propyl group, or an isopropyl group. For example, L³ may a benzene-derived group or biphenyl-derived group unsubstituted or substituted with a methyl group or an ethyl group. L³ may a benzene-derived group unsubstituted or substituted with 1 or 2 methyl groups, or a biphenyl-derived group unsubstituted or substituted with 1 or 2 methyl groups. Or, for example, L³ may a biphenyl-derived group unsubstituted or substituted with 1 or 2 methyl groups. For example, L³ may be an unsubstituted biphenyl-derived group (e.g., a 4,4′-biphenylene group, a 3,4′-biphenylene group, a 2,4′-biphenylene group, a 3,3′-biphenylene group, a 2,3′-biphenylene group, or a 2,6′-biphenylene group). In an example, L³ may be 4,4′-biphenylene group. Such L³ may render the polymeric compound to achieve higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability).

In Chemical Formula 4, R¹⁷ and R¹⁸ are each independently a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, or a substituted or unsubstituted heteroaromatic ring group having 5 to 20 ring-forming atoms. Each R¹⁷ may be the same as or different from each other. Each R¹⁸ may be the same as or different from each other. Further, each of R¹⁷ and R¹⁸ may be the same as or different from each other.

Here, non-limiting examples of the halogen atom, the alkyl group, the cycloalkyl group, the alkoxy group, and the cycloalkoxy group as R¹⁷ and R¹⁸ may be the same as those defined as a “substituent”. Further, specific examples of the aromatic ring group as R¹⁷ and R¹⁸ may be the same as those defined for L¹. Specific examples of the heteroaromatic ring group having 5 to 20 ring-forming atoms as R¹⁷ and R¹⁸ may be the same as those defined for R¹⁵ and R¹⁶.

Among them, in view of higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability), R¹⁷ and R¹⁸ may each independently be a hydrogen atom, a straight alkyl group having 1 to 8 carbon atoms, or a branched alkyl group having 3 to 8 carbon atoms, for example, a hydrogen atom, or a straight alkyl group having 1 to 3 carbon atoms, or for example, a hydrogen atom (unsubstituted).

In Chemical Formula 4, * indicates a linking position to the nitrogen atom.

In Chemical Formula 5, R¹⁹ to R²¹ are each independently a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, or a substituted or unsubstituted heteroaromatic ring group having 5 to 20 ring-forming atoms. Each R¹⁹ may be the same as or different from each other. Each R²⁰ may be the same as or different from each other. Also, each R²¹ may be the same as or different from each other. Further, each of R¹⁹ to R²¹ may be the same as or different from each other.

Here, non-limiting examples of the halogen atom, the alkyl group, the cycloalkyl group, the alkoxy group, and the cycloalkoxy group as R¹⁹ to R²¹ may be the same as those defined as a “substituent”. Further, specific examples of the aromatic ring group as R¹⁹ to R²¹ may be the same as those defined for L¹. Specific examples of the heteroaromatic ring group having 5 to 20 ring-forming atoms as R¹⁹ to R²¹ may be the same as those defined for R¹⁵ and R¹⁶.

Among them, in view of higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability), R¹⁹ and R²⁰ may each independently be a hydrogen atom, a straight alkyl group having 1 to 8 carbon atoms, or a branched alkyl group having 3 to 8 carbon atoms, for example, a hydrogen atom (i.e., unsubstituted), or a straight alkyl group having 1 to 3 carbon atoms, or for example, a hydrogen atom (unsubstituted). Further, in view of much higher hole injection property (and as a result, luminous efficiency) into the LED (i.e., QLED), higher durability (i.e., luminescence life-span), lower driving voltage, good film-forming properties, or a good balance of at least two properties thereof (such as, for example, a good balance of hole injection property and durability), R²¹ may be a straight alkyl group having 3 to 10 carbon atoms, or a branched alkyl group having 3 to 15 carbon atoms, for example, a straight or branched alkyl group having 3 to 10 carbon atoms, for example, a straight alkyl group having 4 to 6 carbon atoms, or for example, a straight alkyl group having 5 carbon atoms, i.e., n-pentyl group. Further, when the group for R²¹ is other than a hydrogen atom, the site for substitution of R²¹ may be any of o-, m-, or p-position with respect to the position of the nitrogen atom in the carbazole ring, for example, p- or m-position, or, for example, p-position with respect to the nitrogen atom of the carbazole ring. Such position of R²¹ may render the polymeric compound to achieve higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability).

In Chemical Formula 5, * indicates a linking position to the nitrogen atom.

Here, the group of Chemical Formula 5 may also be linked to any point with respect to the nitrogen atom of the carbazole ring of Chemical Formula 1, as depicted in Group 2:

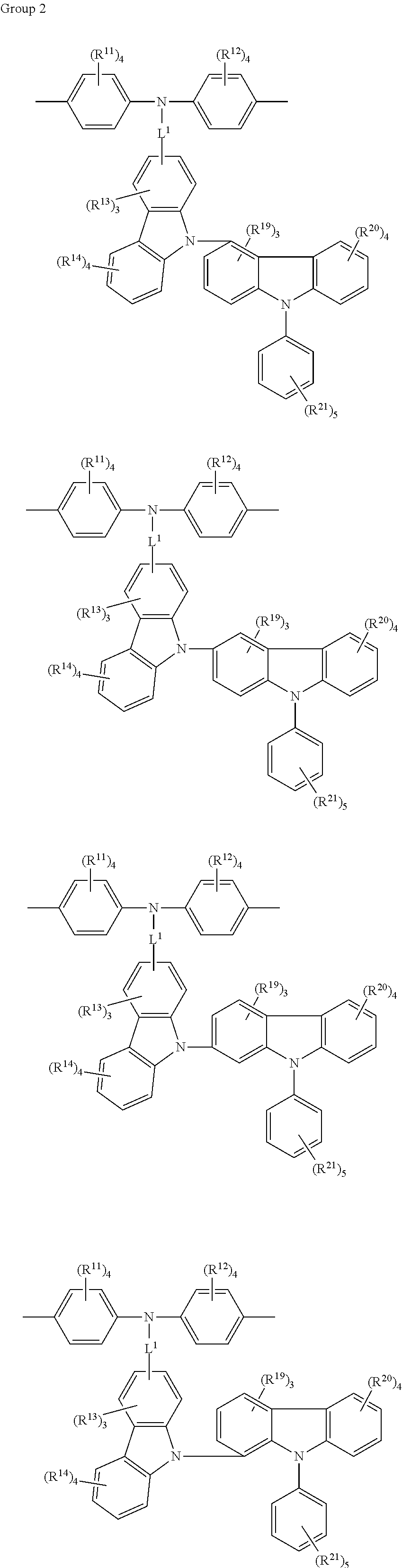

Among them, in view of higher hole injection property (and as a result, luminous efficiency) into the LED (i.e., QLED), a higher durability (i.e., luminescence life-span), a lower driving voltage, good film-forming properties, or a good balance of at least two properties thereof (such as, for example, a good balance of hole injection property and durability), the group of Chemical Formula 5 may be linked to the nitrogen atom of the carbazole ring, as shown below:

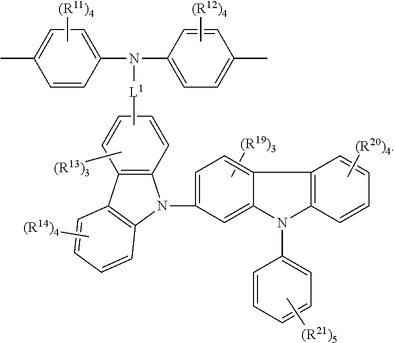

In one or more embodiments, L¹ of Chemical Formula 1, L² of Chemical Formula 3, and L³ of Chemical Formula 4 may each independently be at least one of Chemical Formulae (7-1) to (7-24). The symbol ** in Chemical Formulae (7-1) to (7-24) indicates the position linked to the nitrogen atom. Specifically, ** indicates a position linked to the nitrogen atom in the main chain (i.e., in the case of L¹), or to the nitrogen atom of the carbazole ring which is a side chain linked to the main chain via L¹ in Chemical Formula 1 (in the case of L² and L³). The symbol *** in Chemical Formulae (7-1) to (7-24) indicates a position linked to a carbon atom or a nitrogen atom. Specifically, *** indicates a position linked to a carbon atom of the carbazole ring which is a side chain linked to the main chain via L¹ in Chemical Formula 1 (in the case of L¹), or to a nitrogen atom of Chemical Formula 3 or Chemical Formula 4 (in the case of L² and L³). In some embodiments, L¹ of Chemical Formula 1 may be represented by Chemical Formula (7-1) or Chemical Formula (7-14), and for example, may be represented by Chemical Formula (7-1). In some embodiments, L² of Chemical Formula 3 may be represented by Chemical Formula (7-1) or Chemical Formula (7-4), and for example, may be represented by Chemical Formula (7-4):

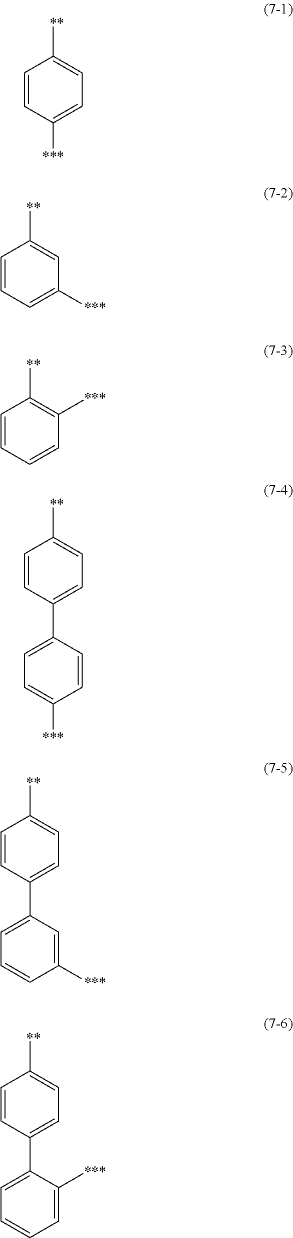

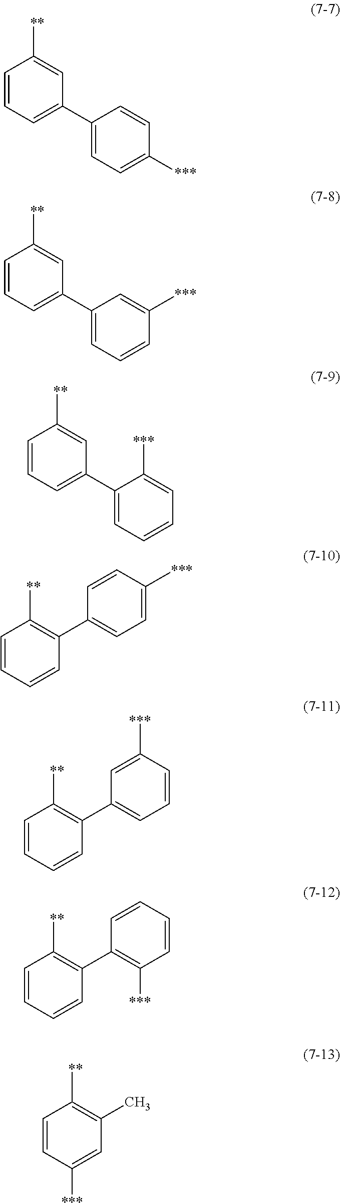

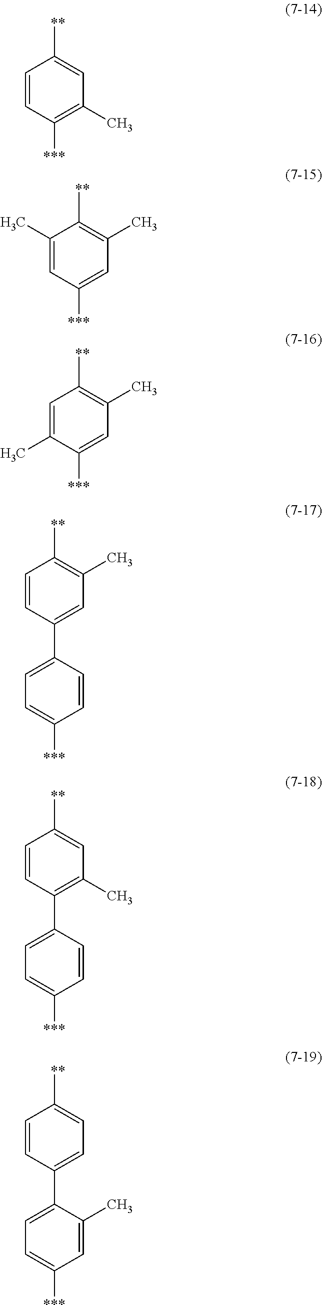

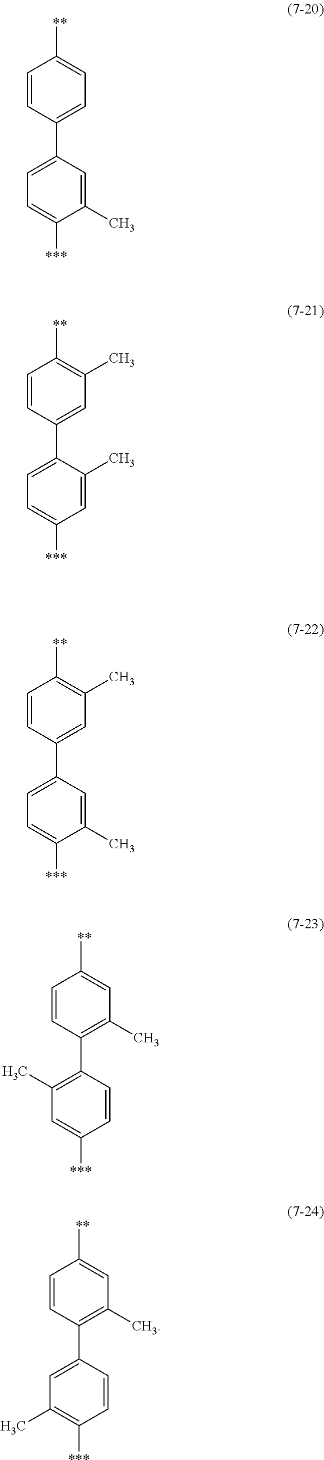

Structural unit (A) of the polymeric compound according to one or more embodiments may be represented by one of the structural units in Group 3. R²¹ of the structural units in Group 3 may be defined by the same as in Chemical Formula 5.

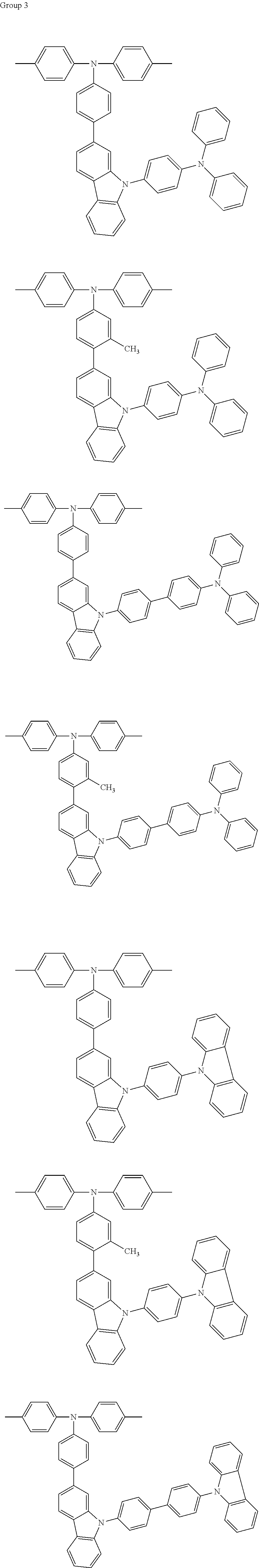

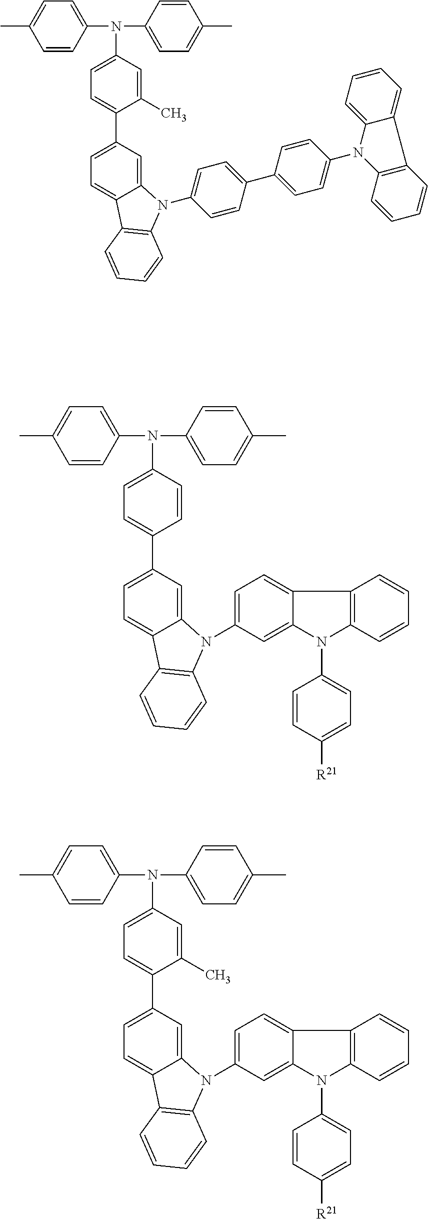

### Structural Unit B

The polymeric compound includes a structural unit (B) represented by Chemical Formula 2, in addition to the structural unit (A) represented by Chemical Formula 1. An electroluminescence device including the polymeric compound including structural unit (A) and structural unit (B) has excellent hole injection property (e.g., into the quantum dots), and a broad light-emitting region in the light-emitting layer. Accordingly, an electroluminescence device according to various embodiments may have a good light-emitting efficiency and durability (i.e., luminescence life-span), as well as achieve high current efficiency and a low driving voltage.

The polymeric compound according to various embodiments may include only one type of structural unit (B), or may include two or more types of structural units (B). If the polymeric compound according to some embodiments includes two or more types of structural units (B), the plurality of structural units (B) may exist in a block form (i.e., as a block copolymer), a random form (i.e., as a random copolymer), an alternating form (i.e., as an alternating copolymer), or a periodic form (i.e., a periodic copolymer).

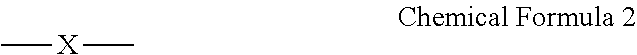

In Chemical Formula 2, X is an aromatic ring group having 6 to 30 carbon atoms, which may be substituted or unsubstituted with a hydrocarbon group having 1 to 14 carbon atoms, or an aromatic ring group having 4 to 30 carbon atoms and at least one heteroatom, which may be substituted or unsubstituted with a hydrocarbon group having 1 to 14 carbon atoms.

In view of higher injection properties (and as a result, luminous efficiency) into LED (i.e., QLED), higher durability (i.e., luminescence life-span), lower driving voltage, good film-forming properties, or a good balance of at least two properties thereof (such as, for example, a good balance of hole injection property and durability), X may be an aromatic ring group having 6 to 24 carbon atoms, which may be substituted or unsubstituted with a hydrocarbon group having 1 to 14 carbon atoms. Here, as the hydrocarbon group (unsubstituted) that can exist in the structural unit “—X—”, examples include straight or branched alkyl groups with 1 to 14 carbon atoms, cycloalkyl groups with 3 to 14 carbon atoms, straight-chain or branched alkenyl groups with 2 to 14 carbon atoms, and straight-chain or branched alkynyl groups with 2 to 14 carbon atoms. Specific examples are the same as those mentioned above. Among these, in view of higher hole injection ability (and thus, luminous efficiency), higher durability (for example, luminous life-pan), lower driving voltage, good film-forming properties, and a better balance of at least two properties thereof (for example, a good balance between hole injection property and durability) in an LED (for example, QLED), the hydrocarbon group (unsubstituted) that can exist in the structural unit “—X—” may be a straight or branched saturated hydrocarbon group with 1 to 14 carbon atoms, for example, a straight alkyl group with 4 to 14 carbon atoms, for example, a straight alkyl group with 8 to 12 carbon atoms (n-octyl group, n-nonyl group, n-decyl group, n-undecyl group, n-dodecyl group, or the like), or for example, a straight alkyl group with 8 to 10 carbon atoms (n-octyl group, n-nonyl group, n-decyl group, or the like).

Furthermore, the structural unit “—X—” may be aromatic ring group such as the chemical groups of L¹ in Chemical Formula 1. Among these, when X is unsubstituted, X may be derived from a compound that is benzene, biphenyl, terphenyl, fluorene, dibenzofuran, or the like, or any combination thereof. For example, it may be derived from benzene, fluorene, or a combination of benzene and fluorene. Specifically, X may be a group derived from benzene, a group derived from fluorene, or a group where two benzene rings are introduced into fluorene, and for example, it may be a group derived from fluorene.

In addition, as the heteroatom that may be included in the aromatic ring group that further includes a heteroatom, examples include oxygen atom, nitrogen atom, sulfur atom, silicon atom, selenium atom, or the like. For example, as the aromatic ring group that may include a heteroatom, structures shown in Group 4 below may be exemplified.

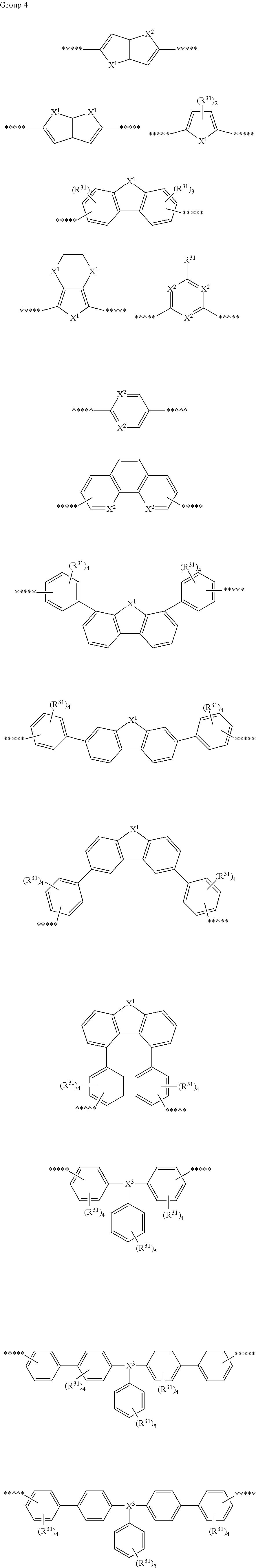

In Group 4, each X¹ may independently be a carbon atom (—C(R³²)₂—), an oxygen atom (—O—), a nitrogen atom (—NH), a sulfur atom (—S—), or a selenium atom (—Se—). If multiple X¹ are present in each structure, each X¹ may be the same or different from one another, but, for example, they may be the same as each other. Among these, X¹ may represent a carbon atom (—C(R³²)₂—) or an oxygen atom, and, for example, may be a carbon atom (—C(R³²)₂—) or an oxygen atom. When X¹ is a carbon atom (—C(R³²)₂—), R³² may each independently be a substituted or unsubstituted linear or branched saturated or unsaturated hydrocarbon group having 1 to 14 carbon atoms, or a substituted aromatic ring group having 6 to 20 carbon atoms or 6 to 10 carbon atoms. If multiple R³² are present within each structure, each R³² may be the same or different, and, for example, may be the same. Specific examples of the hydrocarbon group having 1 to 14 carbon atoms (unsubstituted) as R³² are defined in the same way as the “hydrocarbon group having 1 to 14 carbon atoms” present as a substituent in the aforementioned structural unit (B), which represents —X—.

When X¹ is a carbon atom (—C(R³²)₂—), each R³² may independently be a bridging group as shown in Group 5 below. For example, when using a polymeric compound according to some embodiments in a hole injection layer, the polymeric compound may partially include a structural unit B in which R³² may be a bridging group as shown in Group 5 below. In the following structures, R³³ may be a single bond or a linear or branched alkylene group having 1 to 12 carbon atoms. Non-limiting examples of the alkylene group having 1 to 12 carbon atoms as R³³ may include a methylene group, an ethylene group, an n-propylene group, an isopropylene group, an n-butylene group, an isobutylene group, a sec-butylene group, a tert-butylene group, an n-pentylene group, an isopentylene group, a tert-pentylene group, a neopentylene group, an n-hexylene group, an isohexylene group, an n-heptylene group, an n-octylene group, an n-nonylene group, an n-decylene group, an isodecylene group, an n-undecylene group, an n-dodecylene group, or the like. Among these, in view of new improvements in hole injection properties, the content of the structural unit B, in which R³² represents a bridging group as shown below, may be, for example, from about 2 mol % to about 20 mol %, for example, from about 5 mol % to about 10 mol %, based on a total mole number of the structural units B. When the polymeric compound according to some embodiments include two or more kinds of structural units B in which R³² represents a bridging group as shown below, the content of the structural units refers to the total amount of these structural units.

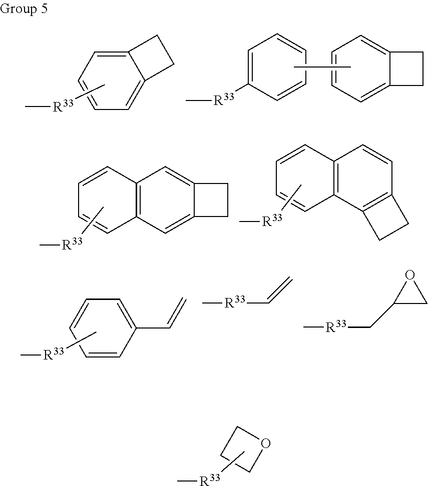

In Group 4, X² may independently be a nitrogen atom (—N═) or —SiR¹⁹═. When multiple X² exist in each structure, each X² may be the same or different, but, for example, they may be the same as each other. Among these, X² may represent a nitrogen atom.

In Group 4, X³ may be a nitrogen atom.

In Group 4, R³¹ may independently be a hydrogen atom or a substituted or unsubstituted saturated hydrocarbon group with a straight or branched chain having 1 to 14 carbon atoms. If multiple R³¹ are present in each structure, each R³¹ may be the same or different from each other, for example, they may be the same as each other.

In Group 4, ***** indicates a linking portion.

According to some embodiments, X in Chemical Formula 2 may be one of the following chemical formulae (8-1) to (8-22). In the chemical formulae (8-1) to (8-22), each R³¹ may independently be a hydrogen atom, a substituted or unsubstituted saturated hydrocarbon group with a straight chain of 1 to 14 carbon atoms, or a substituted or unsubstituted branched saturated hydrocarbon group with 3 to 14 carbon atoms, with specific examples as defined above.

Each R³² may independently be a substituted or unsubstituted saturated hydrocarbon group with a straight chain of 1 to 14 carbon atoms, or a substituted or unsubstituted saturated hydrocarbon group with a branched chain of 3 to 14 carbon atoms, with specific examples defined as mentioned above. The symbol **** indicates a linking position.

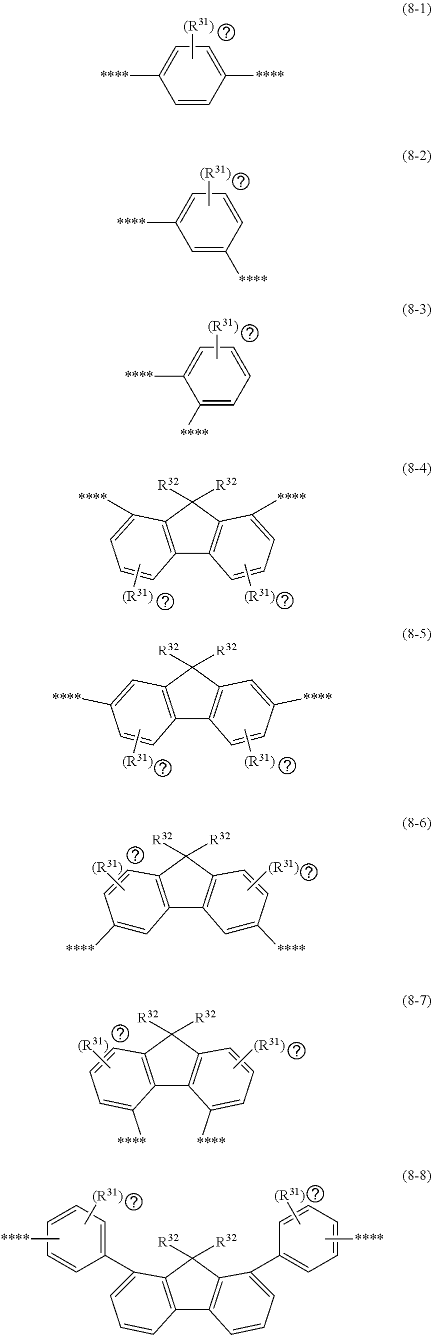

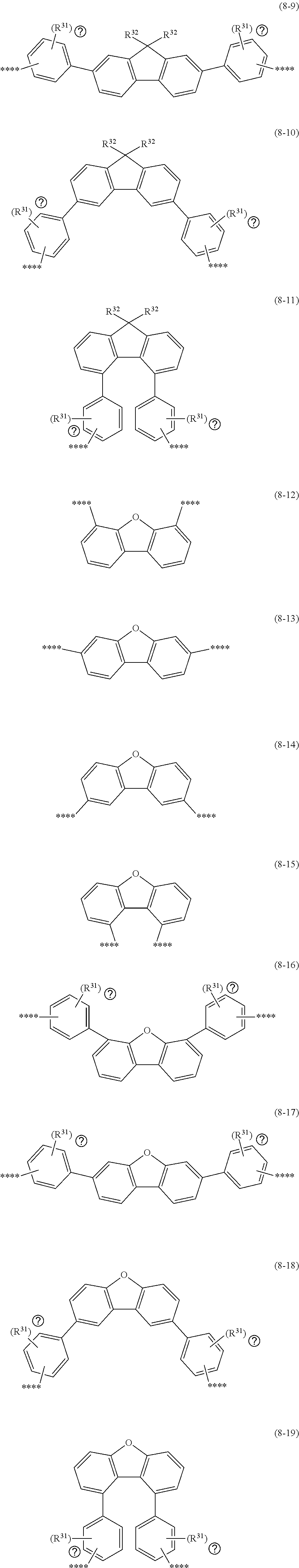

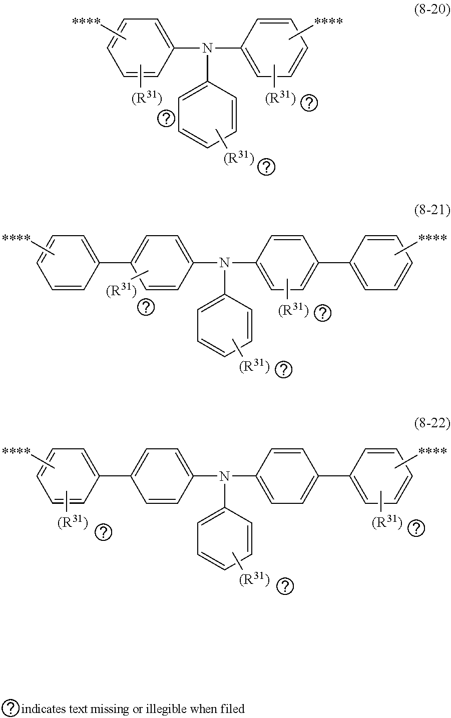

In some embodiments, the composition of structural unit A in the polymeric compound is not limited, for example. In view of higher hole injection capability (and thus luminous efficiency) of an LED (for example, a QLED), higher durability (for example, luminous life-span), lower driving voltage, good film-forming properties, and a better balance of at least two properties thereof (for example, a better balance of hole injection capability and durability), structural unit A may be included in an amount of about 10 mol % to about 90 mol % based on a total moles of all structural units constituting the polymeric compound, for example, about 40 mol % to about 60 mol %, for example, about 50 mol %. If the polymeric compound includes two or more structural units A, the content of structural units A refers to the total amount of structural units A.

In some embodiments, the composition of structural unit B in the polymeric compound is not limited, for example. In view of higher hole injection capability (and thus luminous efficiency) of an LED (for example, a QLED), higher durability (for example, luminous life-span), lower driving voltage, good film-forming properties, and a better balance of at least two properties thereof (for example, a better balance of hole injection capability and durability), structural unit B may be included in an amount of about 10 mol % to about 90 mol % based on a total moles of all structural units constituting the polymeric compound, for example, about 40 mol % to about 60 mol %, for example, about 50 mol %. If the polymeric compound includes two or more structural units B, the content of structural units B refers to the total amount of structural units B.

In one or more embodiments, the polymeric compound may be composed only of structural unit A and structural unit B (that is, the total ratio of structural unit A and structural unit B with respect to the entire structural units is 100 mol %).

In a polymeric compound according to some embodiments, the arrangement of structural unit A and structural unit B may be in blocks (as a block copolymer), randomly arranged (as a random copolymer), or alternately arranged (as an alternating copolymer), for example, they may be alternately arranged (as an alternating copolymer). If the polymeric compound is an alternating copolymer of structural unit A and structural unit B, higher hole injection properties of an LED (for example, QLED), higher durability (for example, emission life-span), lower driving voltage, good film-forming properties, and a better balance of any two or more of these properties (for example, a better balance of hole injection and durability) may be more effectively achieved.

In some embodiments, the polymeric compound may be an alternating copolymer in which structural unit A and structural unit B are alternately present.

That is, the polymeric compound may include a structural unit represented by Chemical Formula 6. For example, the polymeric compound may include a repeating unit represented by Chemical Formula 6. For example, in some embodiments, the polymeric compound may be composed solely of repeating units represented by Chemical Formula 6. In Chemical Formula 6, R¹¹ to R¹⁴, and L¹ and FG are each defined as in Chemical Formula 1, and X is defined as in Chemical Formula 2.

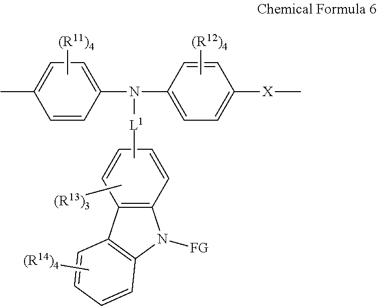

In various embodiments, the polymeric compound may include a structural unit that is represented by one of Group 6 below:

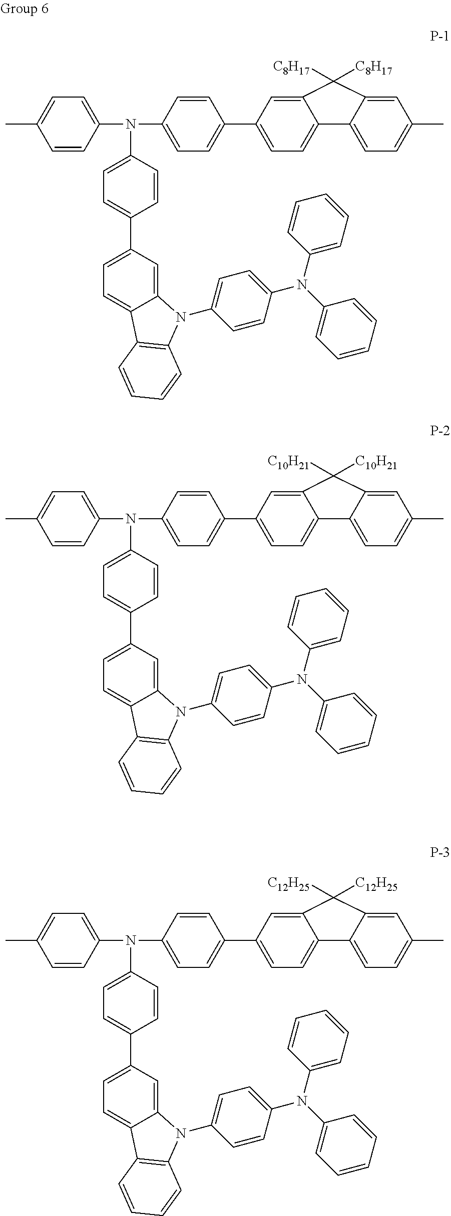

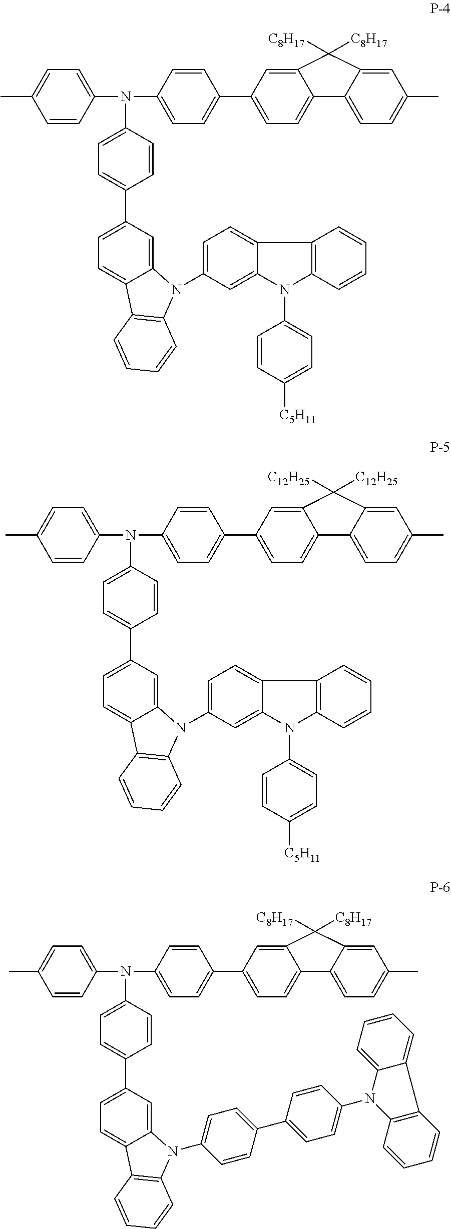

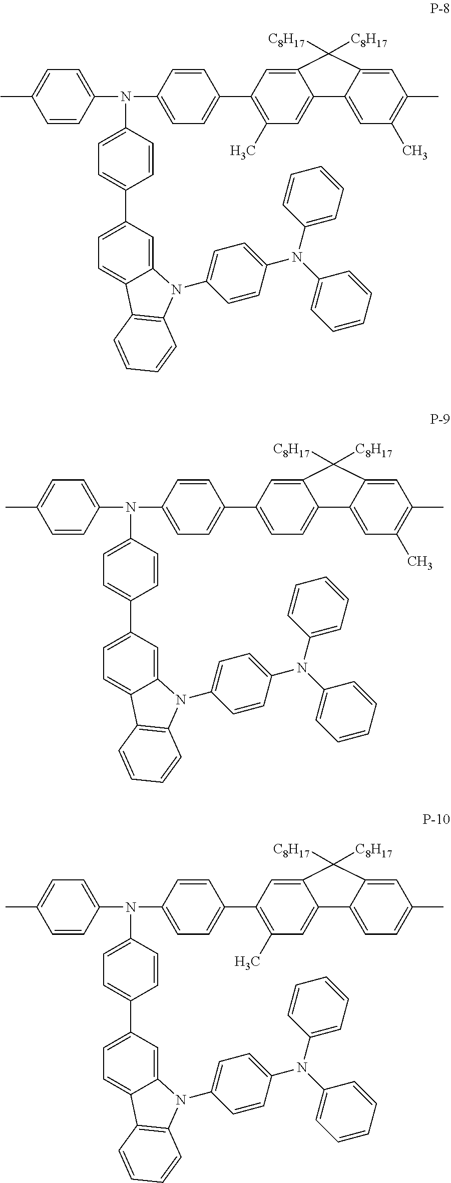

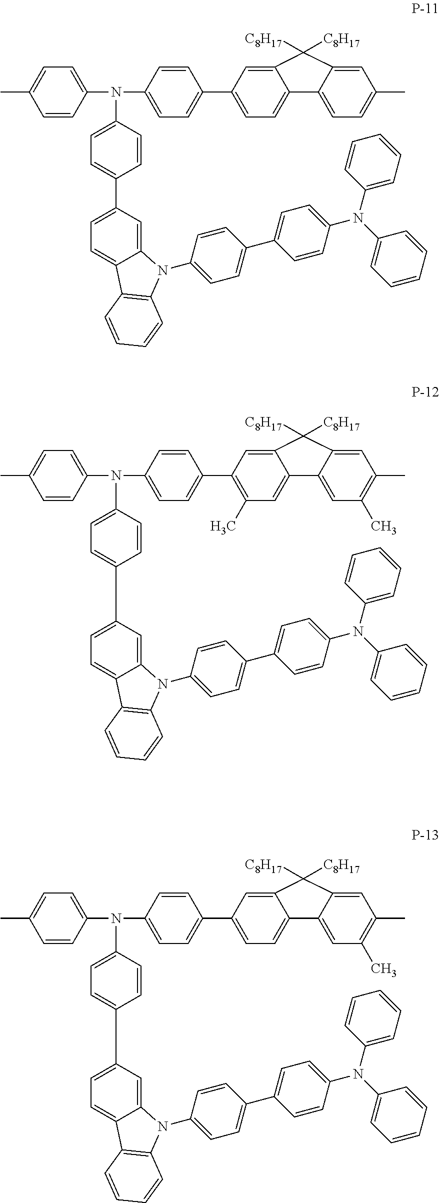

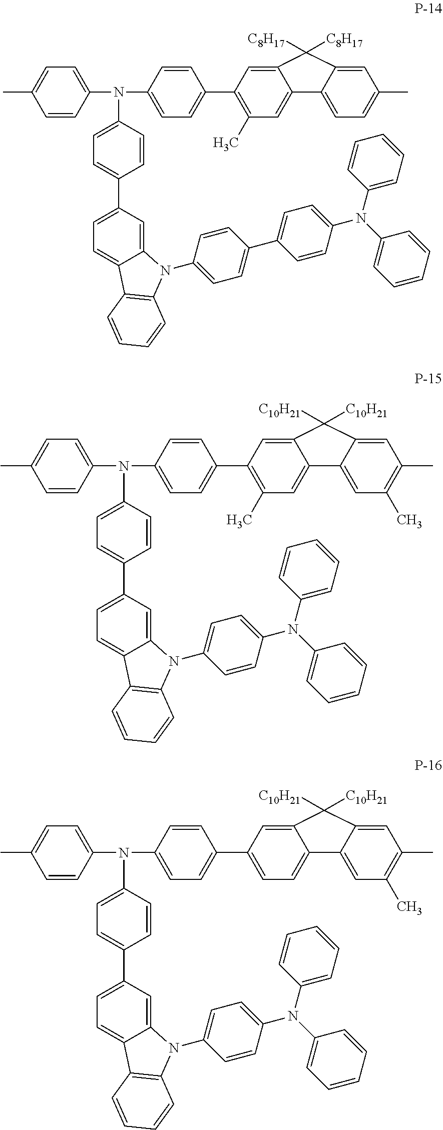

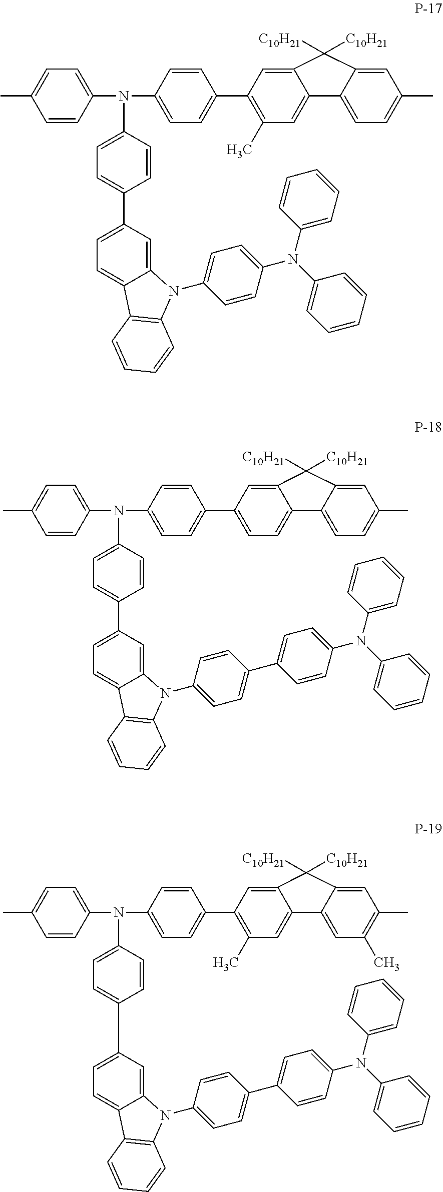

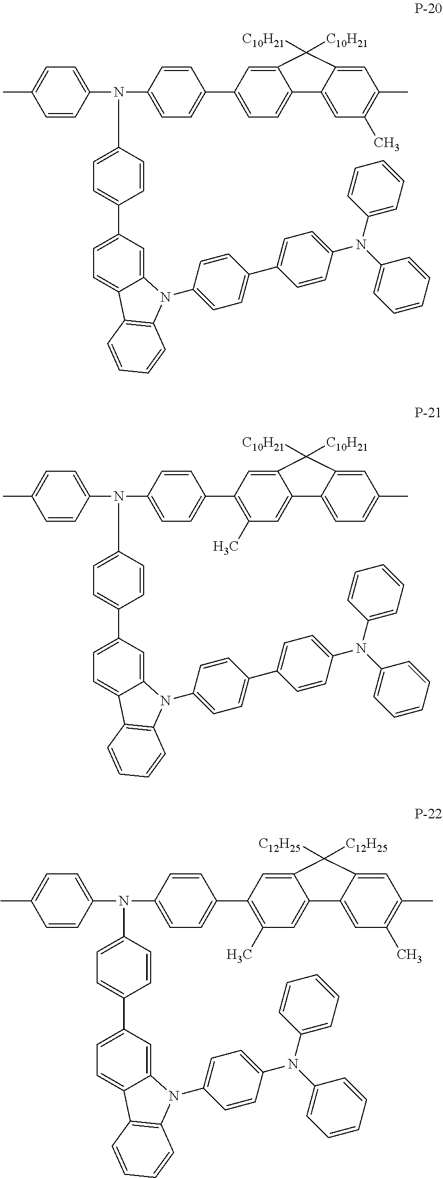

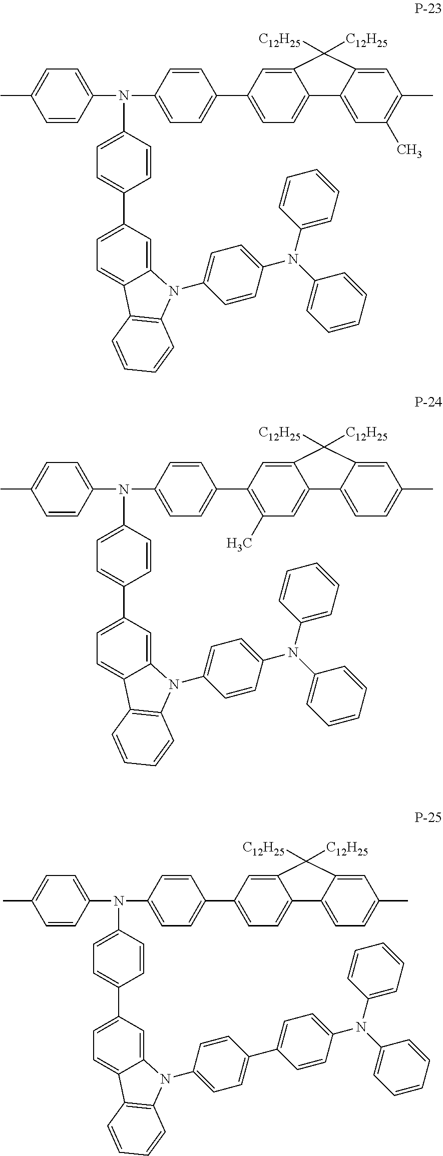

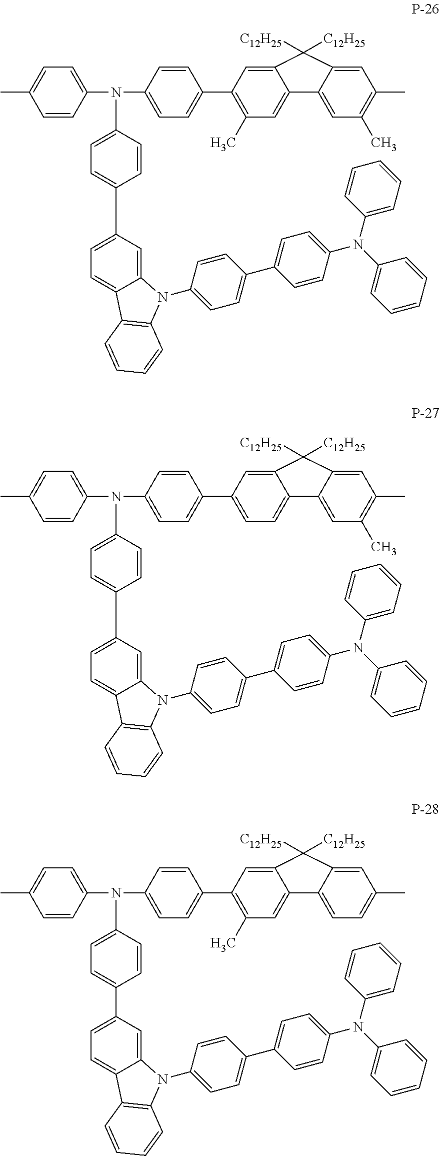

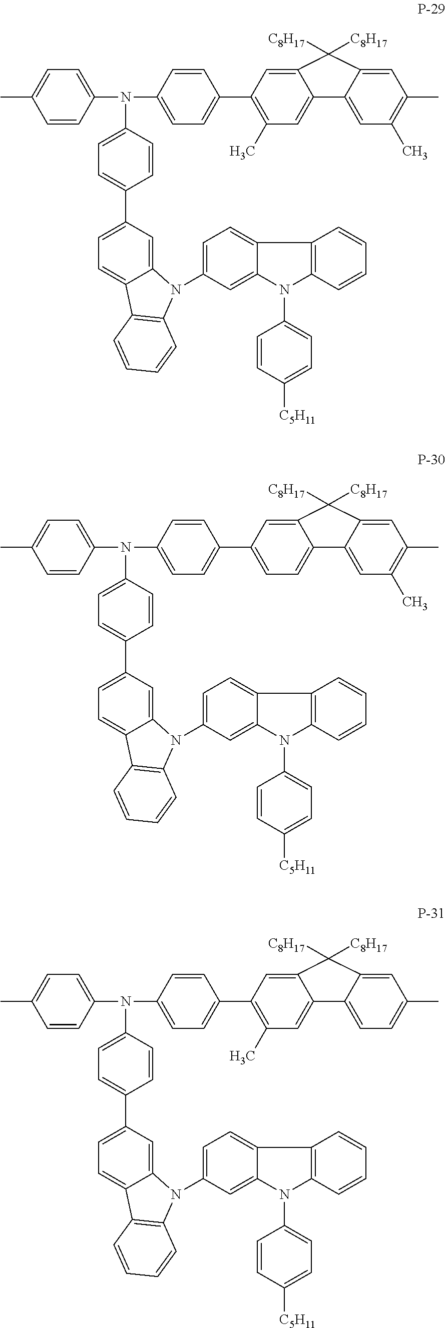

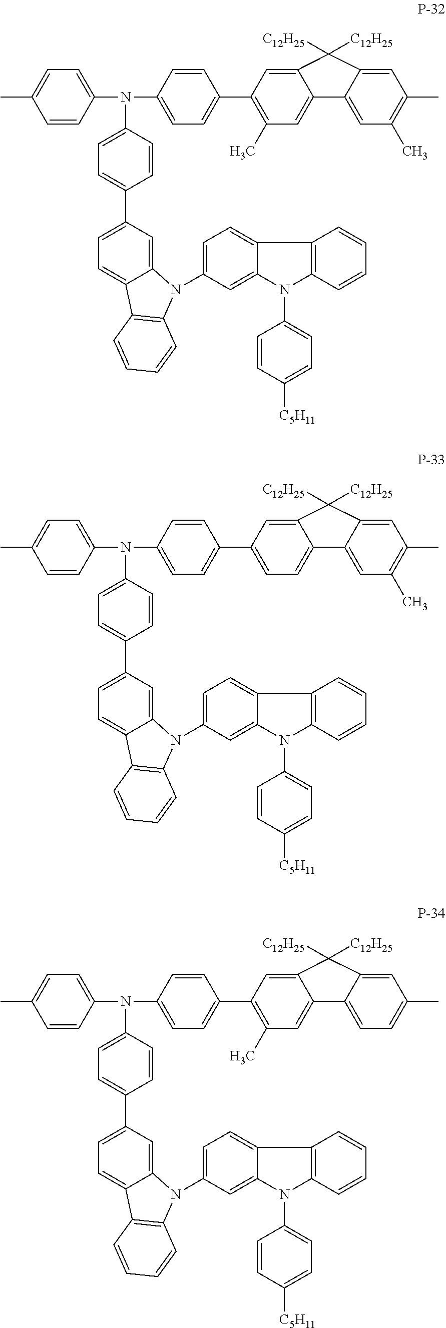

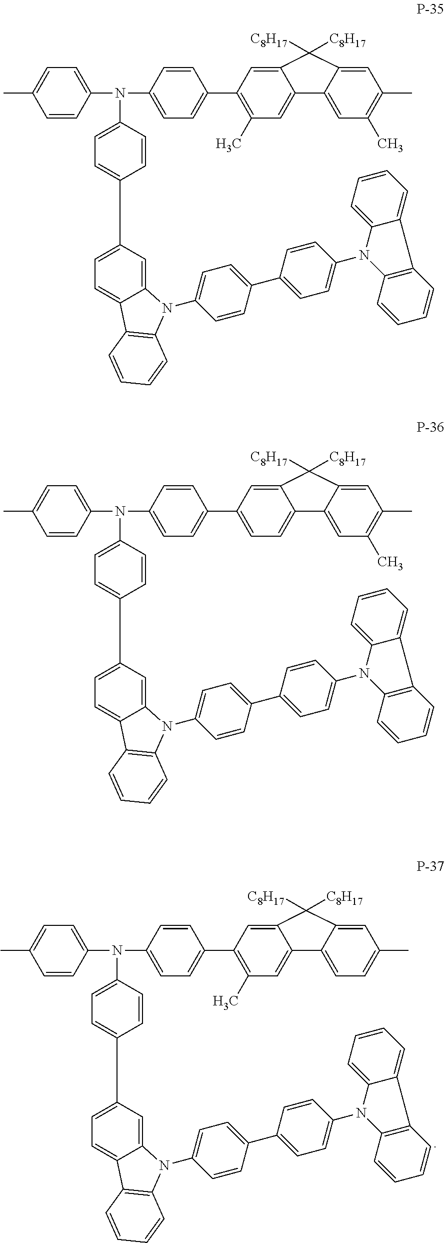

### Other Structural Units

In various embodiments, the polymeric compound may be composed solely of structural unit A and structural unit B. The polymeric compound according to some embodiments may additionally include other structural units (other repeating units) in addition to structural unit A and structural unit B. If the polymeric compound includes other structural units, these other structural units are not particularly limited as long as they do not impair the effects of the present disclosure (for example, the balance of luminous efficiency and durability). For example, structural units such as the following may be exemplified. Hereinafter, the following structural units will be referred to as “structural unit C.”

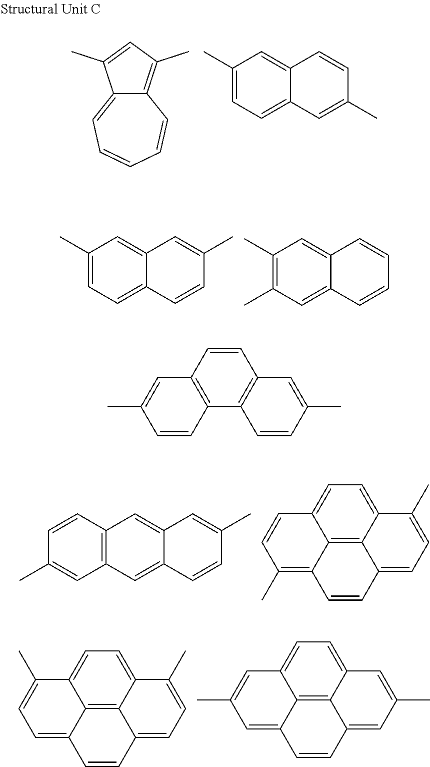

In the polymeric compound according to some embodiments, the composition of structural unit C is not limited, for example. In view of new improvement effects such as ease of film formation and film strength due to the obtained polymeric compound, structural unit C may be included in an amount of about 1 mol % to about 10 mol % based on a total number of moles of structural units constituting the polymeric compound. Additionally, if the polymeric compound contains two or more types of structural unit C, the content of all structural units C refers to the total amount of structural units C.

In some embodiments, a weight average molecular weight (Mw) of the polymeric compound according to one or more embodiments is not limited, as long as the intended effects of the polymeric composition are achieved. The weight average molecular weight (Mw) may be, for example, from about 8,000 Daltons (Da) to about 1,000,000 Da, for example, from about 12,000 Da to about 1,000,000 Da, for example, from about 20,000 Da to about 800,000 Da, or for example, from about 50,000 Da to about 500,000 Da. With such a weight average molecular weight, it may be possible to appropriately adjust the viscosity of the coating solution used to form layers, such as a hole injection layer or a hole transport layer, using the polymeric compound, and/or to form a layer with a uniform film thickness.

In addition, as long as the objective effects of the polymeric composition are achieved, a number average molecular weight (Mn) of the polymeric compound is not particularly limited. The number average molecular weight (Mn) may be, for example, from about 4,000 Da to about 250,000 Da, for example, from about 10,000 Da to about 250,000 Da, for example, from about 20,000 Da to about 150,000 Da, or for example, from about 30,000 Da to about 100,000 Da. With such a number average molecular weight, it may be possible to appropriately adjust the viscosity of the coating solution used to form layers, such as a hole injection layer, a hole transport layer, or the like, and to form layers with a uniform film thickness using the polymeric compound.

The polydispersity index (weight average molecular weight/number average molecular weight) of the polymeric compound according to one or more embodiments may be, for example, from about 1.2 to about 6.0, for instance, from about 1.2 to about 4.0, or for example, from about 1.5 to about 3.5.

As used herein, the measurement of number average molecular weight (Mn) and weight average molecular weight (Mw) can be determined using known methods or suitably modified known methods without limitation. In the present specification, the values measured by the following method are adopted for the number average molecular weight (Mn) and weight average molecular weight (Mw).

On the other hand, the polydispersity index (Mw/Mn) of the polymeric compound is calculated by dividing the weight-average molecular weight (Mw) by the number-average molecular weight (Mn) measured by the following method.

### (Measurement of Number Average Molecular Weight (Mn) and Weight Average Molecular Weight (Mw))

The number average molecular weight (Mn) and weight average molecular weight (Mw) of the polymeric compound may be measured by SEC (Size Exclusion Chromatography) using polystyrene as a standard material under the following conditions:

### SEC Measurement Condition

Analysis equipment (SEC): Shimadzu Corporation, Prominence (registered trademark)
Column: Polymer Laboratories, PLgel MIXED-B
Column temperature: 40° C.
Flow rate: 1.0 mL/min
Injection amount of sample solution: 20 μL (concentration of polymer: about 0.05 mass %)
Eluent: tetrahydrofuran (THF)
Detector (UV-VIS detector): Shimadzu Corporation, SPD-10AV
Standard sample: polystyrene.

The terminal end group of the main chain of the polymeric compound according to the present embodiment is not particularly limited and is appropriately defined depending on the type of raw material used. The terminal end group may be a hydrogen atom or hydrocarbon group, such as, for example, a phenyl group.

### Preparation of Polymeric Compound

The polymeric compound of various embodiments may be synthesized by using a known organic synthesis method. The specific synthesis method of the polymeric compound of the present embodiment may be easily understood by a person of an ordinary skill in the art and by referring to the examples to be described later.

For example, the polymeric compound according to various embodiments may be prepared by a copolymerization reaction using at least one monomer (1) represented by Chemical Formula 1′ and at least one monomer (2) represented by Chemical Formula 2′, or by a copolymerization reaction using one or more monomers (1) represented by the following Chemical Formula 1′, one or more monomers (2) represented by the following Chemical Formula 2′, and other monomers corresponding to the other structural unit C.

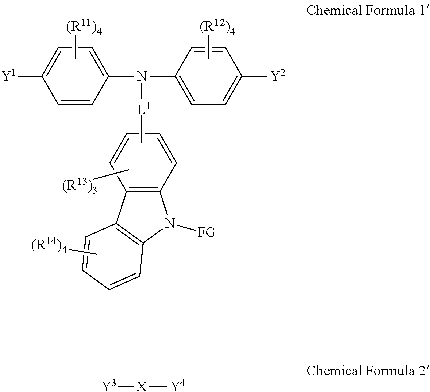

In some embodiments, the polymeric compound may be prepared by a polymerization reaction using one or more monomers (3) represented by Chemical Formula 3′, or by a copolymerization reaction using one or more monomers (3) represented by Chemical Formula 3′ and other monomers corresponding to the structural unit C.

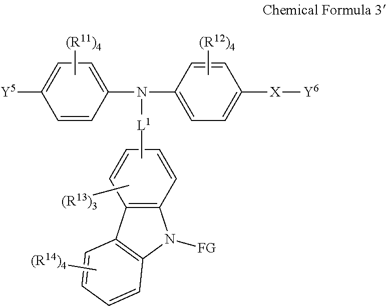

In some embodiments, the monomer that can be used for the polymerization of the polymeric compound can be synthesized by appropriately combining known synthetic reactions, and its structure can also be confirmed by known methods, for example, NMR, LC-MS, etc.

In Chemical Formulae 1′ to 3′, R¹¹ to R¹⁴, and L¹ and FG are each defined in the same way as in Chemical Formula 1, and X is defined in the same way as in Chemical Formula 2. Y¹ and Y², Y³ and Y⁴, and Y⁵ and Y⁶ are each independently a halogen atom (a fluorine atom, a chlorine atom, a bromine atom, an iodine atom, for example, a bromine atom) or a group represented by the following Chemical Formula W:

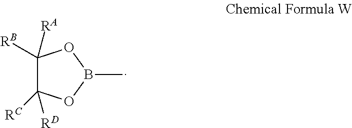

In Chemical Formula W, R^{A} to R^{D} are each independently an alkyl group having 1 to 3 carbon atoms. For example, R^{A} to R^{D} may each be a methyl group.

Y¹ and Y² in Chemical Formula 1′, Y³ and Y⁴ in Chemical Formula 2′, and Y⁵ and Y⁶ in Chemical Formula 3′ may each independently be the same or different from each other. For example, Y¹ and Y² in Chemical Formula 1′ may be the same as each other. For example, Y³ and Y⁴ in Chemical Formula 2′ may be the same as each other. For example, Y⁵ and Y⁶ in Chemical Formula 3′ may be the same as each other.

An electroluminescent device using the polymer compound according to some embodiments as a hole injection material or hole transport material (for example, hole transport material) exhibits excellent luminous efficiency and durability (luminous lifespan).

In some embodiments, the polymeric compound may have a highest occupied molecular orbital (HOMO) level deeper than about −5.20 eV, for example, about −5.50 eV or lower, for example, about −5.55 eV or lower. As a result, the polymeric compound according to one or more embodiments may be suitably used in a quantum dot electroluminescent device (for example, in a hole transport layer). Although the lower limit of the HOMO level of the polymeric compound according to some embodiments is not particularly limited, it may be, for example, about −5.7 eV or greater (for example, about −5.70 eV or greater). As used herein, the HOMO level is a value measured according to the method described in the examples.

In the polymeric compound according to one or more embodiments, the difference between the HOMO level and the HOMO-1 level may be relatively small. For example, a difference (absolute value) between the HOMO level and the HOMO-1 level of the polymeric compound [=|(HOMO-1 (eV))−(HOMO (eV))|]may be less than about 0.59 eV, and for example, it may be about 0.55 eV or less, or for example, it may be about 0.30 eV or less. Since the smaller the difference (absolute value) between the HOMO level and the HOMO-1 level of the polymeric compound according to some embodiments [=J(HOMO-1 (eV))−(HOMO (eV))|], the better, the lower limit is 0 eV (i.e., HOMO level=HOMO-1 level), but it may be permissible if it is, for example, about 0.12 eV or more. As used herein, a difference between the HOMO level and the HOMO-1 level may be a value calculated according to the method described in the examples.

### Material for Electroluminescence Device

The polymeric compound according to some embodiments may be advantageously used as a material for an electroluminescence device. The polymeric compound according to some embodiments may provide a material for an electroluminescence device that balances both luminous efficiency and durability (i.e., has an excellent balance of luminous efficiency and durability (luminous life-span)).

In addition, the polymeric compound according to some embodiments may provide an electroluminescent device material possessing a high triplet energy level (current efficiency) when a low driving voltage is provided. Furthermore, the polymeric compound may exhibit high solubility in solvents, a high heat resistance, and may form a film (thin-filmed) by a wet (coating) method. Consequently, another embodiment provides an electroluminescent device material including the polymeric compound according to one embodiment, or its use as an electroluminescent device material.

### Electroluminescence Device

The polymeric compound according to one or more embodiments may be used in an electroluminescence device. That is, the electroluminescence device may include a pair of electrodes, and at least one layer of an organic film arranged between the pair of electrodes, wherein the at least one layer of the organic film includes a polymeric compound or a material for an electroluminescence device according to some embodiments. Such an electroluminescence device may exhibit excellent luminous efficiency at low driving voltages. Therefore, according to another aspect, an electroluminescence device includes a first electrode, a second electrode, and at least one layer of an organic film arranged between the first electrode and the second electrode, where the at least one layer of the organic film includes a polymeric compound according to one or more embodiments. The purpose (or effect) of one or more embodiments may also be achieved by an electroluminescence device according to this embodiment. In a preferred form of the above embodiment, the electroluminescence device may further include a light emitting layer arranged between the electrodes, where the light emitting layer includes a light-emitting material capable of emitting light from triplet excitons. And, the electroluminescence device of the embodiment is an example of an electroluminescence device according to some embodiments.

In addition, some embodiments provide a method for manufacturing an electroluminescence device including a pair of electrodes and at least one layer of an organic film disposed between the pair of electrodes and including a polymeric compound according to one or more embodiments, where the at least one layer of the organic film is formed by a coating method. In addition, by this method, the present embodiment provides an electroluminescence device in which at least one layer of the organic film is formed by a coating method. In other words, the method according to some embodiments provides a method of manufacturing an electroluminescence device including a first electrode, a second electrode, and at least one layer of an organic film arranged between the first electrode and the second electrode, wherein the at least one layer of the organic film is formed by coating a composition including the polymeric compound according to some embodiments and at least one solvent, and removing the solvent.

The polymeric compound according to some embodiments and the electroluminescence device material (EL device material) according to the present embodiment (hereinafter collectively referred to as “polymeric compound/EL device material”) may have excellent solubility in organic solvents. Accordingly, the polymeric compound/EL device material according to one or more embodiments may be advantageously used in manufacturing of a device (e.g., a thin film) by a coating method (a wet process). Accordingly, according to another embodiment, a composition (i.e., a liquid composition) including a polymeric compound according to one or more embodiments and at least one solvent is provided. The composition is an example of a liquid composition according to one or more embodiments.

In addition, the material for an electroluminescence device according to one or more embodiments as described above, may advantageously be used in the manufacture of a device (e.g., a thin film) by a coating method (a wet process). In view of the above, the present embodiment provides a thin film including a polymeric compound according to one or more embodiments. A thin film like this is an example of a thin film according to one or more embodiments.

In addition, the material for an EL device according to the present embodiment may have excellent hole injection properties and hole mobility. Accordingly, the material may advantageously be used in the formation of an organic film, such as a hole injection material, a hole transport material, or a light emitting material (host). Among these, from the viewpoint of hole transportability, it may advantageously be used as a hole injection material or a hole transport material, or may advantageously be used as a hole transport material.

The present embodiment provides a composition (such as, an electroluminescence device material) including a polymeric compound according to one or more embodiments and at least one material that is a hole transport material, an electron transport material, or a light emitting material. Here, the light emitting material included in the composition is not particularly limited and may contain at least one of semiconductor nanocrystal particles (semiconductor inorganic nanoparticles) or an organometallic complex (i.e., a light-emitting organometallic complex).

Hereinafter, an electroluminescence device according to one or more embodiments will be described in further detail with reference to the FIGURE. The FIGURE is a schematic view showing an electroluminescence device according to one or more embodiments. In the present specification, “electroluminescence device” may be abbreviated as “EL device.”

As shown in the FIGURE, the EL device 100 according to one or more embodiments comprises a substrate 110, a first electrode 120 on the substrate 110, a hole injection layer 130 on the first electrode 120, a hole transport layer 140 on the hole injection layer 130, an emitting layer 150 on the hole transport layer 140, an electron transport layer 160 on the emitting layer 150, an electron injection layer 170 on the electron transport layer 160, and a second electrode 180 on the electron injection layer 170.

Here, the polymeric compound according to one or more embodiments may be included in, for example, an organic film (organic layer) arranged between the first electrode 120 and the second electrode 180. Specifically, the polymeric compound may be included in a hole injection layer 130 as a hole injection material, a hole transport layer 140 as a hole transport material, or a light emitting layer 150 as a light emitting material (host). The polymeric compound may be included in the hole injection layer 130 as a hole injection material or in the hole transport layer 140 as a hole transport material. For example, the polymeric compound may be included in the hole transport layer 140 as a hole transport material. That is, in some embodiments, the organic film including the polymeric compound may be a hole transport layer, a hole injection layer, or a light emitting layer. In some embodiments, the organic film including the polymeric compound may be a hole transport layer or a hole injection layer. In another embodiment, the organic film including the polymeric compound may be a hole transport layer.

In addition, an organic film including a polymeric compound/EL device material according to one or more embodiments may be formed by a coating method (e.g., a solution coating method). For example, the organic film may be formed using a solution coating method such as a spin coat method, a casting method, a micro gravure coat method, a gravure coat method, a bar coat method, a roll coat method, a wire bar coat method, a dip coat method, a spray coat method, a screen printing method, a flexographic printing method, an offset printing method, an ink jet printing method, or the like, but embodiments are not limited thereto.

Any suitable solvent that can dissolve the polymeric compound/EL device material may be used as the solvent used in the solution coating method, and may be appropriately selected depending on the type of polymeric compound used. Non-limiting examples thereof include toluene, xylene, ethylbenzene, diethylbenzene, mesitylene, propylbenzene, cyclohexylbenzene, dimethoxybenzene, anisole, ethoxytoluene, phenoxytoluene, isopropylbiphenyl, dimethylanisole, phenyl acetate, phenyl propionate, methyl benzoate, ethyl benzoate, or cyclohexane, or the like. In addition, an amount of solvent used is not particularly limited, but considering ease of application, etc., the amount is such that the concentration of the polymeric compound may be, for example, greater than or equal to about 0.1 mass % and less than or equal to about 10 mass % or less, or for example, greater than or equal to about 0.5 mass % and less than or equal to about 5 mass %.

There is no particular limitation on the method for forming a film other than an organic film including a polymeric compound/EL device material. A layer other than an organic film including a polymeric compound/EL device material according to an embodiment may be formed by, for example, a vacuum deposition method or a solution coating method.

The substrate 110 may be any suitable substrate used as a general EL device. For example, the substrate 110 may be a semiconductor substrate such as, for example, a glass substrate, a silicon substrate, or a transparent plastic substrate.

The first electrode 120 may be formed on the substrate 110. The first electrode 120 may be, for example, an anode, and may be formed by a metal, an alloy, a conductive compound, or the like, having a relatively large work function.

For example, the first electrode 120 may be formed as a transparent electrode using indium tin oxide (In₂O₃—SnO₂: ITO), indium zinc oxide (In₂O₃—ZnO), tin oxide (SnO₂), zinc oxide (ZnO), or the like, which has excellent transparency and conductivity. Additionally, the first electrode 120 may be formed as a reflective electrode by laminating magnesium (Mg), aluminum (AI), silver (Ag), or the like on the transparent conductive film. Additionally, after forming the first electrode 120 on the substrate 110, if necessary, cleaning and UV-ozone treatment may be performed.

The hole injection layer 130 may be formed on the first electrode 120. The hole injection layer 130 may be a layer that facilitates the injection of holes from the first electrode 120, and specifically, may be formed to have a thickness (a dry film thickness; the same applies hereinafter) of, for example, about 10 nm to about 1000 nm, or for example, about 20 nm to about 50 nm.

The hole injection layer 130 may be formed using a suitable hole injection material. Hole injection materials for forming the hole injection layer 130 may include, for example, poly(ether ketone)-containing triphenylamine (TPAPEK), 4-isopropyl-4′-methyldiphenyliodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(diphenylamino)triphenylamine (TDATA), 4,4′,4″-tris(N,N-2-naphthylphenylamino)triphenylamine (2-TNATA), polyaniline/dodecylbenzenesulphonic acid, poly(3,4-ethylenedioxythiophene)/poly(4-styrenesulfonate): PEDOT/PSS, polyaniline/10-camphorsulfonic acid, or a composition including the following two components:

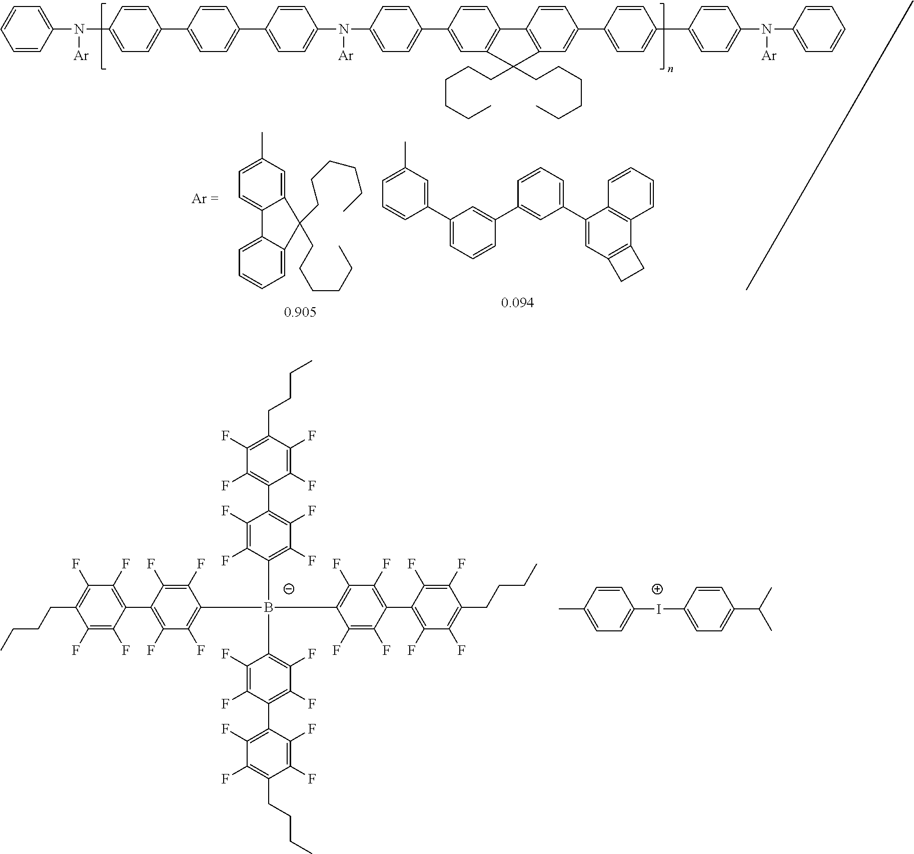

The two components may be present in the composition in a weight ratio of about 100:5.

The hole transport layer 140 may be formed on the hole injection layer 130. The hole transport layer 140 may be a layer having a function of transporting holes, and may be formed with a thickness of, for example, about 10 nm to about 150 nm, for example, about 20 nm to about 50 nm. The hole transport layer 140 may be formed by a solution coating method using the polymeric compound according to one or more embodiments. According to this method, the durability (luminescence life-span) of the EL device 100 may be extended. Additionally, it is possible to improve the current efficiency of the EL device 100 and reduce the driving voltage. In addition, since the hole transport layer may be formed by a solution coating method, a large-area film may be efficiently formed.

When another organic film of the EL device 100 includes the polymeric compound according to an embodiment, the hole transport layer 140 may be formed of a hole transport material. The hole transport materials may include, for example, a carbazole derivative such as 1,1-bis[(di-4-tolylamino)phenyl]cyclohexane (TAPC), N-phenylcarbazole or polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), or the like.

The light emitting layer 150 may be formed on the hole transport layer 140. The light emitting layer 150 may be a layer that emits light by fluorescence, phosphorescence, or the like, and may be formed using a vacuum deposition method, spin coating method, inkjet printing method, or the like. The light emitting layer 150 may be formed with a thickness of, for example, greater than or equal to about 10 nm and less than or equal to about 60 nm, or for example, greater than or equal to about 20 nm and less than or equal to about 50 nm. As the light emitting material of the light emitting layer 150, any known light emitting material may be used. However, the light emitting material included in the light emitting layer 150 may be a light emitting material capable of light emission from triplet excitons (i.e., phosphorescence). In this case, the driving life-span of the EL device 100 may be further improved.

The light emitting layer 150 is not particularly limited and may have a known configuration. For example, the light emitting layer may include at least one of semiconductor nanocrystal particles or a perovskite-type compound. That is, in one or more embodiments, the organic film may have a light emitting layer including at least one of semiconductor nanocrystal particles or an organometallic complex. When the light emitting layer includes semiconductor nanocrystal particles, the EL device may be a quantum dot electroluminescence device (QLED), a quantum dot light emitting device, or a quantum dot light emitting diode. In addition, when the light emitting layer includes an organometallic complex, the EL device is an organic electroluminescence device (OLED).

In the form of alight emitting layer including semiconductor nanocrystal particles (QLED), the light emitting layer is a single layer or multiple layers of a plurality of semiconductor nanocrystal particles (quantum dots). Here, semiconductor nanocrystal particles (quantum dots) are particles of a certain size that have a quantum confinement effect. The diameter of semiconductor nanocrystal particles (quantum dots) is not particularly limited, but may be about 1 nm to about 20 nm.

The semiconductor nanocrystal particles (quantum dots) arranged in the light emitting layer may be synthesized by a wet chemical process, an organometallic chemical vapor deposition process, a molecular beam epitaxy process, or other similar processes. Among these, the wet chemical process is a method of growing particles by adding precursor materials to an organic solvent.

In a wet chemical process, when a crystal grows, an organic solvent is naturally distributed to the surface of the quantum dot crystal and acts as a dispersant, thereby controlling growth of the crystal. Accordingly, in a wet chemical process, the growth of semiconductor nanocrystal particles may be controlled easily and at low cost compared to vapor deposition methods such as metal organic chemical vapor deposition (MOCVD) or molecular beam epitaxy (MBE).

Semiconductor nanocrystal particles (quantum dots) may control the energy band gap by controlling their size, whereby light of various wavelengths may be obtained from the light emitting layer (quantum dot light emitting layer). Therefore, by using multiple quantum dots of different sizes, it is possible to create a display that emits light of multiple different wavelengths. The size of the quantum dots may be selected to emit a red light, a green light, or a blue light, enabling color displays to be constructed. Additionally, the size of the quantum dots may be combined to emit white light with various colors.

As the semiconductor nanocrystal particles (quantum dots), a semiconductor material that is a Group II-VI semiconductor compound; a Group Ill-V semiconductor compound; a Group IV-VI group semiconductor compound; a Group IV element or compound; or a combination thereof may be used.

The Group II-VI semiconductor compound is not particularly limited, and examples thereof may include a binary compound that is CdSe, CdTe, ZnS, ZnSe, ZnTe, ZnO, HgS, HgSe, HgTe, or a mixture thereof; a ternary compound that is CdSeS, CdSeTe, CdSTe, ZnSeS, ZnTeSe, ZnSTe, HgSeS, HgSeTe, HgSTe, CdZnS, CdZnSe, CdZnTe, CdHgS, CdHgSe, CdHgTe, HgZnS, HgZnSe, HgZnTe, or a mixture thereof; or a quaternary compound that is CdZnSeS, CdZnSeTe, CdZnSTe, CdHgSeS, CdHgSeTe, CdHgSTe, HgZnSeS, HgZnSeTe, HgZnSTe, or a mixture thereof.

The Group III-V semiconductor compound is not particularly limited, and examples thereof may include a binary compound that is GaN, GaP, GaAs, GaSb, AlN, AlP, AlAs, AlSb, InN, InP, InAs, InSb, or a mixture thereof; a ternary compound that is GaNP, GaNAs, GaNSb, GaPAs, GaPSb, AlNP, AlNAs, AlNSb, AlPAs, AlPSb, InNP, InNAs, InNSb, InPAs, InPSb, or a mixture thereof; or a quaternary compound that is GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a mixture thereof.

The Group IV-VI semiconductor compound is not particularly limited, and examples thereof may include a binary compound that is SnS, SnSe, SnTe, PbS, PbSe, PbTe, or a mixture thereof; a ternary compound that is SnSeS, SnSeTe, SnSTe, PbSeS, PbSeTe, PbSTe, SnPbS, SnPbSe, SnPbTe, or a mixture thereof; or a quaternary compound that is SnPbSSe, SnPbSeTe, SnPbSTe, or a mixture thereof.

The Group IV element or compound is not particularly limited, and examples thereof may include a single element that is Si, Ge, or a mixture thereof; or a binary elemental compound that is SiC, SiGe, or a mixture thereof.

The semiconductor nanocrystal particles (quantum dots) may have a homogeneous single structure or a core-shell dual structure. The core and shell may include different materials. The material constituting each core and shell may be composed of different semiconductor compounds. However, the energy bandgap of the shell material may be larger than the energy bandgap of the core material. For example, the structures may be ZnTeSe/ZnSe/ZnS, InP/ZnSe/ZnS, CdSe/ZnS, InP/ZnS, or the like, but embodiments are not limited thereto.

For example, a producing process of a quantum dot having a core (CdSe)/shell (ZnS) structure is described. First, a core (CdSe) precursor material such as (CH₃)₂Cd (dimethylcadmium) and TOPSe (trioctylphosphine selenide) is injected into an organic solvent using TOPO (trioctylphosphine oxide) as a surfactant to form a crystal. At this time, after maintaining the crystal at a high temperature for a certain period of time so that it grows to a certain size, a precursor material for the shell (ZnS) is injected to form a shell on the surface of the already formed core. This allows the production of TOPO-capped CdSe/ZnS quantum dots.

In addition, when the light emitting layer includes an organometallic complex (OLED), the light emitting layer 150 may include, as a host material, for example, 6,9-diphenyl-9′-(5′-phenyl-[1,1′:3,1″-terphenyl]-3-yl) 3,3′-bi[9H-carbazole], 3,9-diphenyl-5-(3-(4-phenyl-6-(5′-phenyl-[1,1′:3′,1″-terphenyl]-3-yl)-1,3,5-triazine-2-yl)phenyl)-9H-carbazole, 9,9′-diphenyl-3,3′-bi[9H-carbazole], tris(8-quinolinolato)aluminum (tris(8-quinolinato)aluminum: Alq₃), 4,4′-bis(carbazol-9-yl)biphenyl (4,4′-bis(carbazol-9-yl)biphenyl: CBP), poly(N-vinyl carbazole) (poly(N-vinyl carbazole): PVK), 9,10-di(naphthalene-2-yl)anthracene (9,10-di(naphthalene)anthracene: ADN), 4,4′,4″-tris(N-carbazolyl)triphenylamine (4,4′,4″-tris(N-carbazolyl)triphenylamine: TCTA), 1,3,5-tris(N-phenyl-benzimidazol-2-yl)benzene (1,3,5-tris(N-phenyl-benzimidazol-2-yl)benzene: TPBI), 3-tert-butyl-9,10-di(naphth-2-yl)anthracene (3-tert-butyl-9,10-di(naphth-2-yl)anthracene: TBADN), distyrylarylene (distyrylarylene: DSA), 4,4′-bis(9-carbazole)-2,2′-dimethyl-biphenyl (4,4′-bis(9-carbazole)2,2′-dimethyl-biphenyl: dmCBP), or the like.

The light-emitting layer 150 may include a dopant material, such as, for example, perylene or its derivatives, rubrene or its derivatives, coumarin or its derivatives, 4-dicyanomethylene-2-(p-dimethylaminostyryl)-6-methyl-4H-pyran (DCM) or its derivatives, bis[2-(4,6-difluorophenyl)pyridinate]picolinate iridium(III) (Flrpic), bis(1-phenylisoquinoline)(acetylacetonate)iridium(III) (Ir(piq)₂(acac)), tris(2-phenylpyridine)iridium(Ill) (Ir(ppy)₃), tris(2-(3-p-phenyl)phenyl)pyridine iridium(Ill) and other iridium (Ir) complexes, osmium (Os) complexes, platinum complexes, or the like Among these, the light-emitting material may be a luminescent organometallic complex.

The method for forming the light emitting layer is not particularly limited. It may be formed by coating a coating solution including at least one of semiconductor nanocrystal particles or an organometallic complex (a solution coating method). At this time, as a solvent constituting the coating solution, a solvent that does not dissolve the material in the hole transport layer, such as, for example, a hole transport material, for example, a polymeric compound, may be selected.

The electron transport layer 160 may be formed on the light emitting layer 150. The electron transport layer 160 may be a layer that has the function of transporting electrons and may be formed by using a vacuum deposition method, spin coating method, inkjet method, or the like. The electron transport layer 160 may be formed to have a thickness of, for example, greater than or equal to about 15 nm and less than or equal to about 50 nm.

The electron transport layer 160 may be formed of an electron transport material. Non-limiting examples of electron transport materials may include (8-quinolinolato)lithium (lithium quinolate, Liq), tris(8-quinolinolato)aluminum (Alq₃), or a compound having a nitrogen-containing aromatic ring. Non-limiting examples of the compound having a nitrogen-containing aromatic ring may include a compound including a pyridine ring, such as, for example, 1,3,5-tri[(3-pyridyl)-phen-3-yl]benzene, a compound including a triazine ring, such as, for example, 2,4,6-tris(3′-(pyridin-3-yl)biphenyl-3-yl)-1,3,5-triazine, a compound including an imidazole ring, such as, for example, 2-(4-(N-phenylbenzoimidazolyl-1-yl-phenyl)-9,10-dinaphthylanthracene or 1,3,5-tris(N-phenyl-benzimidazol-2-yl)benzene (TPBI). The electron transport material may be used alone or as a mixture of two or more types.

The electron injection layer 170 may be formed on the electron transport layer 160. The electron injection layer 170 may be a layer that has the function of facilitating the injection of electrons from the second electrode 180. The electron injection layer 170 may be formed by using a vacuum deposition method or the like. The electron injection layer 170 may be formed to have a thickness of, for example, greater than or equal to about 0.1 nm and less than or equal to about 5 nm, or for example, greater than or equal to about 0.3 nm and less than or equal to about 2 nm. Any known material may be used as a material for forming the electron injection layer 170. For example, the electron injection layer 170 may be formed by a lithium compound such as, for example, (8-quinolinato)lithium (lithium quinolate, Liq) or lithium fluoride (LiF), sodium chloride (NaCl), cesium fluoride (CsF), lithium oxide (Li₂O), or barium oxide (BaO).

The second electrode 180 may be formed on the electron injection layer 170. The second electrode 180 may be formed by using a vacuum deposition method or the like. The second electrode 180 may be, for example, a cathode, and may be formed by a metal, an alloy, or a conductive compound having a small work function. For example, the second electrode 180 may be formed as a reflective electrode using a metal, such as, for example, lithium (Li), magnesium (Mg), aluminum (Al), calcium (Ca), silver (Ag) or an alloy, such as, for example, aluminum-lithium (Al—Li), magnesium-indium (Mg—In), or magnesium-silver (Mg—Ag). The second electrode 180 may be formed with a thickness of, for example, from about 10 nm to about 200 nm, for example, from about 50 nm to about 150 nm. Alternatively, the second electrode 180 may be formed as a transparent electrode by a thin film of the metal material having a thickness of 20 nm or less, a transparent conductive film, such as, for example, indium tin oxide (In₂O₃—SnO₂) or indium zinc oxide (In₂O₃—ZnO).

As described above, as an example of an electroluminescence device according to one or more embodiments, an EL device 100 according to the present embodiment has been described. The EL device 100 according to the present embodiment may improve durability (luminescence life-span) and luminous efficiency (current efficiency) with a good balance by installing an organic film (e.g., a hole transport layer or a hole injection layer) including an organic film including a polymeric compound according to one or more embodiments. Further, the driving voltage of the EL device 100 may decrease.

The stacked structure of the EL device 100 according to one or more embodiments is not limited to the above example. The EL device 100 according to one or more embodiments may be formed by another known stacked structure. For example, the EL device 100 may omit one or more of the hole injection layer 130, the hole transport layer 140, the electron transport layer 160, or the electron injection layer 170, and may additionally include another layer. Additionally, each layer of the EL device 100 may be formed as a single layer or as multiple layers.

For example, the EL device 100 may further include a hole blocking layer between the electron transport layer 160 and the light emitting layer 150 to prevent holes from diffusing into the electron transport layer 160. And, the hole blocking layer may be formed by, for example, an oxadiazole derivative, a triazole derivative, or a phenanthroline derivative.

In addition, the polymeric compound according to one or more embodiments may be applied to electroluminescence devices other than the QLED or OLED. Other electroluminescence devices to which the polymeric compound according to one or more embodiments may be applied include, but are not particularly limited to, organic inorganic Perovskite electroluminescence devices.

One or more embodiments may include the following aspects and forms.
Aspect 1. A polymeric compound comprising a structural unit represented by Chemical Formula 1 and a structural unit represented by Chemical Formula 2:

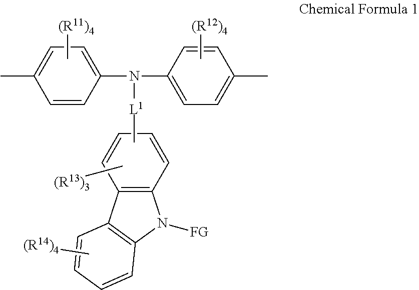

wherein, in Chemical Formula 1, R¹¹ to R¹⁴ are each independently a hydrogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aryl group, or a halogen atom,
L¹ is a substituted or unsubstituted aromatic ring group having 6 to 15 ring-forming atoms, and,
FG is represented by one of Chemical Formula 3 to Chemical Formula 5:

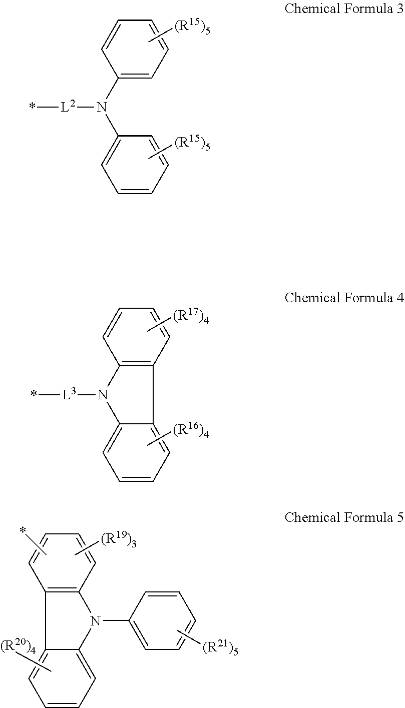

wherein, in Chemical Formula 3 to Chemical Formula 5,
L² and L³ are each independently a substituted or unsubstituted aromatic ring group having 6 to 15 ring-forming atoms,
R¹⁵ to R²¹ are each independently a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, or a substituted or unsubstituted heteroaromatic ring group having 6 to 20 ring-forming atoms, and
* indicates a linking position to a nitrogen atom;

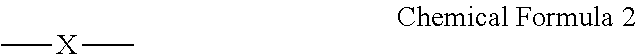

wherein, in Chemical Formula 2, X is an aromatic ring group having 6 to 30 carbon atoms unsubstituted or substituted with a hydrocarbon group having 1 to 14 carbon atoms, or an aromatic ring group having 4 to 30 carbon atoms and at least one hetero atom and unsubstituted or substituted with a hydrocarbon group having 1 to 14 carbon atoms.
Aspect 2. In the polymeric compound according to Aspect 1, the polymeric compound includes a structural unit represented by Chemical Formula 6:

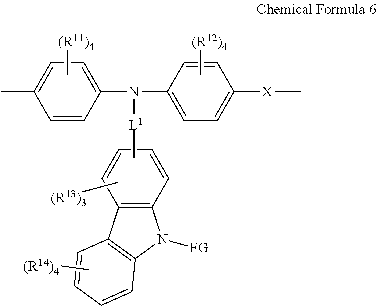

wherein, in Chemical Formula 6, R¹¹ to R¹⁴, L¹, and FG are the same as in Chemical Formula 1 above, and
X is the same as defined in Chemical Formula 2.
Aspect 3. In the polymeric compound according to Aspect 1 or Aspect 2, L¹, L², and L⁴ may each independently be one of the structures represented by Chemical Formulae (7-1) to (7-24):

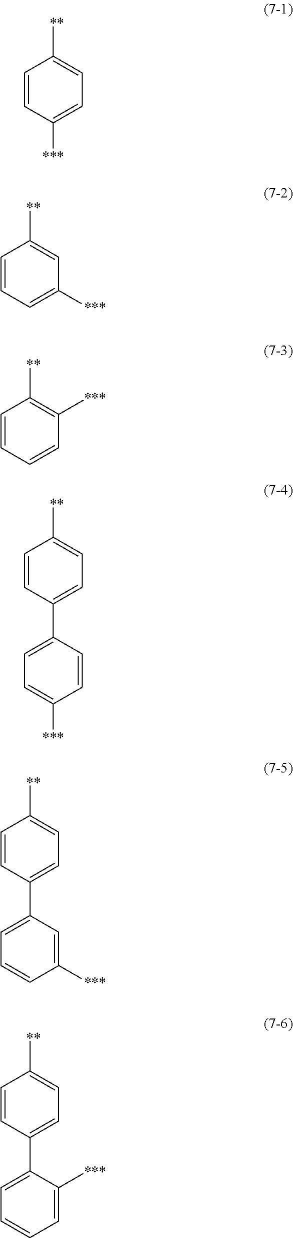

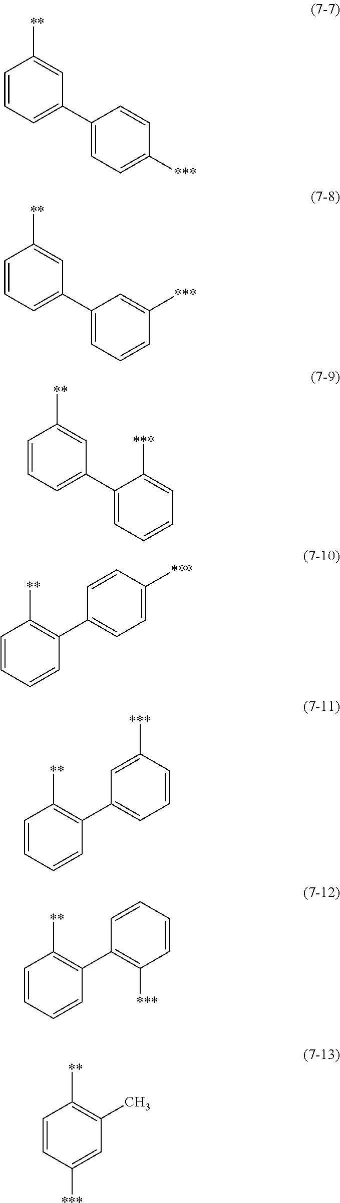

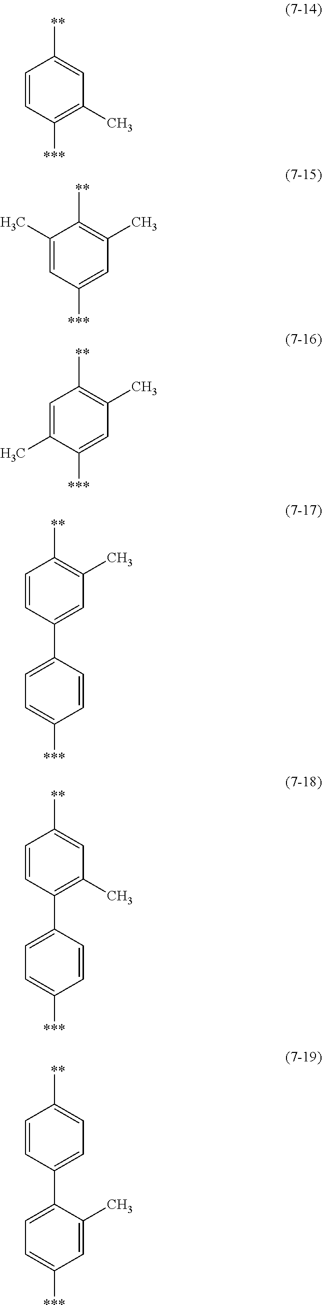

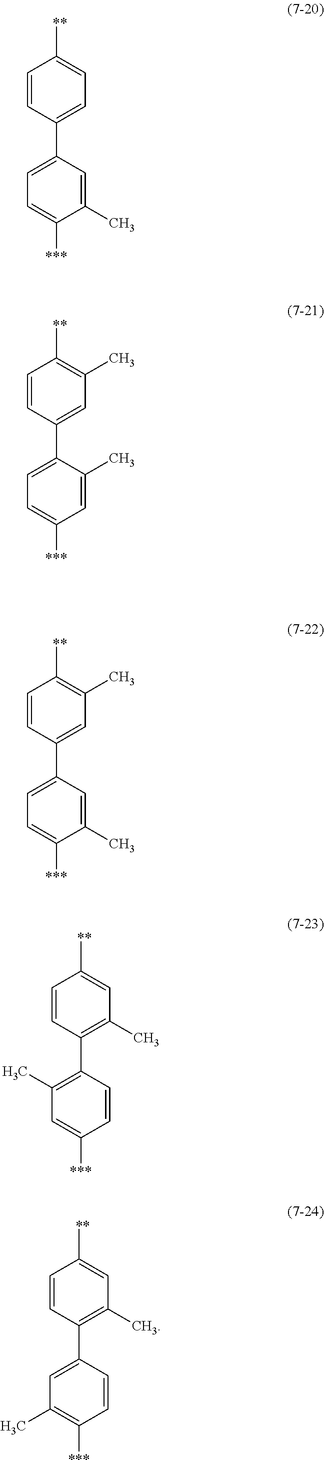

wherein, in Chemical Formula (7-1) to Chemical Formula (7-24), ** indicates a position linked to a nitrogen atom, and *** indicates a position linked to a carbon atom or a nitrogen atom.
Aspect 4. In the polymeric compound according to any one of Aspect 1 to Aspect 3, X may be represented by a structure represented by Chemical Formulae (8-1) to (8-22):

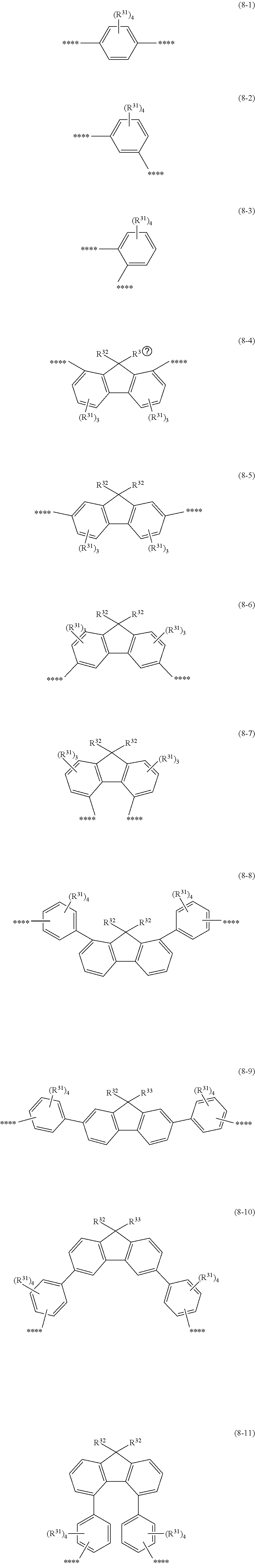

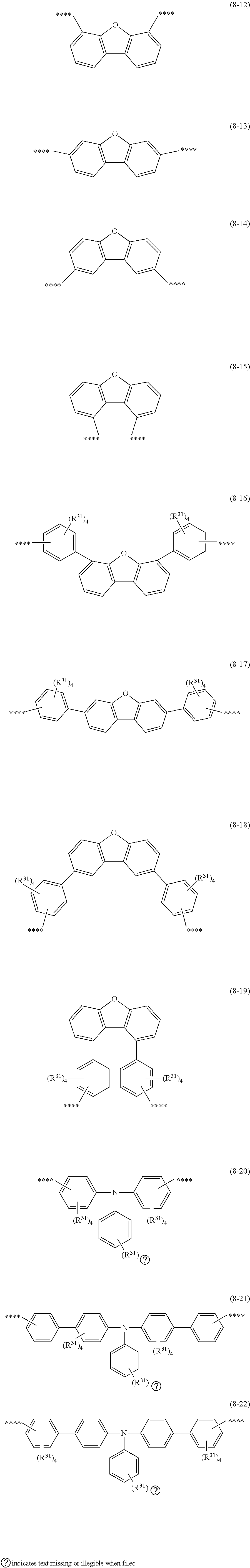

wherein, in Chemical Formulae (8-1) to (8-22),
R³¹ may independently be a hydrogen atom, a substituted or unsubstituted saturated linear hydrocarbon group having 1 to 14 carbon atoms, or a substituted or unsubstituted branched saturated hydrocarbon group having 3 to 14 carbon atoms,
R³² may independently be a substituted or unsubstituted linear saturated hydrocarbon group having 1 to 14 carbon atoms, or a substituted or unsubstituted branched saturated hydrocarbon group having 3 to 14 carbon atoms, and
**** indicates a linking position.
Aspect 5. A composition including a polymeric compound according to any one of Aspect 1 to Aspect 4, and at least one material that is a hole transport material, an electron transport material, or a light-emitting material.
Aspect 6. A composition including the polymeric compound according to any one of Aspect 1 to Aspect 4, and at least one solvent.
Aspect 7. An electroluminescence device, including a first electrode, a second electrode, and at least one layer of an organic film arranged between the first electrode and the second electrode, where the at least one layer of the organic film may include the polymeric compound according to any one of Aspect 1 to Aspect 4.
Aspect 8. The electroluminescence device according to Aspect 7, where the at least one of the organic film including the polymeric compound may be a hole transport layer or a hole injection layer.
Aspect 9. The electroluminescence device according to Aspect 7 or Aspect 8, where the organic film may further include a light emitting layer that includes at least one of a semiconductor nanoparticle or an organometallic complex.
Aspect 10. A method of manufacturing an electroluminescence device that includes a first electrode, a second electrode, and at least one layer of an organic film arranged between the first electrode and the second electrode, where the method includes forming the at least one layer of the organic film by coating a composition including the polymeric compound according to any one of Aspect 1 to Aspect 4 above and at least one solvent, and removing the solvent.

### EXAMPLES

The present subject matter is described in further detail using the following examples and comparative examples. However, the technical range of the disclosure is not limited to the following examples. In the following examples, unless specifically described, each operation was performed at room temperature (25° C.). In addition, unless specifically stated, “%” and “a part” mean “mass %” and “a part by mass,” respectively. In addition, in the chemical formulae below, the description of “CₘH₂ₘ₊₁ (m is an integer)” indicating an alkyl group indicates a linear alkyl group unless specified otherwise.

### Example 1: Synthesis of Polymeric Compound P-1

### Synthesis of Monomer M-1

Monomer M-1 was synthesized according to Reaction Scheme 1.

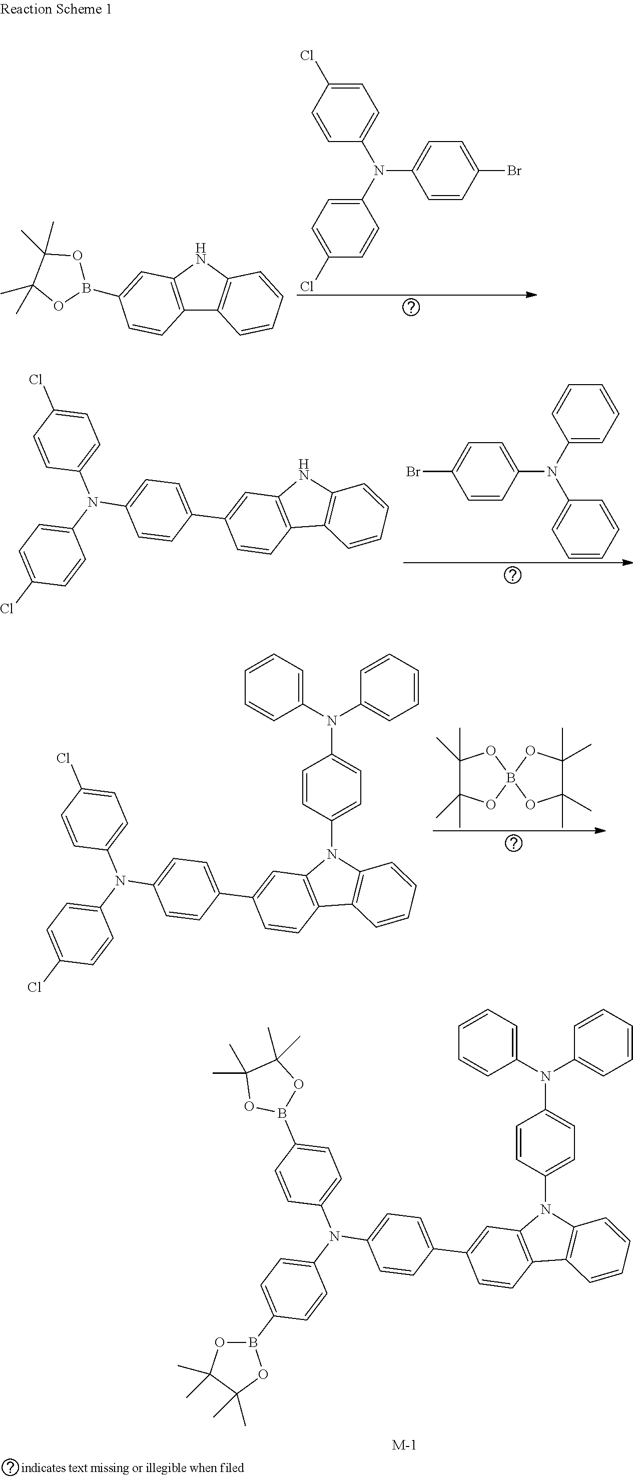

In a 1000 ml-four-neck flask, 2-(9H-carbazol-2-yl)-4,4,5,5-tetramethyl-1,3,2-dioxaborolane (37.2 grams (g)), 4-bromo-4′,4″-dichlorotriphenylamine (50.0 g), sodium carbonate (20.2 g), tetrakis(triphenylphosphine)palladium (0) (Pd(PPh₃)₄) (7.34 g), toluene (510 milliliters (mL)), ethanol (120 mL), and water (120 mL) were combined and stirred at 100° C. (bath temperature) for 3 hours. After cooling to room temperature, the aqueous layer was separated and extracted with toluene (100 mL×2). The organic layer was washed with water (100 mL×2), dried over magnesium sulfate, and separated. The solvent was removed by vacuum distillation, toluene (200 mL) was added to the residue, refluxed at 60° C. for 1 hour, and the solid was filtered, separated, and dried to obtain N-(4-(9-carbazol-2-yl)phenyl)-4-chloro-N-(4-chlorophenyl)aniline (43.5 g).

In a 4-neck flask charged with argon, N-(4-(9-carbazol-2-yl)phenyl)-4-chloro-N-(4-chlorophenyl)aniline (7.50 g), 4-bromo triphenylamine (5.07 g), tris(dibenzylideneacetone)dipalladium (Pd₂(dba)₃) (0.716 g), tri-tert-butylphosphonium tetrafluoroborate (tBu₃PH·BF₄) (0.680 g), sodium tert-butoxide (t-BuONa) (4.51 g), and toluene (80 mL) were combined and heated at 125° C. for 7 hours. After cooling to room temperature, impurities were filtered and separated using Celite. The solvent was removed by vacuum distillation, and the product was purified by column chromatography to obtain 4-(2-(4-(bis(4-chlorophenyl)amino)phenyl)-9H-carbazol-9-yl)-N,N-diphenylaniline (7.06 g).

In a 50 mL three-neck flask, the obtained 4-(2-(4-(bis(4-chlorophenylamino)phenyl)-9H-carbazol-9-yl)—N, N-diphenylanilne (8.00 g), bis(pinacolato)diboron (9.83 g), potassium acetate (KOAc) (6.51 g), tris(dibenzylideneacetone)dipalladium (Pd₂(dba)₃) (0.608 g), Xphos (0.791 g), and 1,4-dioxane (91 mL) were combined, and stirred at 110° C. (bath temperature) for 3 hours under a nitrogen atmosphere. After cooling to room temperature, the insoluble matter was removed using Celite as a filtration aid. The solvent was removed under reduced pressure, and the residue was dissolved in a mixed solvent of toluene (20 mL) and hexane (40 mL). Activated carbon (2.50 g) and synthetic zeolite (2.50 g) were added thereto, and the contents were heated at reflux for 30 minutes. The insoluble matter was filtered and separated using Celite as a filtration aid, and after removing the solvent under reduced pressure, the residue was recrystallized from toluene/acetonitrile to obtain monomer M-1 (3.82 g).

### Synthesis of Polymer Compound P-1

Under a nitrogen atmosphere, the obtained monomer M-1 (1.46 g), 2,7-dibromo-9,9-dioctylfluorene (1.07 g), dichloro bis[di-t-butyl(p-dimethylaminophenyl)phosphino]palladium(II) (12.5 mg), toluene (51 mL), and a 20 mass % tetraethylammonium hydroxide aqueous solution (9.15 g) were placed in a four-neck flask and stirred at 85° C. for 6 hours. Phenylboronic acid (215 mg), bis(triphenylphosphine)palladium(II) dichloride (74.8 mg), and a 20 mass % tetraethylammonium hydroxide aqueous solution (5.46 g) were added, and the contents were stirred at 85° C. for 6 hours. Then, sodium N,N-diethyldithiocarbamate trihydrate (6.00 g) dissolved in ion-exchanged water (35 mL) was added and stirred at 85° C. for 2 hours. After separating the organic layer from the aqueous layer, the organic layer was sequentially washed with water, a 3 mass % acetic acid aqueous solution, and water. The organic layer was purified by column chromatography using silica gel/alumina, and the solvent was removed under reduced pressure. The obtained liquid was dropped into methanol, the precipitated solid was dissolved in toluene, dropped into methanol to precipitate, and the precipitated solid was filtered, separated, and dried to obtain the polymer compound P-1 (0.518 g). The weight average molecular weight (Mw) and polydispersity (Mw/Mn) of the obtained polymer compound P-1 were measured by SEC. The weight average molecular weight (Mw) and polydispersity (Mw/Mn) of the polymer compound P-1 were 137,000 Dalton (Da) and 1.61, respectively.

The polymer compound P-1 obtained in this way is presumed to have the following structural units from the monomer.

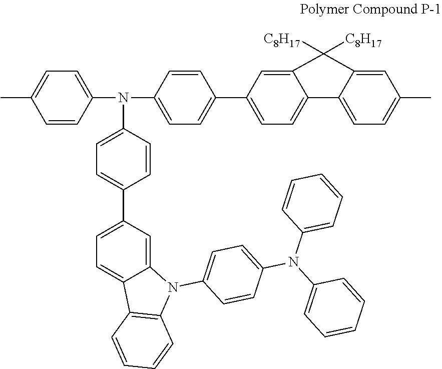

### Example 2: Synthesis of Polymeric Compound P-2

### Preparation of Monomer M-1

Monomer M-1 was prepared in the same manner as in Example 1.

### Synthesis of Polymeric Compound P-2

Under a nitrogen atmosphere, the monomer M-1 obtained above (1.48 g), 2,7-dibromo-9,9-didecylfluorene (0.992 g), dichloro bis[di-t-butyl(p-dimethylaminophenyl)phosphino]palladium(II) (11.7 mg), toluene (54 mL), and a 20% by weight aqueous solution of tetraethylammonium hydroxide (8.45 g) were combined in a four-neck flask and stirred at 85° C. for 6 hours. Phenylboronic acid (198 mg), bis(triphenylphosphine)palladium(II) dichloride (69.1 mg), and a 20% by weight aqueous solution of tetraethylammonium hydroxide (8.45 g) were added and stirred at 8500 for 6 hours. Then, sodium N,N-diethyldithiocarbamate trihydrate (5.55 g) dissolved in ion-exchanged water (54 mL) was added and stirred at 85° C. for 2 hours. After separating the organic layer from the aqueous layer, the organic layer was sequentially washed with water, a 3% by weight aqueous acetic acid solution, and water. The organic layer was purified by column chromatography using silica gel/alumina, and the solvent was removed by distillation under reduced pressure. The obtained liquid was dropped into methanol, and the precipitated solid was dissolved in toluene, dropped into methanol to precipitate, and the precipitated solid was filtered, separated, and dried to obtain the polymer compound P-2 (0.823 g). The weight average molecular weight (Mw) and polydispersity (Mw/Mn) of the obtained polymer compound P-2 were measured by SEC. As a result, the weight average molecular weight (Mw) and polydispersity (Mw/Mn) of the polymer compound P-2 were 122,000 Da and 1.64, respectively.

The polymer compound P-2 obtained in this way was presumed to have the following structural units from the monomer.

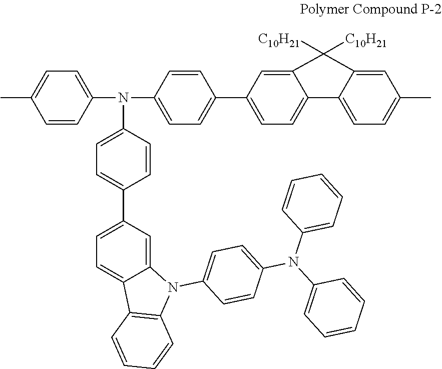

### Example 3: Synthesis of Polymeric Compound P-3

### Preparation of Monomer M-1

Monomer M-1 was prepared in the same manner as in Example 1.

### Synthesis of Polymeric Compound P-3

Under a nitrogen atmosphere, the obtained monomer M-1 (1.41 g), 2,7-dibromo-9,9-didodecylfluorene (1.03 g), dichloro bis[di-t-butyl(p-dimethylaminophenyl)phosphino]palladium(II) (11.1 mg), toluene (54 mL), and a 20 mass % tetraethylammonium hydroxide aqueous solution (8.05 g) were added to a four-neck flask and stirred at 85° C. for 6 hours. Phenylboronic acid (189 mg), bis(triphenylphosphine)palladium(II) dichloride (65.8 mg), and a 20 mass % tetraethylammonium hydroxide aqueous solution (8.05 g) were added and stirred at 85° C. for 6 hours. Then, sodium diethyldithiocarbamate trihydrate (5.28 g) dissolved in ion-exchanged water (54 mL) was added, and the contents were stirred at 85° C. for 2 hours. After separating the organic layer from the aqueous layer, the organic layer was sequentially washed with water, a 3 mass % acetic acid aqueous solution, and water. The organic layer was purified by column chromatography using silica gel/alumina, and the solvent was removed under reduced pressure. The obtained liquid was dropped into methanol, and the precipitated solid was dissolved in toluene, dropped into methanol to precipitate, and the precipitated solid was filtered, separated, and dried to obtain the polymer compound P-3 (0.402 g). The weight-average molecular weight (Mw) and polydispersity (Mw/Mn) of the obtained polymer compound P-3 were measured by SEC. As a result, the weight-average molecular weight (Mw) and polydispersity (Mw/Mn) of the polymer compound P-3 were 135,000 Da and 1.68, respectively.

The polymer compound P-3 obtained in this way was presumed to have the following structural units from the monomer.

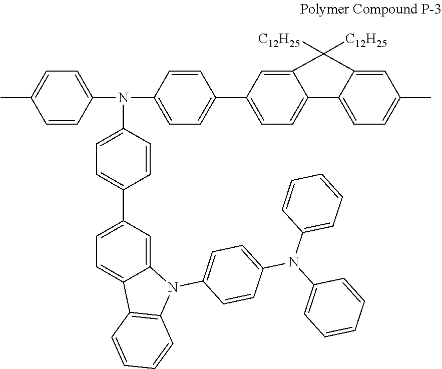

### Example 4: Synthesis of Polymeric Compound P-4

### Synthesis of Monomer M-2

Monomer M-2 was synthesized according to Reaction Scheme 2.

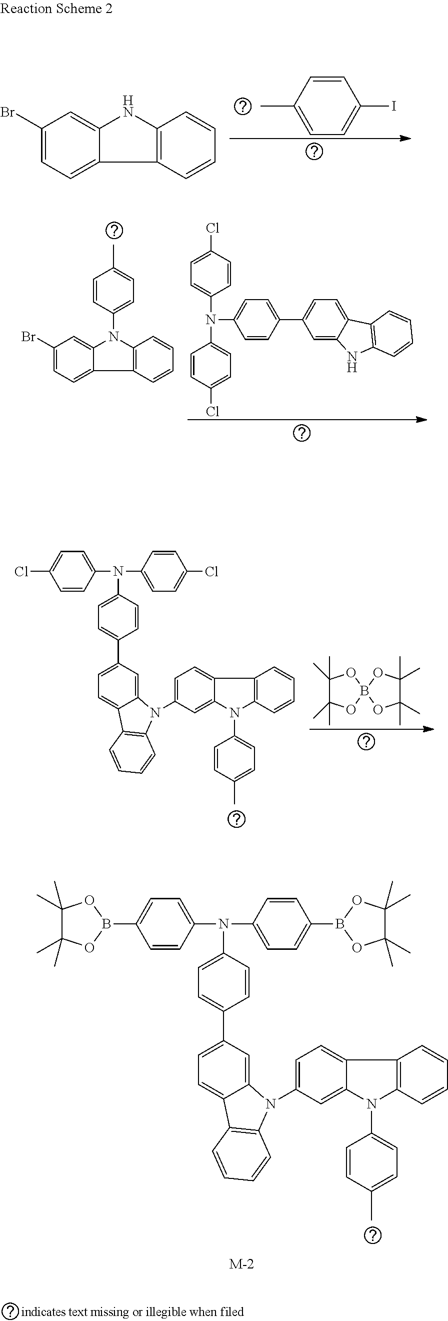

In a 300 mL 4-neck flask, 2-bromo-9H-carbazole (9.30 g), 1-iodo-4-pentylbenzene (10.00 g), copper iodide (0.320 g), sodium t-butoxide (t-BuONa) (6.52 g), trans-1,2-cyclohexanediamine (0.774 g), and 1,4-dioxane (34 mL) were combined and stirred at 100° C. for 30 hours under a nitrogen atmosphere. After cooling to room temperature, the insoluble materials were filtered and separated using Celite. The solvent was removed under reduced pressure, dissolved in toluene (100 mL), purified by column chromatography (silica gel, toluene/ethyl acetate=8/2), and 2-bromo-9-(4-pentylphenyl)-9H-carbazole (10.3 g) was obtained.

In a 200 mL four-neck flask replaced with argon, the obtained 2-bromo-9-(4-pentylphenyl)-9H-carbazole (5.37 g), N-(4-(9-carbazol-2-yl)phenyl)-4-chloro-N-(4-chlorophenyl)aniline (6.55 g), tris(dibenzylideneacetone)dipalladium (Pd₂(dba)₃) (0.625 g), tri-tert-butylphosphonium tetrafluoroborate (t-Bu₃PH·BF₄) (0.594 g), sodium tert-butoxide (t-BuONa) (3.94 g), and toluene (68 mL) were combined and heated to 125° C. for 5 hours. The mixture was cooled to room temperature, and impurities were filtered and separated using celite. After removing the solvent under reduced pressure, the product was purified by column chromatography, yielding 4-chloro-N-(4-chlorophenyl)-N-(4-(9-(4-pentylphenyl)-9H-[2,9′-bicarbazolyl]-2′-yl)phenyl)aniline (4.01 g).

In a 100 mL three-neck flask, 4.00 g of 4-chloro-N-(4-chlorophenyl)-N-(4-(9-(4-pentylphenyl)-9H-[2,9′-bicarbazolyl]-2′-yl)phenyl)aniline obtained above, 4.95 g of bis(pinacolato)diboron, 2.97 g of potassium acetate (KOAc), 0.277 g of tris(dibenzylideneacetone)dipalladium (Pd₂(dba)₃), 0.361 g of Xphos, and 41 mL of 1,4-dioxane were combined. Under a nitrogen atmosphere, the mixture was stirred at 110° C. (bath temperature) for 3 hours. The mixture was cooled to room temperature, and the insoluble materials were removed using Celite as a filter aid. The solvent was removed under reduced pressure, and the residue was dissolved in a mixed solvent of toluene (100 mL) and hexane (100 mL). Activated carbon (1.50 g) and synthetic zeolite (1.50 g) were added thereto, and the mixture was heated at reflux for 30 minutes. The insoluble materials were filtered and separated using Celite as a filter aid, and the solvent was removed under reduced pressure. The residue was recrystallized from toluene/ethanol to obtain monomer M-2 (3.14 g).

### Synthesis of Polymeric Compound P-4

Under a nitrogen atmosphere, the monomer M-2 obtained above (1.31 g), 2,7-dibromo-9,9-dioctylfluorene (0.663 g), dichloro bis [di-t-butyl(p-dimethylaminophenyl)phosphino]palladium(II) (9.60 mg), toluene (42 mL), and a 20% by weight tetraethylammonium hydroxide aqueous solution (6.94 g) were combined to a four-necked flask and stirred at 85° C. for 6 hours. Phenylboronic acid (163 mg), bis(triphenylphosphine)palladium(II) dichloride (56.7 mg), and a 20% by weight tetraethylammonium hydroxide aqueous solution (6.94 g) were added thereto, and the contents were stirred at 85° C. for 6 hours. Then, sodium diethyldithiocarbamate trihydrate (4.55 g) dissolved in ion-exchanged water (42 mL) was added, and the contents were stirred at 85° C. for 2 hours. After separating the organic layer from the aqueous layer, the organic layer was sequentially washed with water, a 3% by weight acetic acid aqueous solution, and water. The organic layer was purified by column chromatography using silica gel/alumina, and the solvent was removed under reduced pressure. The obtained liquid was dropped into methanol, the precipitated solid was dissolved in toluene, dropped into methanol to precipitate, and the precipitated solid was filtered, separated, and dried to obtain the polymer compound P-4 (0.433 g). The weight-average molecular weight (Mw) and polydispersity (Mw/Mn) of the obtained polymer compound P-4 were measured by SEC. As a result, the weight-average molecular weight (Mw) and polydispersity (Mw/Mn) of the polymer compound P-4 were 64,200 Da and 1.50, respectively.

The polymer compound P-4 obtained in this way was presumed to have the following structural units from the monomer.

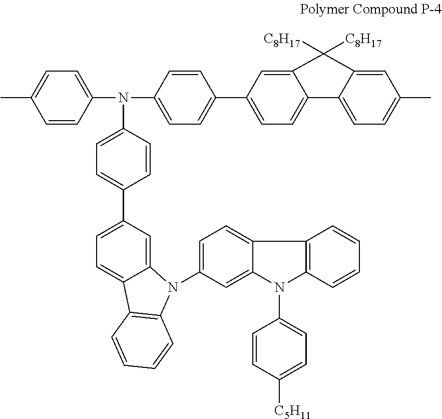

### Example 5: Synthesis of Polymeric Compound P-5

### Preparation of Monomer M-2

Monomer M-2 was prepared in the same manner as in Example 4.

### Synthesis of Polymeric Compound P-5

Under a nitrogen atmosphere, the obtained monomer M-2 (1.43 g), 2,7-dibromo-9,9-didodecylfluorene (0.974 g), dichloro bis[di-t-butyl(p-dimethylaminophenyl)phosphino]palladium(II) (10.5 mg), toluene (54 mL), and 20 mass % tetraethylammonium hydroxide aqueous solution (7.60 g) were combined in a four-neck flask and stirred at 85° C. for 6 hours. Phenylboronic acid (178 mg), bis(triphenylphosphine)palladium(II) dichloride (62.1 mg), and 20 mass % tetraethylammonium hydroxide aqueous solution (7.60 g) were added, and the mixture was stirred at 85° C. for 6 hours. Then, sodium N,N-diethyldithiocarbamate trihydrate (4.98 g) dissolved in ion-exchanged water (54 mL) was added and stirred at 85° C. for 2 hours. After separating the organic layer from the aqueous layer, the organic layer was sequentially washed with water, 3 mass % acetic acid aqueous solution, and water. The organic layer was purified by column chromatography using silica gel/alumina, and the solvent was removed under reduced pressure. The obtained liquid was dropped into methanol, the precipitated solid was dissolved in toluene, dropped into methanol to precipitate, filtered, and dried to obtain polymer compound P-5 (0.635 g). The weight average molecular weight (Mw) and polydispersity (Mw/Mn) of the obtained polymer compound P-5 were measured by SEC. As a result, the weight average molecular weight (Mw) and polydispersity (Mw/Mn) of the polymer compound P-5 were 89,800 Da and 1.64, respectively.

The polymer compound P-5 obtained in this way was presumed to have the following structural units from the monomer.

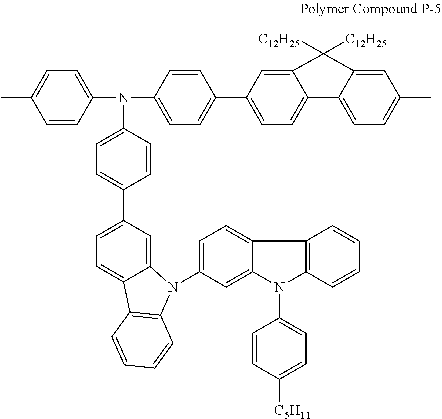

### Example 6: Synthesis of Polymeric Compound P-6

### Synthesis of Monomer M-3

Monomer M-3 was synthesized according to Reaction Scheme 3.

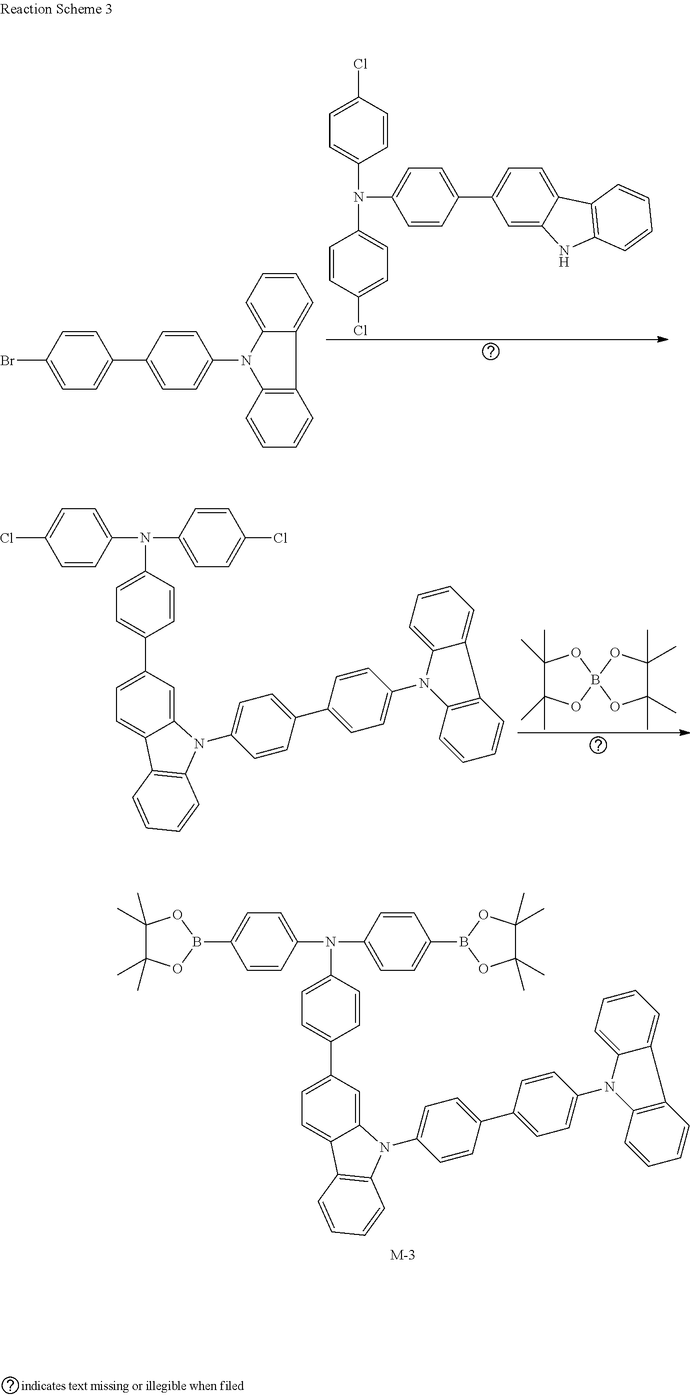

In a 200 mL four-neck flask replaced with argon, 9-(4′-bromo-4-biphenyl)carbazole (21.9 g), N-(4-(9-carbazol-2-yl)phenyl)-4-chloro-N-(4-chlorophenyl)aniline (24.0 g), tris(dibenzylideneacetone)dipalladium (Pd₂(dba)₃) (0.458 g), tri-tert-butylphosphonium tetrafluoroborate (t-Bu₃P—BF₄) (0.290 g), sodium tert-butoxide (t-BuONa) (7.21 g), and toluene (250 mL) were combined and heated to 125° C. for 5 hours. The contents were cooled to room temperature, and impurities were filtered and separated using Celite. After removing the solvent under reduced pressure, the product was purified by column chromatography to obtain 4-(9-(4′-(9H-carbazol-9-yl)-[1,1′-biphenyl]-4-yl)-9H-carbazol-2-yl)-N,N-bis(4-chlorophenyl) aniline (28.9 g).

In a 300 mL three-neck flask, 4-(9-(4′-(9H-carbazol-9-yl)-[1,1′-biphenyl]-4-yl)-9H-carbazol-2-yl)—N, N-bis(4-chlorophenyl) aniline (20.0 g), bis(pinacolato)diboron (15.8 g), potassium acetate (KOAc) (14.7 g), tris(dibenzylideneacetone)dipalladium (Pd₂(dba)₃) (1.37 g), Xphos (1.79 g), and 1,4-dioxane (41 mL) were combined, and the contents were stirred at a bath temperature of 110° C. for 3 hours under a nitrogen atmosphere. After cooling to room temperature, the insoluble materials were removed using Celite as a filtration aid. The solvent was removed under reduced pressure, the residue was dissolved in a mixed solvent of toluene (100 mL) and hexane (100 mL), and refluxed for 30 minutes with activated carbon (5.0 g) and synthetic zeolite (5.0 g). The insoluble materials were filtered and separated using Celite as a filtration aid, the solvent was removed under reduced pressure, and the residue was recrystallized with toluene/ethanol to obtain monomer M-3 (16.3 g).

### Synthesis of Polymeric Compound P-6

Under a nitrogen atmosphere, the obtained monomer M-3 (1.58 g), 2,7-dibromo-9,9-dioctylfluorene (0.886 g), dichloro bis[di-tert-butyl(p-dimethylaminophenyl)phosphino]palladium(II) (11.5 mg), toluene (50 mL), and a 20 wt % tetraethylammonium hydroxide aqueous solution (8.32 g) were combined in a four-neck flask and stirred at 85° C. for 6 hours. Phenylboronic acid (195 mg), bis(triphenylphosphine)palladium(II) dichloride (68.0 mg), and a 20 wt % tetraethylammonium hydroxide aqueous solution (8.32 g) were added, and the mixture was stirred at 85° C. for 6 hours. Then, sodium N,N-diethyldithiocarbamate trihydrate (5.46 g) dissolved in ion-exchanged water (50 mL) was added, and the mixture was stirred at 85° C. for 2 hours. After separating the organic layer from the aqueous layer, the organic layer was washed with water, a 3 wt % acetic acid aqueous solution, and water. The organic layer was purified by column chromatography using silica gel/alumina, and the solvent was removed under reduced pressure. The obtained liquid was dropped into methanol, and the precipitated solid was dissolved in toluene, then dropped into methanol to precipitate, and the precipitated solid was filtered, separated, and dried to obtain the polymer compound P-6 (0.765 g). The weight average molecular weight (Mw) and polydispersity (Mw/Mn) of the obtained polymer compound P-6 were measured by SEC. As a result, the weight average molecular weight (Mw) and polydispersity (Mw/Mn) of the polymer compound P-6 were 76,700 Da and 1.74, respectively.

The polymer compound P-6 obtained in this way was presumed to have the following structural units from the monomer.

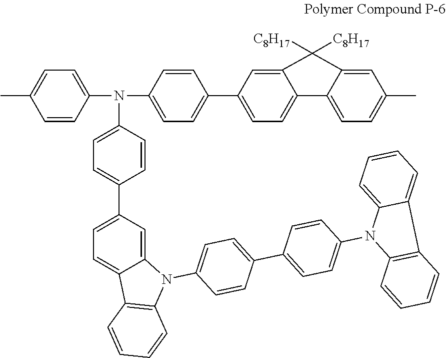

### Comparative Example 1

A polymer with the following structural unit, poly[(9,9-dioctylfluorenyl-2,7-diyl)-co-(4,4′-(N-(4-sec-butylphenyl)diphenylamine)](TFB) (manufactured by Luminescence Technology Corp.) was prepared. The weight-average molecular weight (Mw) and polydispersity index (Mw/Mn) of TFB were measured by SEC. As a result, the weight-average molecular weight (Mw) and polydispersity index (Mw/Mn) of TFB were 359,000 Da and 3.4, respectively.

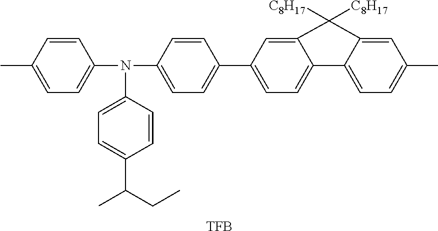

### Comparative Example 2: Synthesis of Comparative Polymeric Compound P-7

### Synthesis of Monomer M-4

Monomer M-4 was synthesized according to Reaction Scheme 4.

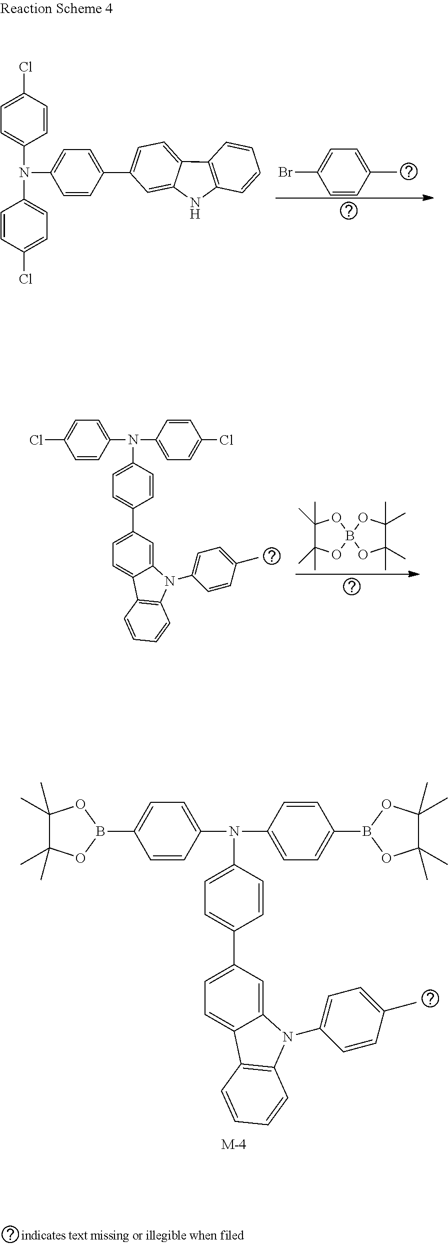

In a 4-neck flask replaced with argon, N-(4-(9-carbazol-2-yl)phenyl)-4-chloro-N-(4-chlorophenyl)aniline (10.0 g), 1-bromo-4-hexylbenzene (3.00 g), tris(dibenzylideneacetone)dipalladium (Pd₂(dba)₃) (0.580 g), tri-tert-butylphosphonium tetrafluoroborate (t-Bu₃P·BF₄) (0.276 g), sodium tert-butoxide (t-BuONa) (2.43 g), and toluene (60 mL) were combined, and heated at 110° C. for 7 hours. The contents were cooled to room temperature and impurities were filtered and separated using Celite. After removing the solvent under reduced pressure, the residue was purified by column chromatography to obtain 4-chloro-N-(4-chlorophenyl)-N-(4-(9-(4-hexylphenyl)-9-carbazol-2-yl)phenyl)aniline (1.60 g).

In a 50 mL three-neck flask, 4-chloro-N-(4-chlorophenyl)-N-(4-(9-(4-hexylphenyl)-9-carbazol-2-yl)phenyl)aniline (1.60 g) obtained above, bis(pinacolato)diboron (1.90 g), potassium acetate (KOAc) (1.47 g), tris(dibenzylideneacetone)dipalladium (Pd₂(dba)₃)), XPhos (0.177 g), and 1,4-dioxane (16 mL) were combined, and the mixture was stirred for 3 hours at a bath temperature of 100° C. under a nitrogen atmosphere. The contents were cooled to room temperature, and insoluble materials were removed using Celite as a filtration aid. The solvent was removed under reduced pressure, dissolved in a mixed solvent of toluene (20 mL) and hexane (40 mL), and then activated carbon (2.0 g) was added thereto. The mixture was heated under reflux for 30 minutes. Insoluble materials were filtered and separated using Celite as a filtration aid, and after removing the solvent under reduced pressure, the residue was recrystallized with toluene/acetonitrile to obtain monomer M-4 (1.85 g).

### Synthesis of Comparative Polymeric Compound P-7

Under a nitrogen atmosphere, the monomer M-4 (1.49 g) obtained above, 2,7-dibromo-9,9-didecylfluorene (0.970 g), palladium acetate (3.6 mg), tris(2-methoxyphenyl)phosphine (33.9 mg), toluene (54 mL), and a 20 wt % tetraethylammonium hydroxide aqueous solution (8.27 g) were placed in a four-neck flask and stirred at 85° C. for 6 hours. Phenylboronic acid (194 mg), bis(triphenylphosphine)palladium(II) dichloride (67.6 mg), a 20 wt % tetraethylammonium hydroxide aqueous solution (8.27 g), and sodium carbonate trihydrate (5.42 g) were added and stirred at 85° C. for 2 hours. After separating the organic layer from the aqueous layer, the organic layer was washed with water. The washed organic layer was purified by column chromatography (packing material=silica gel/alumina, eluent=toluene) and reprecipitated with toluene/methanol, and then dried under reduced pressure, to obtain the comparative polymer compound P-7 (1.25 g). The weight average molecular weight (Mw) and polydispersity (Mw/Mn) of the obtained comparative polymeric compound P-7 were measured by SEC. As a result, the weight average molecular weight (Mw) and polydispersity (Mw/Mn) of the comparative polymeric compound P-7 were 73,000 Da and 1.40, respectively.

The comparative polymeric compound P-7 obtained in this way was presumed to have the following structural units from the monomer.

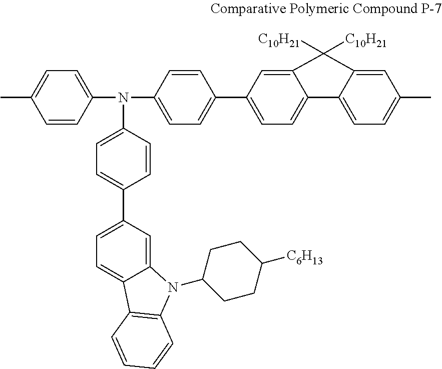

### Evaluation of Characteristics of Each Polymeric Compound

Polymeric Compounds P-1 to P-6 according to Examples 1 to 6, poly[(9,9-dioctylfluorenyl-2,7-diyl)-co-(4,4′-(N-(4-sec-butylphenyl)diphenylamine)](TFB) of Comparative Example 1, and Comparative Polymeric Compound P-7 according to Comparative Example 2 were measured with respect to HOMO level (eV), LUMO level (eV), and a glass transition temperature (T_{g})(° C.) in the following methods. A difference between HOMO level and HOMO-1 level was calculated by the following method. The results are shown in Tables 1 to 3. In Tables 1 to 3, the differences between HOMO level and HOMO-1 level (AE)(eV)[=HOMO-1 level (eV)−HOMO level (eV)] are described in the column indicated as “(ΔE)(eV)”.

### Measurement of HOMO Level

Each polymeric compound was dissolved in xylene to a concentration of 1% by mass to prepare a coating solution. Using the prepared coating solution, a film was formed on a UV-cleaned ITO-attached glass substrate by spin coating at 2000 rpm. The film was then dried on a hot plate at 150° C. for 30 minutes to produce a sample for measurement. The HOMO level of the sample was measured using an ambient photoelectron spectrometer (Riken Keiki Co., Ltd., AC-3). At this time, the tangent intersection of the rise was calculated from the measurement results and defined as the HOMO level (eV). The HOMO level was typically a negative value.

### Measurement of LUMO Level

Each of the above-mentioned polymeric compounds was dissolved in toluene to a concentration of 3.2% by mass to prepare a coating solution. Using the coating solution prepared above, a film was formed on a UV-cleaned ITO-coated glass substrate by spin coating at a speed of 1600 rpm. The film was then dried on a hotplate at 25° C. for 60 minutes to produce a measurement sample (the thickness of the formed film was approximately 70 nm). The obtained sample was cooled to 77K (−196° C.), and the photoluminescence (PL) spectrum was measured. From the peak value on the shortest wavelength side of the PL spectrum, the LUMO level (eV) was calculated. The LUMO level was typically a negative value.

### Glass Transition Temperature (T_{g})

The glass transition temperature (T_{g}) of each sample of the polymeric compounds was measured using differential scanning calorimetry (DSC) (Tradename: DSC6000, Seiko Instrument Inc.) by increasing a temperature to 300° C. at an increasing rate of 10° C./min and maintaining the temperature for 10 minutes, decreasing the temperature to 25° C. at a decreasing rate of 10° C./min and maintaining the temperature for 10 minutes, and increasing the temperature to 300° C. at an increasing rate of 10° C./min and measuring. After the measurement, the samples were cooled to room temperature (25° C.) at a decreasing rate of 10° C./min.

### Calculation of Difference Between HOMO Level and HOMO-1 Level

The difference between the HOMO level and the HOMO-1 level (ΔE)(eV) is expressed as the absolute value of the difference between the energy level (eV) of the HOMO (Highest Occupied Molecular Orbital) and the energy level (eV) of the orbital one below the HOMO, or ΔE=[I(HOMO-1 (eV))−(HOMO(eV))1]. Each energy level was calculated using Gaussian16 (Gaussian16, Revision C.01, M. J. Frisch, et al, Gaussian, Inc., Wallingford CT, 2019.), a software for molecular orbital calculations by Gaussian. The calculations were performed using B3LYP/6-31G (d, p) as the keyword, on a structure where the terminal units of the polymeric compound's structural unit are replaced with phenyl groups.

TABLE 1

| | | Mw | HOMO | ΔE | LUMO | Tg |
|---|---|---|---|---|---|---|
| | Structural Unit | (Mw/Mn) | (eV) | (eV) | (eV) | (° C.) |
| Example 1 (Polymer Compound P-1) | 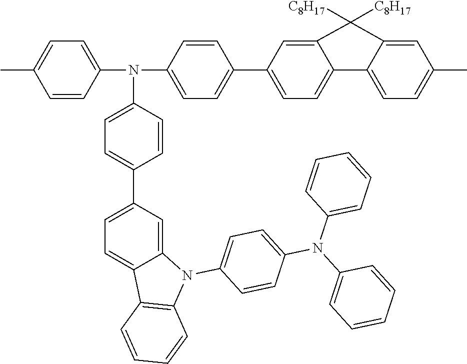 | 137.000 (1.61) | −5.59 | 0.27 | −2.69 | 179 |
| Example 2 (Polymer Compound P-2) | 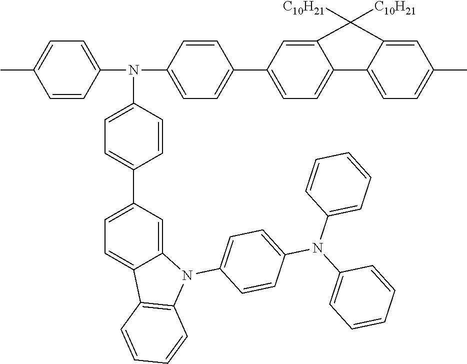 | 122.000 (1.64) | −5.58 | 0.27 | −2.73 | 152 |
| Example 3 (Polymer Compound P-3) | 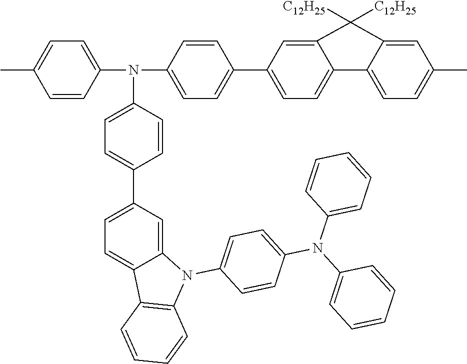 | 135.000 (1.68) | −5.57 | 0.27 | −2.73 | 100 |

TABLE 2

| | | Mw | | ΔE | LUMO | |
|---|---|---|---|---|---|---|
| | Structural Unit | (Mw/Mn) | HOMO (eV) | (eV) | (eV) | Tg (° C.) |
| Example 4 (Polymer Compound P-4) | 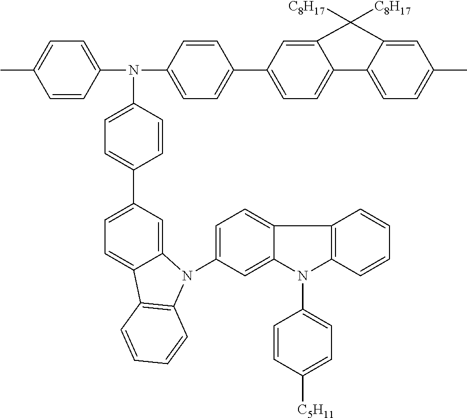 | 64.200 (1.50) | −5.51 | 0.52 | −2.85 | 193 |
| Example 5 (Polymer Compound P-5) | 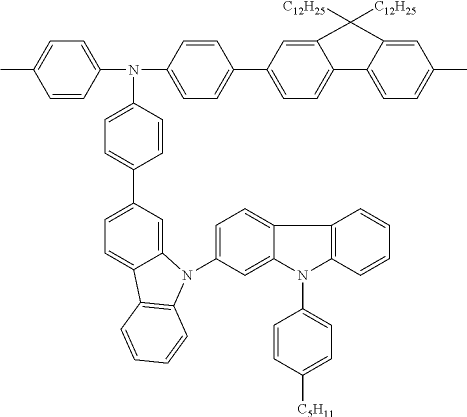 | 89.800 (1.64) | −5.50 | 0.52 | −2.84 | 115 |
| Example 6 (Polymer Compound P-6) | 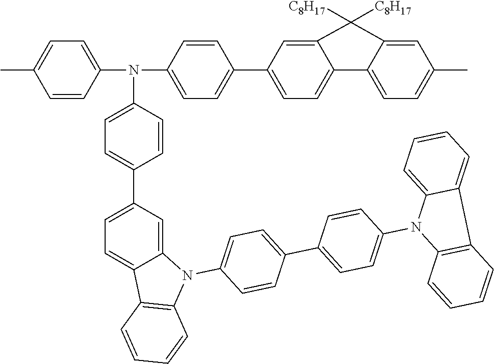 | 76.700 (1.74) | −5.54 | 0.54 | −2.84 | 214 |

TABLE 3

| | | | HOMO | | LUMO | |
|---|---|---|---|---|---|---|
| | Structural Unit | Mw (Mw/Mn) | (eV) | ΔE (eV) | (eV) | Tg (° C.) |
| Comparative Example 1 (TFB) | 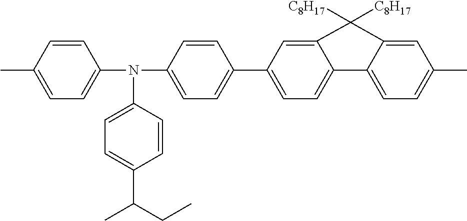 | 359.000 (3.40) | −5.54 | 0.60 | −2.60 | 156 |
| Comparative Example 2 (Polymer Compound P-7) | 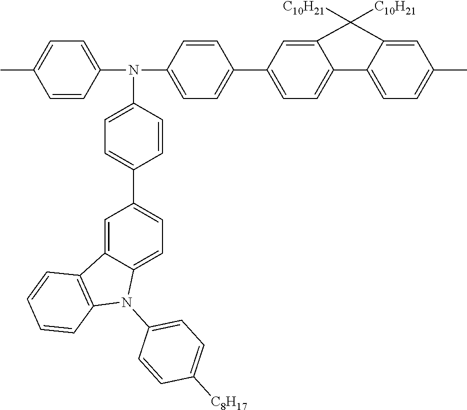 | 73.000 (1.40) | −5.52 | 0.59 | −2.68 | 125 |

### Example 7: Manufacturing of Quantum Dot Electroluminescence Device D-1

As a first electrode (an anode), an ITO-attached glass substrate, on which indium tin oxide (ITO) was patterned to have a film thickness of 150 nm, was used. This ITO-attached glass substrate was sequentially washed with a neutral detergent, deionized water, water, and isopropyl alcohol, and then treated with UV-ozone. Subsequently, on this ITO-attached glass substrate, poly(3,4-ethylenedioxythiophene)/poly(4-styrenesulfonate)(PEDOT/PSS) (Sigma-Aldrich Co., Ltd.) was spin-coated to have a dry film thickness of 30 nm, and dried. As a result, a hole injection layer with a thickness (dry film thickness) of 30 nm was formed on the ITO-attached glass substrate.

On the hole injection layer, a toluene solution including 1.0 mass % of Polymeric Compound P-1 according to Example 1 (a hole transport material) was spin-coated to have a dry film thickness of 30 nm, and heat-treated at 230° C. for 60 minutes to form a hole transport layer. As a result, the hole transport layer with a thickness (dry film thickness) of 30 nm was formed on the hole injection layer.

A quantum dot dispersion was prepared by dispersing blue quantum dots of ZnTeSe/ZnSe/ZnS (core/shell/shell; an average diameter of about 10 nm) to be 1.0 mass % in cyclohexane. The hole transport layer, particularly, Polymeric Compound P-1, was not dissolved in the cyclohexane. The quantum dot dispersion was spin-coated to have a dry film thickness of 30 nm on the hole transport layer, and dried. As a result, a quantum dot light emitting layer having the thickness (dry film thickness) of 30 nm was formed on the hole transport layer. The light emitted by the quantum dot dispersion upon irradiation with ultraviolet rays has a central wavelength of 462 nm and a full width at half maximum (FWHM) of 30 nm.

The quantum dot light emitting layer was completely dried. On this quantum dot light emitting layer, lithium quinolate (Liq) and 1,3,5-tris(N-phenylbenzimidazole-2-yl)benzene (TPBI) (Sigma-Aldrich Co., Ltd.) as an electron transport material were co-deposited by using a vacuum deposition device. As a result, an electron transport layer with a thickness of 36 nm was formed on the quantum dot light emitting layer.

On the electron transport layer, (8-quinolinolato)lithium (lithium quinolate, Liq) was deposited by using a vacuum deposition device. As a result, a 0.5 nm-thick electron injection layer was formed on the electron transport layer.

On the electron injection layer, aluminum (Al) was deposited by using the vacuum deposition device. As a result, a 100 nm-thick second electrode (a cathode) was formed on the electron injection layer. In this way, Quantum Dot Electroluminescence Device D-1 was obtained.

### Example 8: Manufacturing of Quantum Dot Electroluminescence Device D-2

Quantum Dot Electroluminescence Device D-2 was manufactured in the same manner as in Example 7, except that Polymeric Compound P-2 of Example 2 was used instead of Polymeric Compound P-1 of Example 1.

### Example 9: Manufacturing of Quantum Dot Electroluminescence Device D-3

Quantum Dot Electroluminescence Device D-3 was manufactured in the same manner as in Example 7, except that Polymeric Compound P-3 of Example 3 was used instead of Polymeric Compound P-1 of Example 1.

### Example 10: Manufacturing of Quantum Dot Electroluminescence Device D-4

Quantum Dot Electroluminescence Device D-4 was manufactured in the same manner as in Example 7, except that Polymeric Compound P-4 of Example 4 was used instead of Polymeric Compound P-1 of Example 1.

### Example 11: Manufacturing of Quantum Dot Electroluminescence Device D-5

Quantum Dot Electroluminescence Device D-5 was manufactured in the same manner as in Example 7, except that Polymeric Compound P-5 of Example 5 was used instead of Polymeric Compound P-1 of Example 1.

### Example 12: Manufacturing of Quantum Dot Electroluminescence Device D-6

Quantum Dot Electroluminescence Device D-6 was manufactured in the same manner as in Example 7, except that Polymeric Compound P-6 of Example 6 was used instead of Polymeric Compound P-1 of Example 1.

### Comparative Example 3: Manufacturing of Comparative Quantum Dot Electroluminescence Device D-7

Comparative Quantum Dot Electroluminescence Device D-7 was manufactured in the same manner as in Example 7, except that poly[(9,9-dioctylfluorenyl-2,7-diyl)-co-(4,4′-(N-(4-sec-butylphenyl)diphenylamine)](TFB) of Comparative Example 1 was used instead of Polymeric Compound P-1 of Example 1.

### Comparative Example 4: Manufacturing of Comparative Quantum Dot Electroluminescence Device D-8

Comparative Quantum Dot Electroluminescence Device D-8 was manufactured in the same manner as in Example 7, except that Comparative Polymeric Compound P-7 of Comparative Example 2 was used instead of Polymeric compound P-1 of Example 1.

### Evaluation of Quantum Dot Electroluminescence Devices

Quantum Dot Electroluminescence Devices D-1 to D-6 according to Examples 7 to 12 and Comparative Quantum Dot Electroluminescence Devices D-7 and D-8 of Comparative Examples 3 and 4 were evaluated with respect to driving voltage (V@5 mA (V)), current efficiency (Cd/Aₘₐₓ), luminous efficiency (EQEₘₐₓ (%)), and luminous life-span (LT50 (hr)) in the following methods. The results are shown in Table 4.

Driving Voltage (V@5 mA(V))

When a voltage was applied to each quantum dot electroluminescent device using a direct current (DC) constant voltage power supply (source meter, Keyence Corp.), current begins to flow at a certain voltage, and the quantum dot electroluminescent device emits light. The voltage (V) at a current density of 5 mA/cm² was defined as the driving voltage “V@5 mA (V).”

### Luminous Efficiency (External Quantum Efficiency (EQE_{Max} (%))

When a voltage was applied to each of the quantum dot electroluminescence devices, as a current began to flow at a predetermined voltage, the quantum dot electroluminescence devices emitted light. The voltage was slowly increased for each device by using a DC constant voltage power supply (a source meter, Keyence Corp.) to measure a current at this point, and in addition, a luminance meter (SR-3, Topcom Technology Cp., Ltd.) was used to measure luminance of the devices at the light emission. Here, the luminance measurement was stopped at the point where the luminance started to attenuate. The current value per unit area (current density) from the area of each device was calculated, and the luminance (cd/m²) was divided by the current density (A/m²) to calculate the current efficiency (cd/A). In Table 4, the greatest current efficiency within the measured voltage range is considered as “cd/A max.” The current efficiency represents the efficiency of converting current into luminous energy (conversion efficiency), and the higher the current efficiency, the better the performance of the device.

In addition, a spectral radiance luminance spectrum measured by the luminance meter, assuming that Lambertian radiation was performed, was used to calculate maximum external quantum efficiency (EQEₘₐₓ) (%), which was used to evaluate the luminous efficiency.

### Luminous Life-Span (LT50 (Hr))

A DC constant voltage power supply (a source meter, Keyence Corp.) was used to apply a predetermined voltage to each of the quantum dot electroluminescence devices to cause each of the quantum dot electroluminescence devices to emit light. Each of the quantum dot electroluminescence devices, while measuring luminance by using a luminance meter (SR-3, Topcom) by slowly increasing a current, was allowed to stand by keeping the current constant, when the luminance reached 650 nits (cd/m²). The time when the luminance measured by the luminance meter gradually decreased and reached 50% of the initial luminance was measured as “LT50(hr).”

TABLE 4

| | | | | V@5 mA | EQE max | LT50 |
|---|---|---|---|---|---|---|
| | Device | Polymer | cd/A max | (V) | [%] | [hr] |
| Example 7 | D-1 | P-1 | 13.3 | 2.95 | 13.9 | 49.2 |
| Example 8 | D-2 | P-2 | 12.6 | 2.75 | 13.5 | 51.3 |
| Example 9 | D-3 | P-3 | 13.6 | 2.96 | 13.2 | 32.5 |
| Example 10 | D-4 | P-4 | 12.1 | 2.60 | 11.5 | 42.1 |
| Example 11 | D-5 | P-5 | 13.5 | 2.94 | 13.1 | 35.5 |
| Example 12 | D-6 | P-6 | 12.9 | 2.78 | 13.2 | 41.6 |
| Com. Exa. 3 | D-7 | TFB | 3.0 | 3.00 | 9.2 | 12.0 |
| Com. Exa. 4 | D-8 | P-7 | 7.1 | 2.95 | 8.7 | 37.0 |

From the results in Table 4, the quantum dot electroluminescent devices D-1 to D-6 of Examples 7-12 are comparable in terms of luminous efficiency and durability. For example, the quantum dot electroluminescent devices D-1 to D-6 of Examples 7-12 exhibit greater luminous efficiency and superior durability at lesser driving voltages than the comparative quantum dot electroluminescent device D-7 of Comparative Example 3. Meanwhile, the comparative quantum dot electroluminescent device D-8 of Comparative Example 4 has an equivalent driving voltage and superior luminous lifetime (LT50) compared to the quantum dot electroluminescent devices D-3 of Example 9 and D-5 of Example 11, but it deteriorates in terms of luminous efficiency (EQE). In this regard, relatively speaking, the comparative quantum dot electroluminescent device D-8 of Comparative Example 4 is considered to have inferior luminous performance (i.e., a bad balance of luminous efficiency and luminous lifetime) in actual use compared to the quantum dot electroluminescent devices D-1 to D-6 of Examples 7-12.

Although the above has been described with reference to exemplary embodiments, the present disclosure is not limited to specific embodiments, and various modifications and changes are possible within the scope of the disclosure described in the claims.

What is claimed is:

1. A polymeric compound comprising a structural unit represented by Chemical Formula 1, and a structural unit represented by Chemical Formula 2: 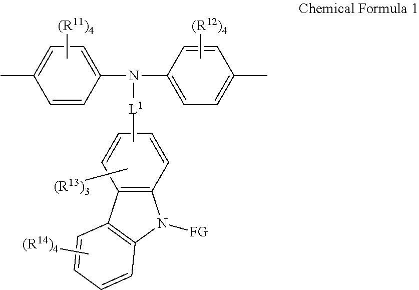
wherein, in Chemical Formula 1,
R¹¹ to R¹⁴ are each independently a hydrogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aryl group, or a halogen atom,
L¹ is a substituted or unsubstituted aromatic ring group having 6 to 15 ring-forming atoms, and
FG is represented by one of Chemical Formula 3 to Chemical Formula 5: 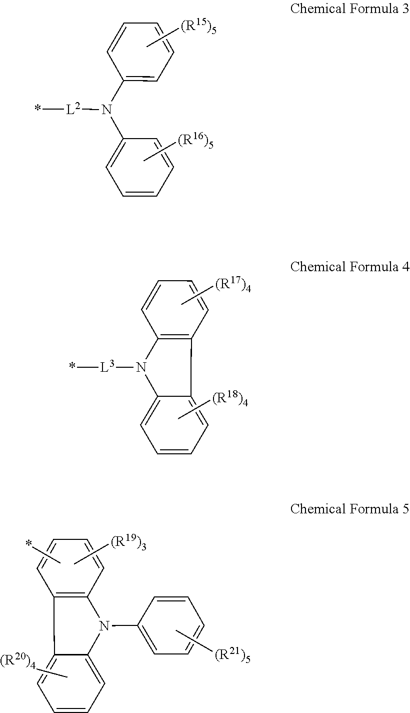
Wherein, in Chemical Formula 3 to Chemical Formula 5,
L² and L³ are each independently a substituted or unsubstituted aromatic ring group having 6 to 15 ring-forming atoms,
R¹⁵ to R²¹ are each independently a hydrogen atom, a halogen atom, a substituted or unsubstituted alkyl group, a substituted or unsubstituted cycloalkyl group, a substituted or unsubstituted alkoxy group, a substituted or unsubstituted cycloalkoxy group, a substituted or unsubstituted aromatic ring group having 6 to 25 ring-forming atoms, or a substituted or unsubstituted heteroaromatic ring group having 5 to 20 ring-forming atoms, and
* indicates a linking position to a nitrogen atom; 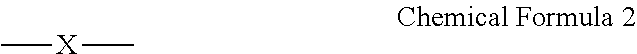
wherein in Chemical Formula 2,
X is an aromatic ring group having 6 to 30 carbon atoms and unsubstituted or substituted with a hydrocarbon group having 1 to 14 carbon atoms, or an aromatic ring group having 4 to 30 carbon atoms and at least one heteroatom and unsubstituted or substituted with a hydrocarbon group having 1 to 14 carbon atoms.

2. The polymeric compound of claim 1, comprising a structural unit represented by Chemical Formula 6: 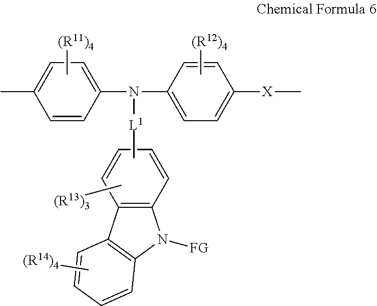
wherein, in Chemical Formula 6, each R¹¹ to R¹⁴, L¹, and FG is the same as defined in Chemical Formula 1, and X is defined as in Chemical Formula 2.

3. The polymeric compound of claim 1, wherein Chemical Formula 1 is represented by one of Group 1: 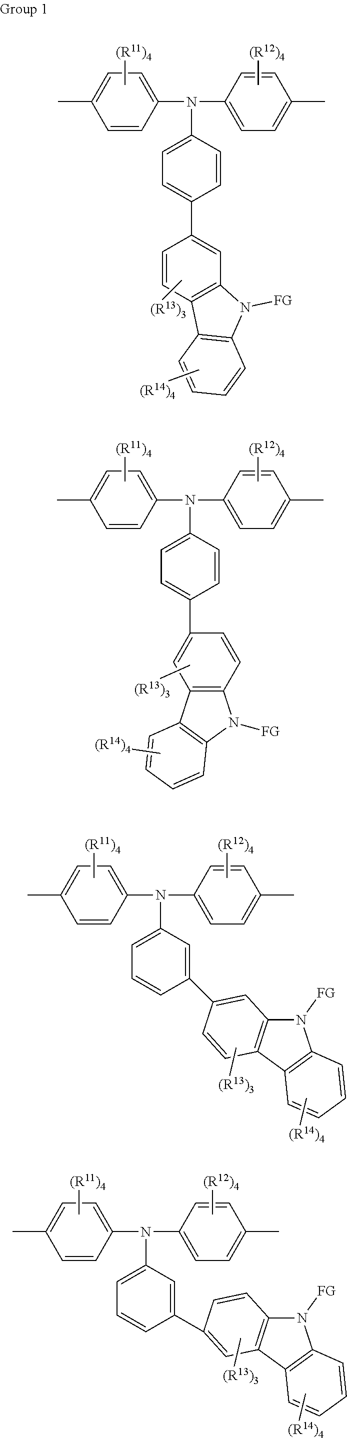
wherein in Group 1, each R¹¹ to R¹⁴, L¹, and FG is the same as defined in Chemical Formula 1.

4. The polymeric compound of claim 1, wherein L¹, L², and L³ are each independently represented by one of Chemical Formulae (7-1) to (7-24): 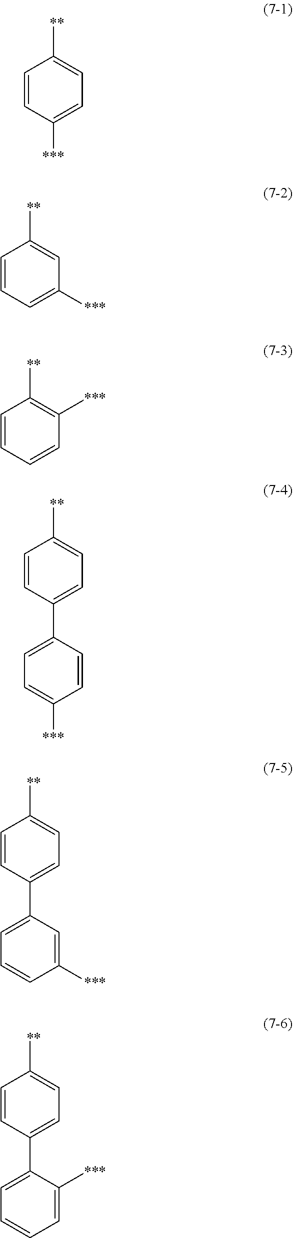 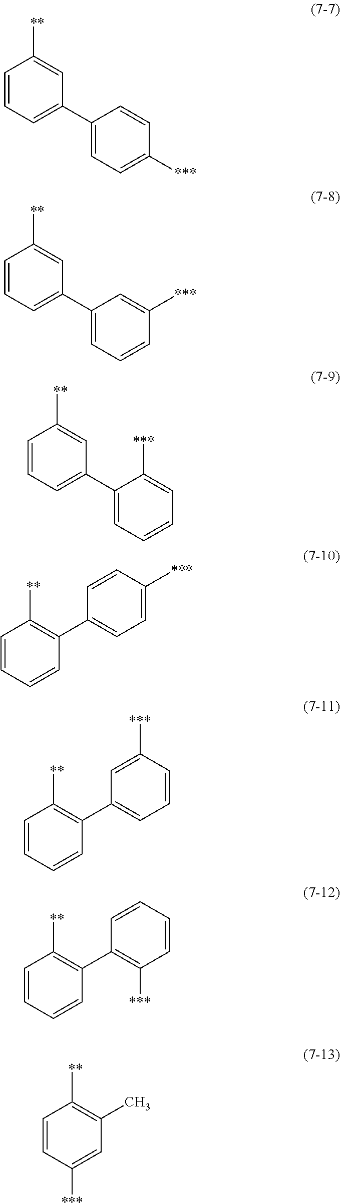 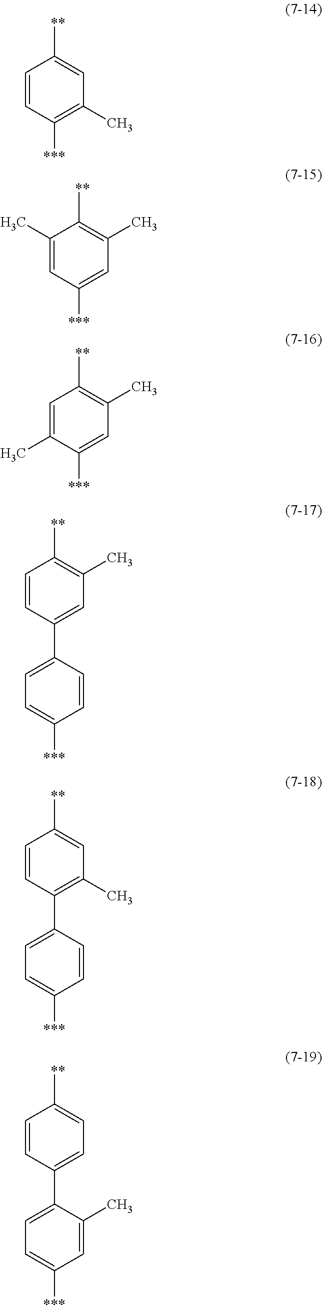 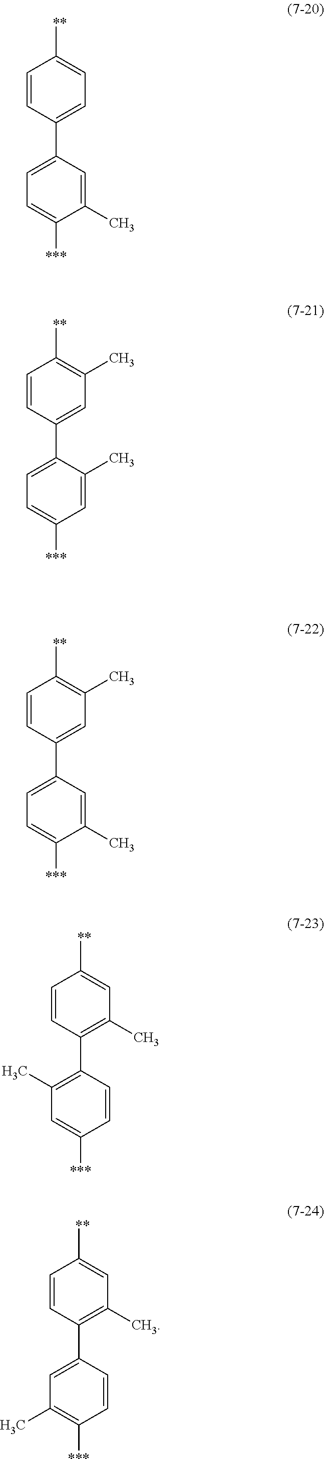
wherein, in Chemical Formulae (7-1) to (7-24),
** indicates a position linked to a nitrogen atom, and
*** indicates a position linked to a carbon atom or a nitrogen atom.

5. The polymeric compound of claim 1, wherein Chemical Formula 1 is represented by one of Group 3: 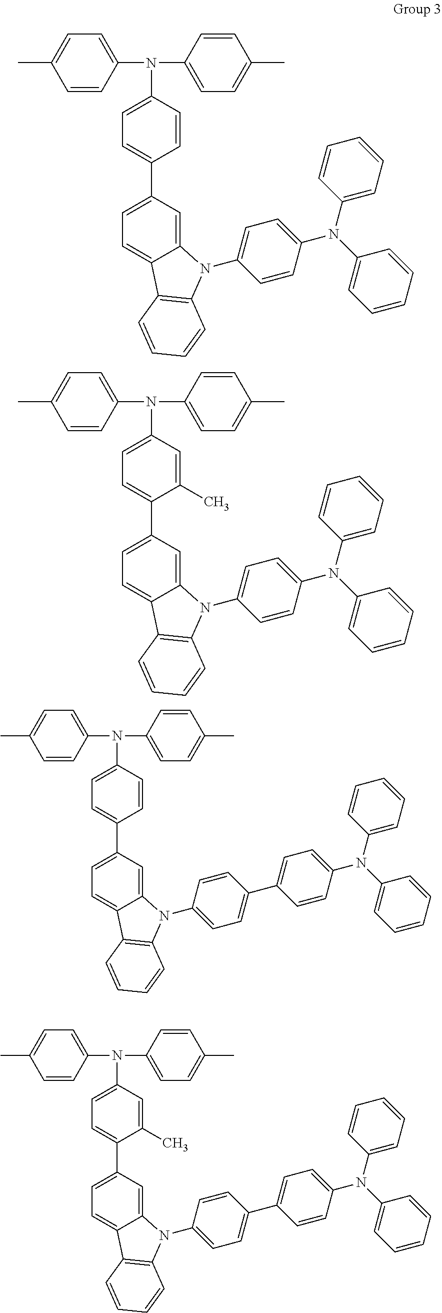 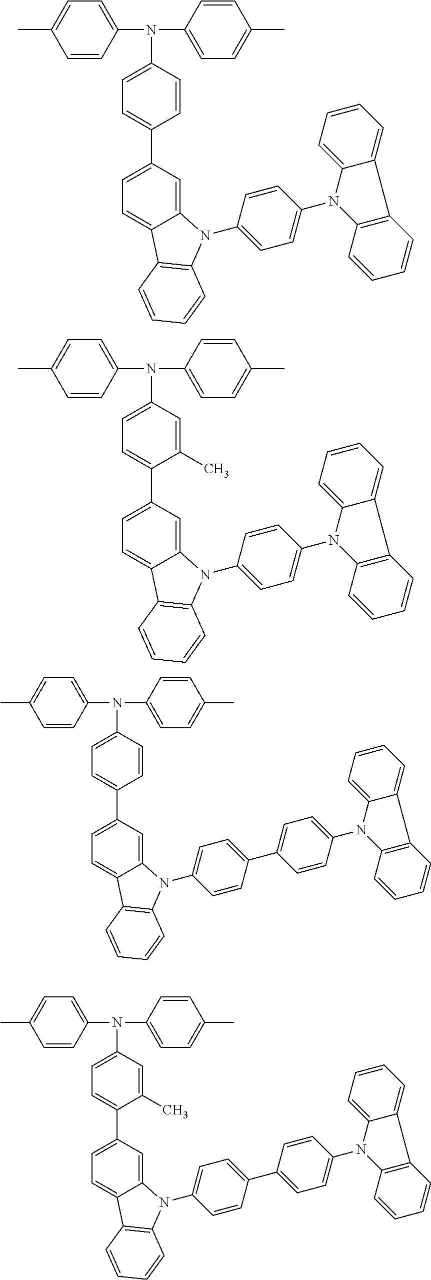 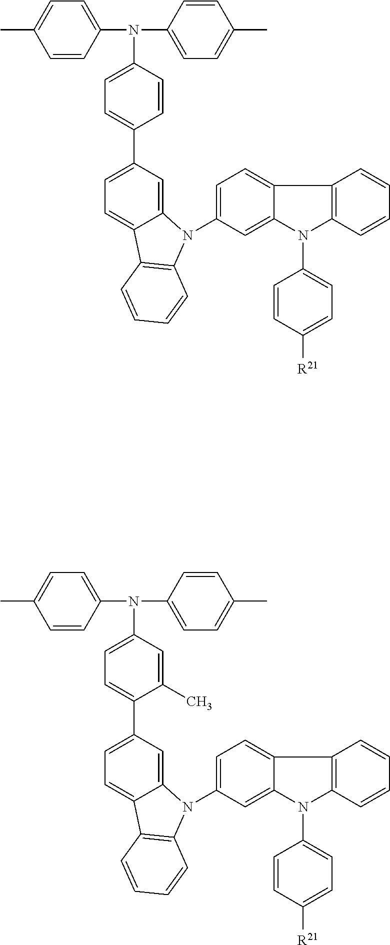
wherein, in Group 3,
R²¹ is as defined in Chemical Formula 5.

6. The polymeric compound of claim 1, wherein X in Chemical Formula 2 is represented by one of Chemical Formulae (8-1) to (8-22): 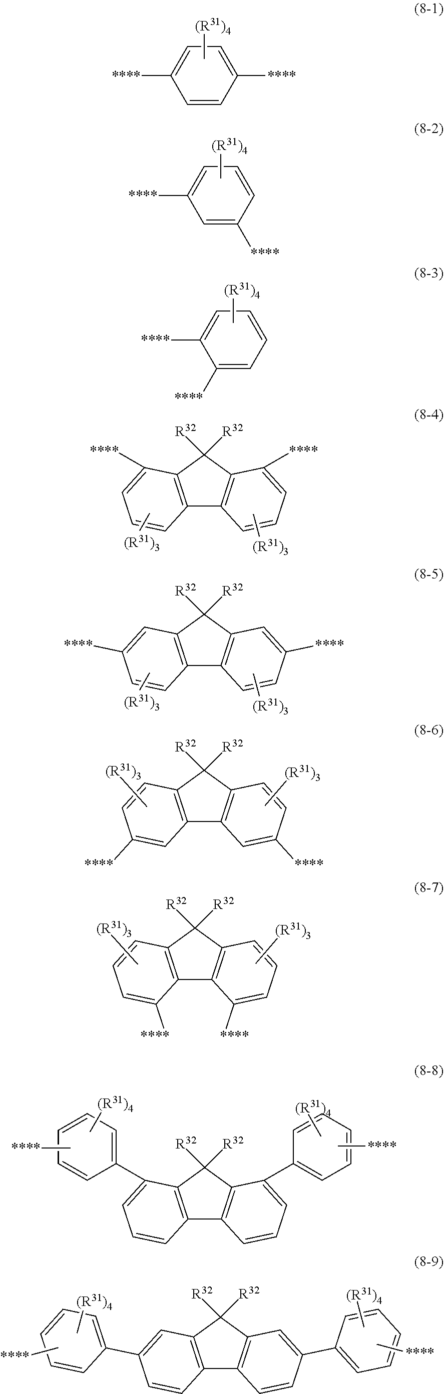 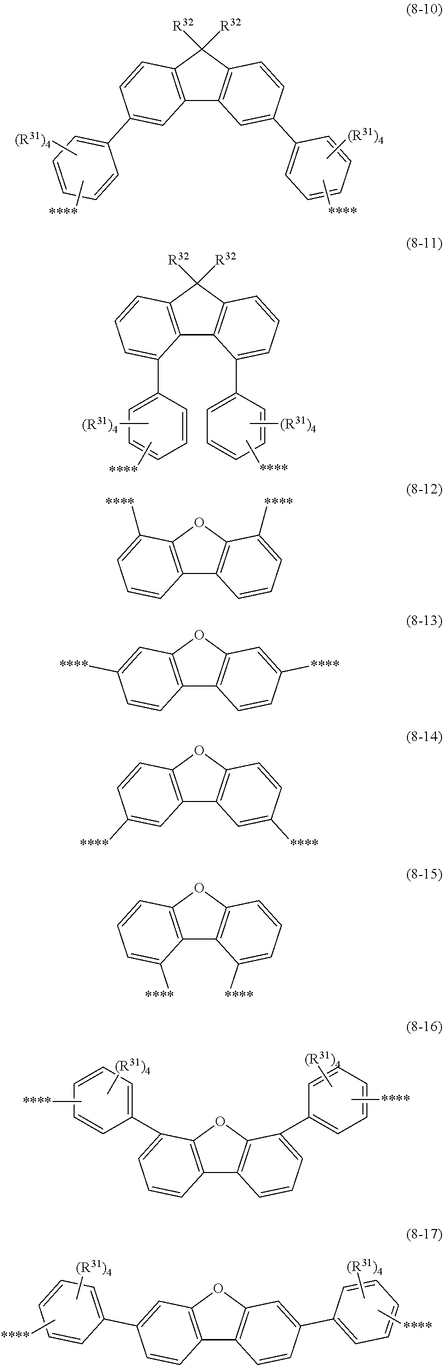 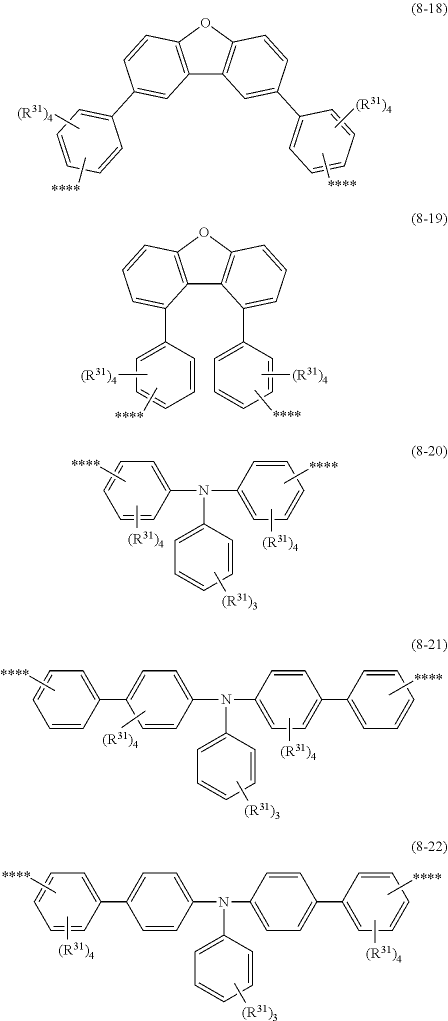
wherein in Chemical Formulae (8-1) to (8-22),
R³¹ is a hydrogen atom, a substituted or unsubstituted linear saturated hydrocarbon group having 1 to 14 carbon atoms, or a substituted or unsubstituted branched saturated hydrocarbon group having 3 to 14 carbon atoms,
R³² is a substituted or unsubstituted linear saturated hydrocarbon group having 1 to 14 carbon atoms, or a substituted or unsubstituted branched saturated hydrocarbon group having 3 to 14 carbon atoms, and
**** indicates a linking position.

7. The polymeric compound of claim 1, wherein Chemical Formula 1 is a structural unit represented by one of Group 6:

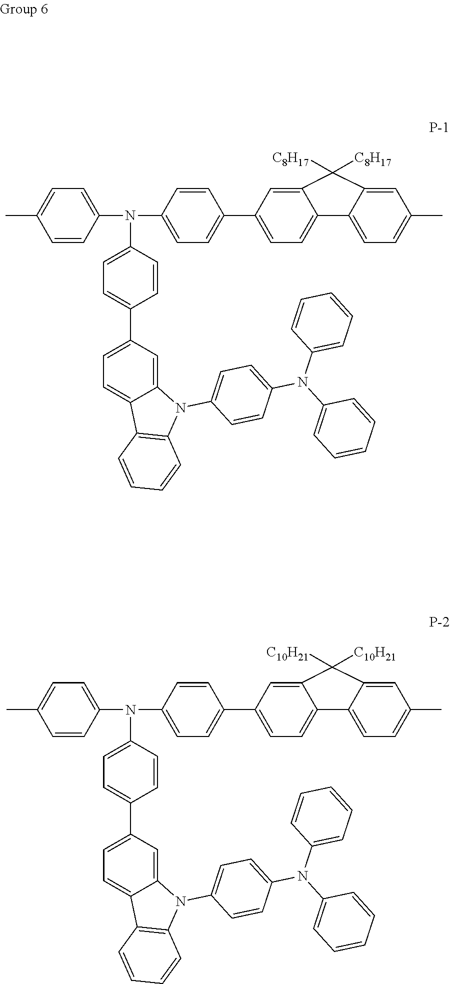

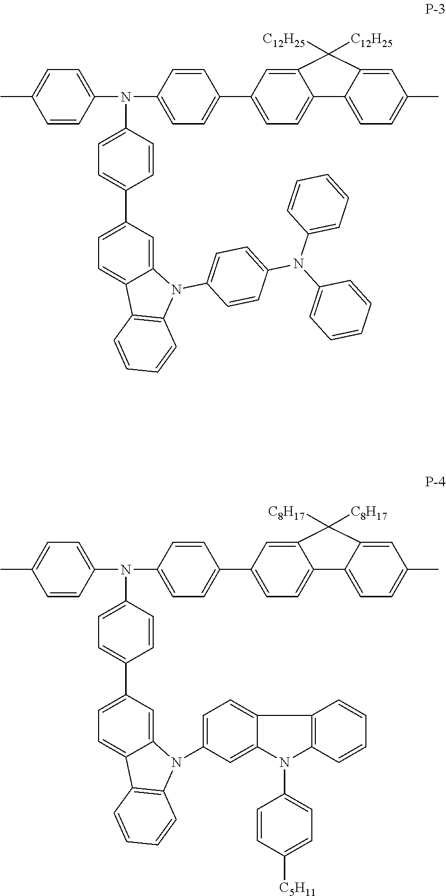

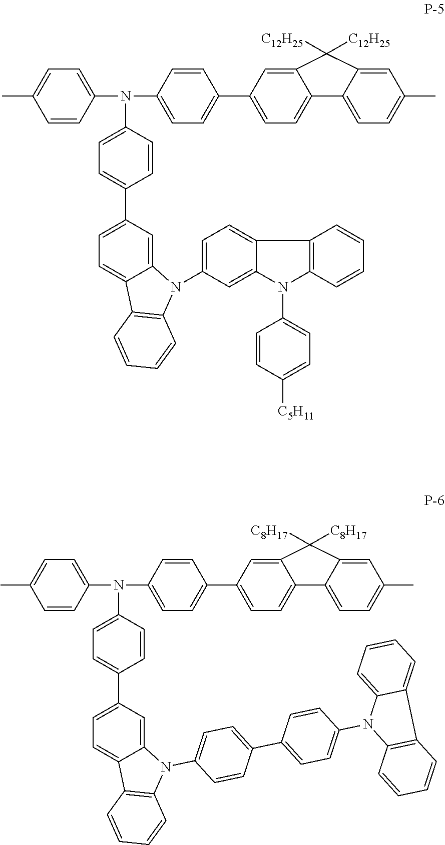

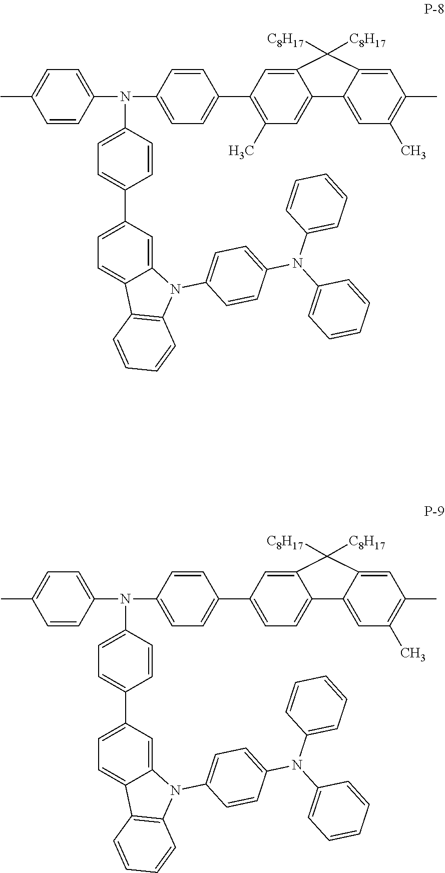

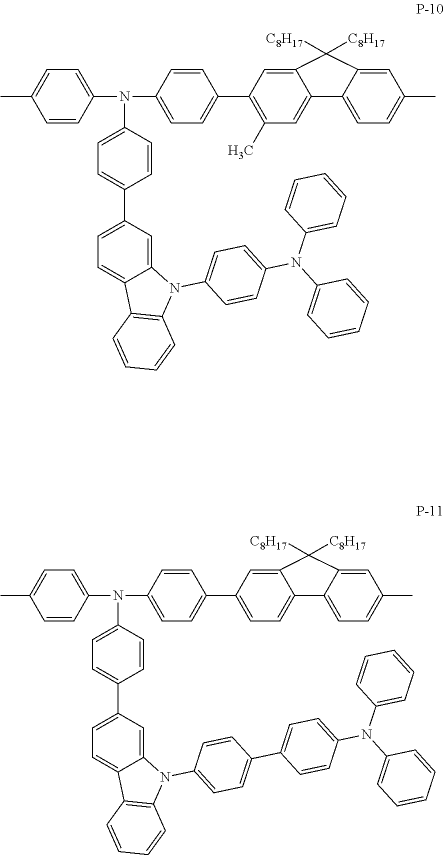

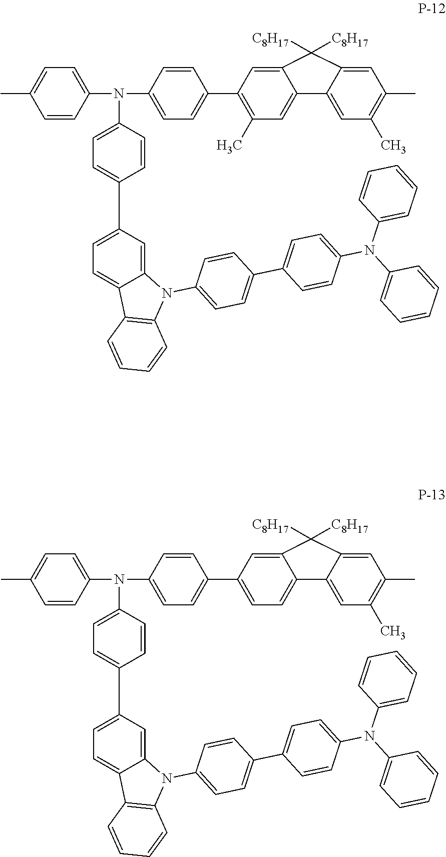

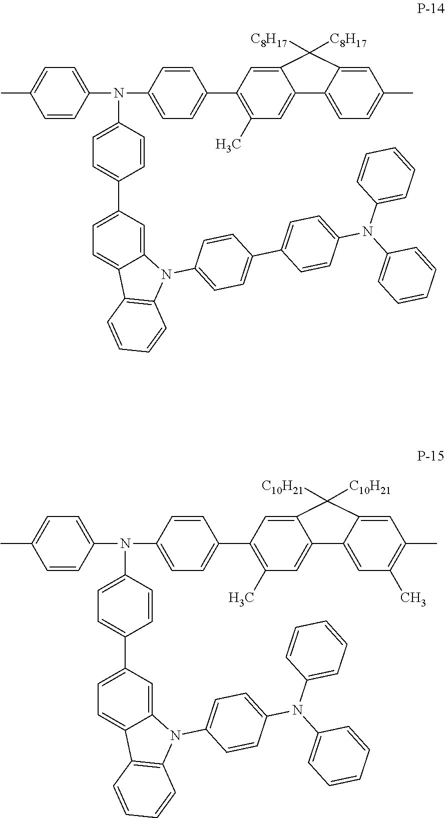

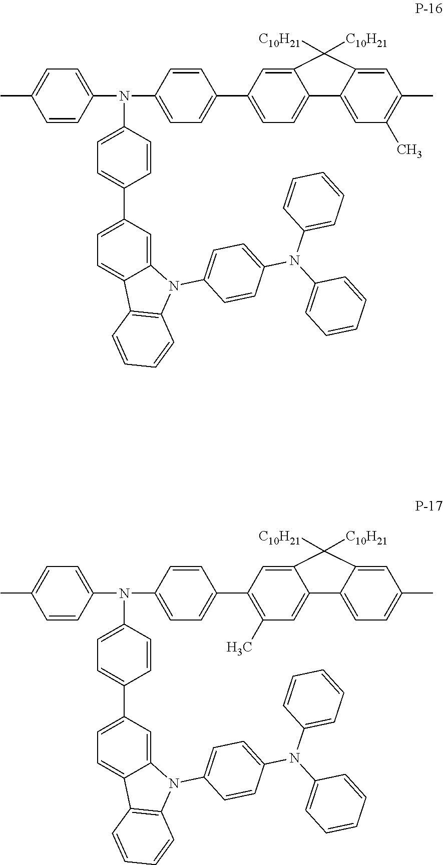

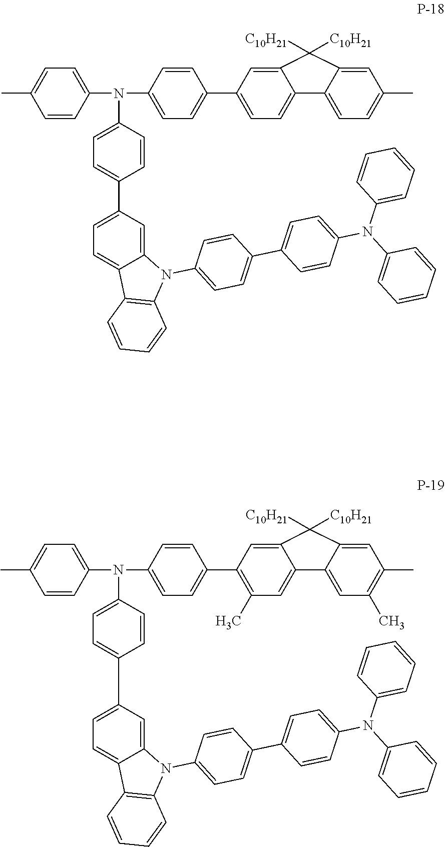

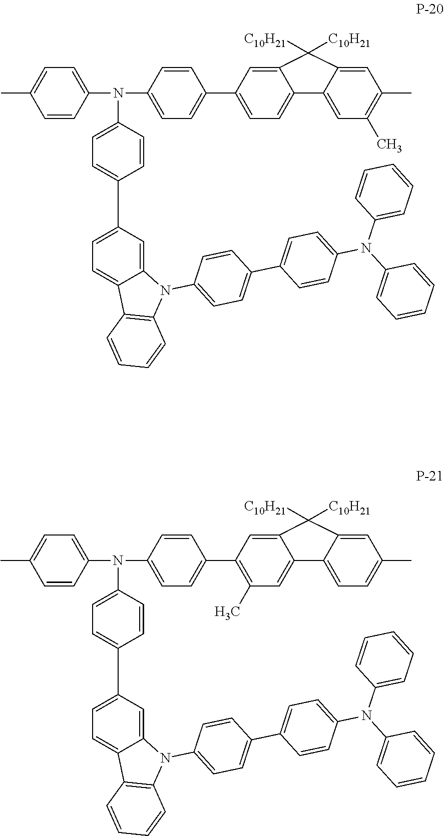

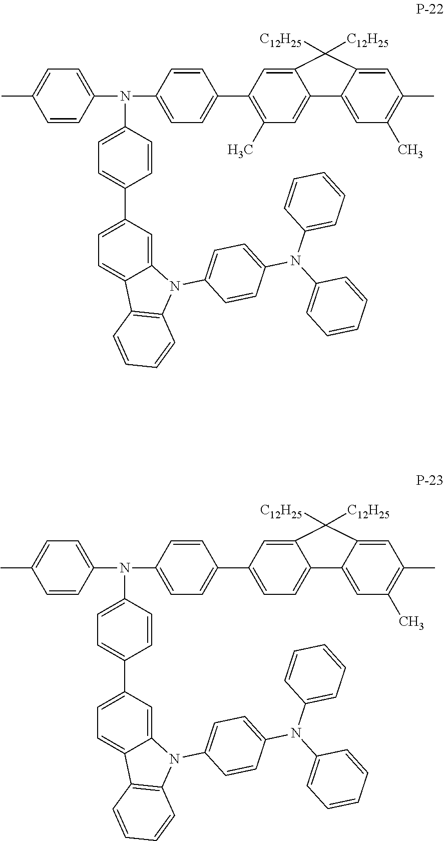

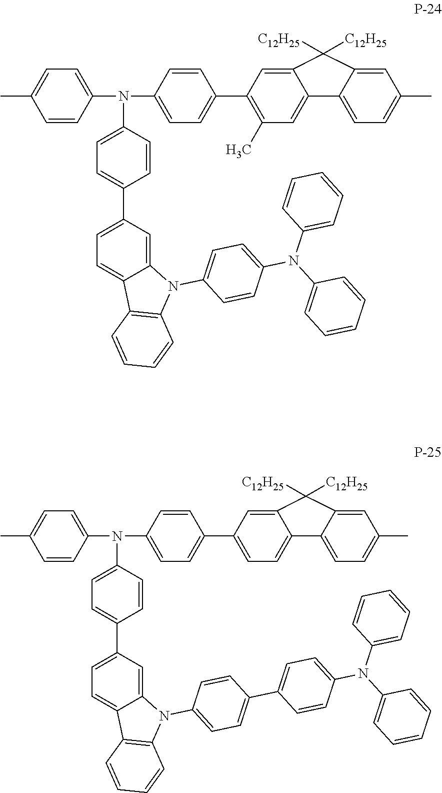

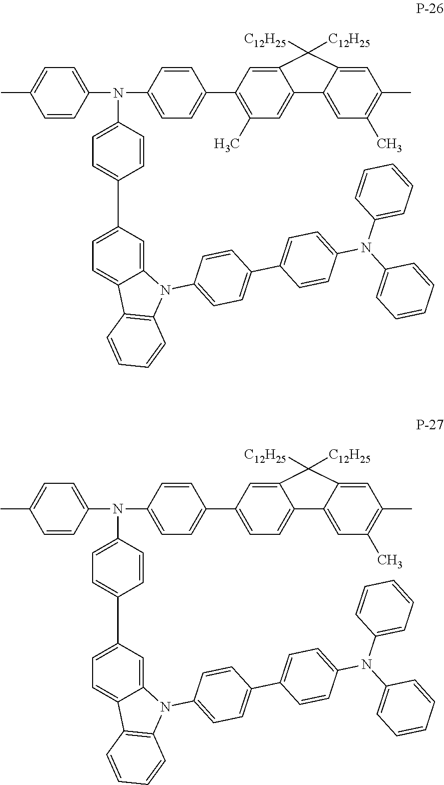

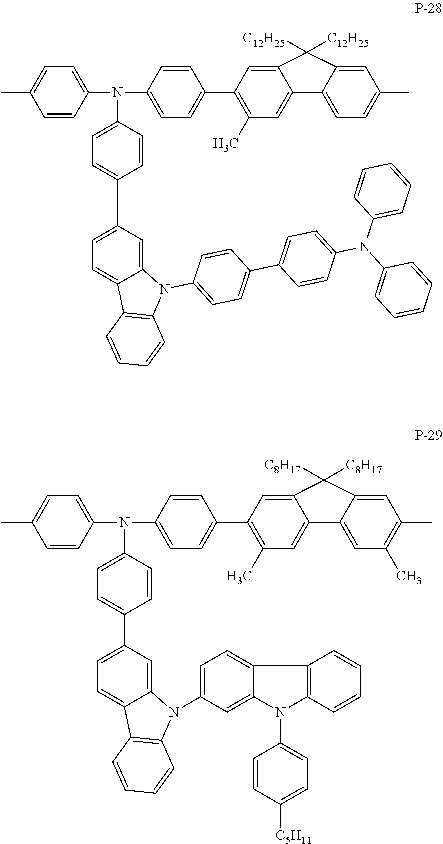

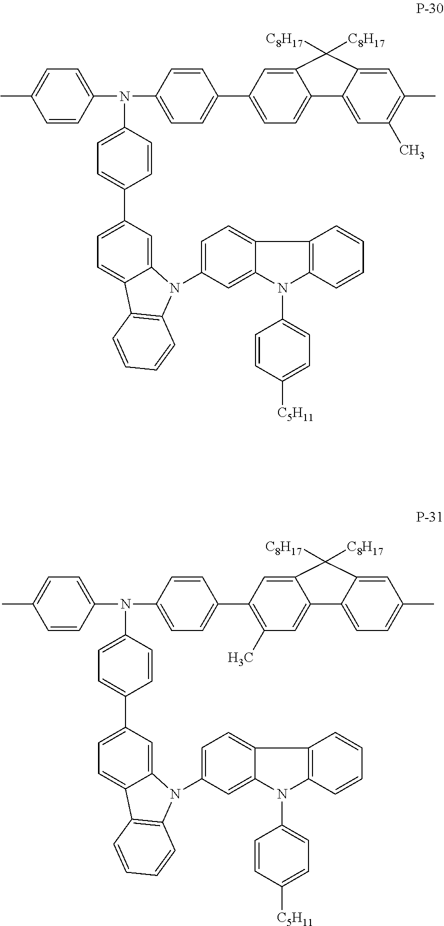

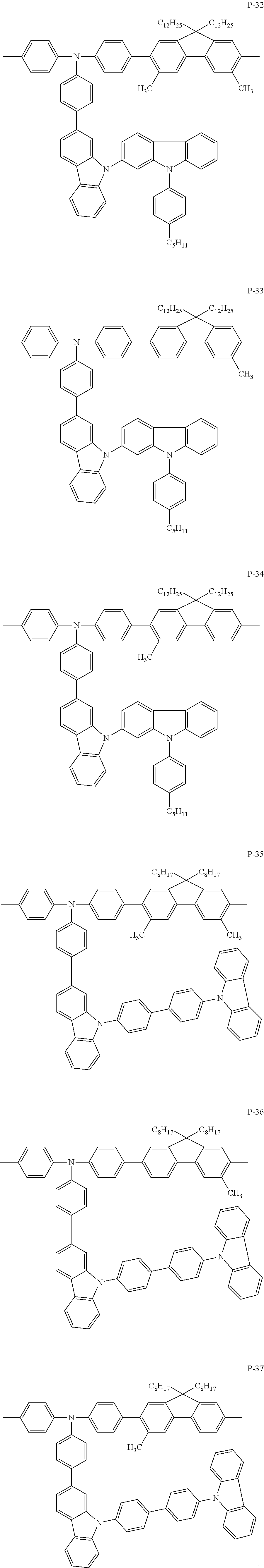

8. The polymeric compound of claim 1, wherein the polymeric compound further comprises one or more terminal end groups, wherein the terminal end groups comprise a hydrocarbon group or a hydrogen atom.

9. A composition comprising the polymeric compound of claim 1, and at least one of a hole transport material, electron transport material, or a light-emitting material.

10. A composition comprising the polymeric compound of claim 1, and at least one solvent.

11. An electroluminescence device, comprising:
a first electrode,
a second electrode, and
at least one layer of an organic film arranged between the first electrode and the second electrode,
wherein the at least one layer of the organic film comprises the polymeric compound of claim 1.

12. An electroluminescence device, comprising:
a first electrode, a second electrode, and at least one layer of an organic film arranged between the first electrode and the second electrode,
wherein the at least one layer of the organic film comprises the composition of claim 9.

13. The electroluminescence device of claim 11, wherein the at least one layer of the organic film comprising the polymeric compound is a hole transport layer or a hole injection layer.

14. The electroluminescence device of claim 11, wherein the electroluminescence device further comprises a light emitting layer comprising at least one of a semiconductor nanocrystal particle or an organometallic complex between the first electrode and the second electrode.

15. The electroluminescence device of claim 14, wherein the light emitting layer is positioned adjacent to the at least one layer of the organic film comprising the polymeric compound of claim 1.

16. A method of manufacturing an electroluminescence device comprising a first electrode, a second electrode, and at least one layer of an organic film arranged between the first electrode and the second electrode, the method comprising:
coating a composition comprising the polymeric compound of claim 1 and a solvent to form the at least one layer of the organic film between the first electrode and the second electrode, and
removing the solvent.
